(19) United States
(12) Patent Application Publication
(10) Pub. No.: US 2014/0166483 A1
(43) Pub. Date: Jun. 19, 2014

(54) ELECTROKINETICS-ASSISTED SENSOR

(71) Applicant: Queen's University at Kingston, Kingston (CA)

(72) Inventors: Jacky CHOW, Kingston (CA); Matthew R. TOMKINS, Vancouver (CA); Yong Jun LAI, Kingston (CA); Aristides DOCOSLIS, Kingston (CA)

(73) Assignee: Queen's University at Kingston, Kingston (CA)

(21) Appl. No.: 14/133,779

(22) Filed: Dec. 19, 2013

Related U.S. Application Data
(60) Provisional application No. 61/739,314, filed on Dec. 19, 2012.

(30) Foreign Application Priority Data
Jan. 31, 2013 (CA) 2804848

(51) Int. Cl. G01N 27/447; B81B 1/00

(52) U.S. Cl. CPC G01N 27/44791; B81B 1/006
USPC 204/451; 204/602

(57) ABSTRACT

An electrokinetics-assisted sensor for sensing a target material. The sensor may include a microstructure deflectable in response to added mass on its body. The sensor may also include one or more features on or near the microstructure designed to generate an electric field giving rise to one or more electrokinetic effects to drive material towards the microstructure, when an electrical signal is applied to the feature(s). Presence of the target material on the body of the microstructure may cause a response in the microstructure, including a detectable change in deflection of the microstructure.

### CROSS-REFERENCE TO RELATED APPLICATION

The present disclosure claims priority from U.S. provisional patent application No. 61/739,314, filed Dec. 19, 2012; and Canadian patent application no. 2,804,848, filed Jan. 31, 2013; the entireties of which are hereby incorporated by reference.

### TECHNICAL FIELD

The present disclosure relates to electrokinetics-assisted sensors, devices and systems, including microelectrode sensors using electrokinetic effects, such as dielectrophoresis, electroosmosis and/or electrothermal flow (flow driven by electrical property gradients in a fluid) to assist in sensing of one or more target materials. The present disclosure may be suitable for implementation as a biosensor.

### BACKGROUND

Various technologies have been proposed as alternatives to microbiological culture for detection of bacteria. Technologies such as enzyme-linked immunosorbent assay (ELISA) [55-57], biochemical labeling or fluorescence tagging, and polymerase chain reaction (PCR) have been demonstrated, but also have limitations. For instance, standard ELISA detects target pathogens at concentrations of about 6×10⁵ to about 6×10¹¹ cells/mL [25]. Other limitations of conventional technologies may include one or more of: i) time consuming culture steps, such as requiring at least 12 hours for detection [48]; ii) complex procedures requiring highly trained personnel [49, 50] and iii) laboratory-based methodologies using specialized instruments [51, 52]. These and other limitations may result in lengthy testing periods, high cost and/or limited applications for these conventional techniques. Miniaturization and microfluidics technologies have also been recently reported for field monitoring of bacteria [54, 56, 57, 61-63] with prototypes at the laboratory stage demonstrating reduced testing time. However, such technologies still have relatively high detection limits (about 10⁴ cell/mL) and relatively low sample throughput, and some may require relatively expensive supporting equipment and/or balance-of-plant (BOP).

Detection and identification of pathogenic bioparticles may be useful for prevention of an outbreak or in the treatment of a disease, among other applications. Conventional drinking water bacteria tests require samples to be sent to a laboratory, or use a microbiological culture kit that requires a lengthy incubation time (e.g., a minimum of 18-24 hr incubation) followed by visual detection by an experienced technician [39]. These culture procedures may have been designed to achieve the required selectivity (e.g., for E. coli or coliform type bacteria) and a detection limit of one cell in a 100 mL sample. Molecular diagnostic methods based on DNA or RNA detection may be used for environmental monitoring, but these are still laboratory based [48, 53, 58-60]. Various biosensors and miniature systems for bacteria detection have been reported [67, 62], but typically are not suitable for routine use for drinking water monitoring because they typically cannot achieve the required selectivity and/or detection limit. Even for applications where detection of hundreds or thousands of cells is needed, relatively lengthy culture methods are still the conventional approach.

On-site detection of pathogens has been possible with surface based biosensors tailored to selectively capture bacteria on a functionalized surface and transduce this collection event into an electronic signal [1-3]. However, the transport of particles from the bulk of a sample to the sensor's surface is often diffusion limited and this may be a bottleneck in the operation of these devices, such as for the detection of pathogens from dilute samples.

### SUMMARY

In some example aspects, the present disclosure provides an electrokinetics-assisted sensor for sensing a target material, the sensor may include: a microstructure deflectable in response to added mass on a body of the microstructure; and at least one of a resistive feature or a capacitive feature on or near the microstructure designed to generate an electric field giving rise to one or more electrokinetic effects to drive material towards the body of the microstructure, when an electrical signal is applied to the at least one feature; wherein presence of at least the target material on the body of the microstructure causes a response in the microstructure, the response including a detectable change in deflection of the microstructure.

In some examples, the sensor may include a functionalized surface on the body of the microstructure that captures the target material on the body of the microstructure.

In some examples, the functionalized surface may include at least one macromolecule.

In some examples, the at least one macromolecule may be specific for a biological target material.

In some examples, the at least one macromolecule may include at least one of: an antibody, an antigen-binding antibody fragment, an enzyme, a binding protein, and a polynucleotide.

In some examples, the at least one macromolecule may include at least one of: a polyelectrolyte, a charged polymer, and a binding protein.

In some examples, the resistive feature may include at least one of: a change in conductivity of the microstructure, a change in cross-sectional area of the microstructure, and a resistive electrical component.

In some examples, the capacitive feature may include at least two spaced-apart conductive components on the microstructure.

In some example aspects, the present disclosure provides an electrokinetics-assisted sensor for sensing a target material, the sensor may include: a microstructure deflectable in response to added mass on a body of the microstructure; at least one feature on or near the microstructure designed to generate an electric field giving rise to one or more electrokinetic effects to drive material towards the body of the microstructure, when an electrical signal is applied to the at least one feature; and a functionalized surface on the body of the microstructure comprising at least one macromolecule specific for the target material, that captures the target material on the body; wherein presence of at least the target material on the body of the microstructure causes a response in the microstructure, the response including a detectable change in deflection of the microstructure.

In some examples, the functionalized surface may include at least one macromolecule specific for a biological target material.

In some examples, the at least one macromolecule may include at least one of: an antibody, an antigen-binding antibody fragment, an enzyme, a binding protein, and a polynucleotide.

In some examples, the at least one feature may include at least one of: a resistive feature, a capacitive feature, and a microelectrode.

In some examples, the resistive feature may include at least one of: a change in conductivity of the microstructure, a change in cross-sectional area of the microstructure, and a resistive electrical component.

In some examples, the capacitive feature may include at least two spaced-apart conductive components on the microstructure.

In some examples, the detectable change in deflection of the microstructure may include a change in a resonant mode of the microstructure.

In some examples, the at least one feature may be designed to give rise to one or more electrokinetic effects to drive material towards an antinode of the resonant mode, and wherein presence of material at the antinode results in greater detectable change than presence of material elsewhere on the microstructure.

In some examples, the at least one feature may be designed to give rise to one or more electrokinetic effects to drive material towards a node of the resonant mode, and wherein presence of material at the node results in little or no detectable change.

In some examples, the detectable change may include a change in at least one of: resonant frequency, resonant amplitude, and resonant phase.

In some examples, the one or more electrokinetic effects may include at least one of: dielectrophoresis (DEP), electroosmosis (EO), and electrothermal flow.

In some examples, the microstructure may include at least one of: a cantilever beam having one free end and one fixed end, and a fixed-fixed beam having two fixed ends.

In some examples, at least one feature may be designed to give rise to one or more electrokinetic effects to drive material with at least one of: different mass, different charge, and different polarization, to different areas on or near the microstructure.

In some examples, the generated electric field may have locally enhanced or diminished field strength at a selected area to collect the target material.

In some examples, the selected area may include the body of the microstructure.

In some example aspects, the present disclosure provides a device for electrokinetics-assisted sensing of a target material, the device may include: a chamber defined in a substrate, the chamber housing: i) any one of the sensors described above, and ii) a fluid sample; and at least one bonding pad in electrical communication with the at least one feature of the sensor, that delivers an electrical signal to the sensor to cause generation of the electric field.

In some examples, the device may include an excitation electrode at or near the sensor, that mechanically excites the sensor into a resonant mode.

In some examples, the chamber may be in fluid communication with an inlet enabling inflow of the fluid sample and an outlet enabling outflow of the fluid sample.

In some examples, the chamber may be in fluid communication with a gas microchannel that enables introduction of a gas bubble into the chamber.

In some example aspects, the present disclosure provides a system for electrokinetics-assisted sensing of a target material, the system comprising: any one of the sensors and/or devices described above; at least a first signal source in electrical communication with the sensor, that provides an electrical signal to cause generation of the electric field; a detector that detects a response of the sensor; and a processor that analyzes the detected response and generates a signal indicating whether there is detection of the target material.

In some examples, the system may include an actuator that actuates the sensor into a resonant mode.

In some examples, the actuator may include at least one of: a piezoelectric element, and a heating element.

In some examples, the system may include at least a second signal source in electrical communication with the actuator, that provides an electrical signal to cause actuation of the sensor.

In some examples, the at least first signal source may be configured to provide a multi-frequency electrical signal, the multi-frequency electrical signal including at least one frequency that causes mechanical excitation of the sensor and at least one frequency that causes generation of the electric field.

In some examples, the system may include a pump that pumps a fluid sample to the sensor.

In some examples, the first signal source may be configured to provide an electrical signal for mechanical excitation of the sensor, simultaneously or in series with the electrical signal to generate the electric field. In some examples, “in series” may be used to refer to events that occur at different times, although not necessarily in a fixed order nor necessarily immediately after one another. In some examples, events that occur in series may occur in sequence.

In some examples, the system may include at least one output device, wherein the signal indicating detection of the target material is transmitted to the at least one output device to be outputted.

In some examples, the response of the sensor may be detectable as a change in resonance of the sensor, and the processor may be configured to analyze the detected response for at least one of: a change in frequency, a change in phase and a change in amplitude, in order to determine whether there is detection of the target material.

In some example aspects, the present disclosure provides a method for electrokinetics-assisted sensing of a target material, the method may include: providing a fluid sample to any one of the sensors, devices and/or systems described above; applying at least one electrical signal to the at least one feature of the sensor to give rise to one or more electrokinetic effects to drive material in the fluid sample toward the microstructure of the sensor; applying i) a same or different electrical signal or ii) a magnetic field to the sensor or to an actuator at or near the sensor to mechanically excite the sensor into a resonant mode; detecting a resonant response of the sensor; and determining, based on at least one of the frequency, phase and amplitude of the resonant response, whether the target material is present in the fluid sample and/or an amount of target material present in the fluid sample.

In some examples, the electrical signal to give rise to one or more electrokinetic effects and the electrical signal to mechanically excite the sensor may be included in a same single frequency or multi-frequency electrical signal.

In some examples, the method may include, prior to detecting the resonant response, removing non-target material from the sensor.

In some examples, the method may include removing the target material from the sensor.

In some examples, removing the target material from the sensor may include at least one of: thermally ablating the sensor and applying a denaturing chemical compound to the sensor.

In some examples, removing the target material from the sensor may include washing the sensor with a high ionic strength solution to dissociate the target material from the functionalized surface.

In some examples, the fluid sample may include a liquid and/or a gas.

In some examples, the method may include, prior to applying the electrical signal to mechanically excite the sensor, introducing a gas bubble to fully or partially engulf the sensor.

### BRIEF DESCRIPTION OF THE DRAWINGS

FIG. 1 shows an example system incorporating an example electrokinetics-assisted sensor;

FIG. 2 shows an example device incorporating an example electrokinetics-assisted sensor;

FIG. 3 shows an example flow-through system incorporating an example electrokinetics-assisted sensor;

FIGS. 4a-c show a schematic and close-up optical images of an example electrokinetics-assisted sensor;

FIGS. 5a and 5b show close-up optical images of an example electrokinetics-assisted sensor, demonstrating the effect of electrokinetic assistance;

FIGS. 6a and 6b are close-up optical images of an example electrokinetics-assisted sensor, demonstrating selectivity;

FIGS. 7 and 8 are charts comparing frequency responses of an example electrokinetics-assisted sensor, demonstrating the effect of electrokinetic assistance;

FIGS. 9a-f are schematics and images of an example electrokinetics-assisted sensor having a microstructure with a fixed-fixed beam configuration, in an example study;

FIGS. 10a and 10b show optical images demonstrating specificity of the example sensor of FIG. 9;

FIGS. 11a and 11b show optical images demonstrating selectivity of the example sensor of FIG. 9;

FIG. 12 is a chart illustrating specificity and selectivity of the example sensor of FIG. 9;

FIGS. 13a-16b are example images of the example sensor of FIG. 9 before and after collection of the target bacteria;

FIGS. 17a-30c are schematics, optical images and charts illustrating different example electrokinetics-assisted sensors;

FIGS. 31a-d are charts showing example results of applying a multi-frequency signal to an example electrokinetics-assisted sensor, and results illustrating saturation of an example electrokinetics-assisted sensor;

FIGS. 32a-c show optical images and a schematic illustrating thermal ablation of an example electrokinetics-assisted sensor;

FIG. 33 is a chart showing the frequency response before and after thermal ablation of an example electrokinetics-assisted sensor;

FIG. 34 is a chart showing the frequency response of an example electrokinetics-assisted sensor in a liquid medium and in a gas medium;

FIGS. 35a and 35b are images illustrating an example electrokinetics-assisted sensor in which a gas bubble may be introduced;

FIGS. 36a and 36b show an example schematic illustrating introduction of gas bubbles into a liquid flow and an image of an example electrokinetics-assisted sensor in which a gas bubble may be introduced;

FIG. 37 shows schematics illustrating the phenomena of positive and negative dielectrophoresis;

FIG. 38 is a schematic illustrating the phenomenon of electroosmosis;

FIG. 39 is a block diagram illustrating an example system including an example electrokinetics-assisted sensor;

FIG. 40 is a chart showing the detection response of an example electrokinetics-assisted sensor excited using a single frequency signal at about 1 MHz;

FIGS. 41a and 41b show images and schematics illustrating plug flows of liquid and air at a T-junction micro-mixer, in an example electrokinetics-assisted sensor;

FIG. 41c is a chart showing the first five measurement steps in the example sensor of FIGS. 41a and 41b, as the liquid plug approached the sensor;

FIGS. 42a-42e are images illustrating an example of thermal ablation in an example electrokinetics-assisted sensor; and

FIGS. 43a-43c are charts illustrating the frequency response before and after thermal ablation of an example electrokinetics-assisted sensor.

### DETAILED DESCRIPTION

### Overview

In some example aspects and embodiments, the present disclosure describes electrokinetics-assisted sensors, devices and systems for detection of target material(s). The sensor may be a microfluidic-microelectromechanical system (MEMS)-based detection platform, in which electrokinetic effects (which may include dielectrophoresis, electroosmosis and/or electrothermal flow) may be use to drive target material(s) (e.g., biological material, such as bioparticles or organisms) towards a sensing region (e.g., surface and/or internal region) of the sensor. The sensor may respond to the presence of the target material(s) at its sensing region, which response may be detected using a suitable detector.

Examples of the present disclosure may serve as platforms for Accelerated Detection of Bacteria (ADB), and may be used as a biosensor device for routine monitoring of, for example, drinking water safety and for monitoring bacteria in source waters before treatment. In some examples, the disclosed device may include the use of MEMS detectors [28, 37] and electrokinetic particle trapping technology [33].

In some examples, the present disclosure may provide real-time and/or label-free detection of the target material(s), and the disclosed sensor may be multiplexed into a sensor array.

In some examples, the disclosed sensor may include a functionalized sensing region, such as a functionalized surface (e.g., coated using an antibody, such as a commercially-available antibody) to provide selectivity and/or enhanced sensitivity [67] towards the target material(s).

In some examples, the disclosed sensor may include microelectrodes and/or other features (e.g., resistive or capacitive features), including circuit components (e.g., resistive or capacitive electrical components), that may be configured to, when an electrical signal is applied, cause electrokinetic effects to promote concentration of the target material(s) (e.g., organisms) in the vicinity of (at or near) the sensing region of the sensor. A microstructure (e.g., a sensing beam, which may be a cantilever beam or a fixed-fixed beam) of the sensor may provide the sensing region. The result may be a sensor with relatively low detection limits and relatively accelerated target detection, without requiring a subsequent labeling step.

The present disclosure may enable speeding up of target material(s) (e.g., biological material such as bioparticles, or non-biological material such as chemicals) detection through the use of spatially non-uniform electric field effects, which may be created by features (e.g., resistive and/or capacitive features, or one or more microelectrodes) provided on the sensor (e.g., embedded on, in and/or near a sensing microstructure). For example, it has been found that alternating current (AC) electrokinetic effects may provide a means for relatively fast convective transport, and subsequent concentration amplification of pathogens at a target detection surface [4-8]. Enhanced detection of bacteria has been found to be possible by employing AC electrokinetic effects in proof-of-principle studies [9-11]. Reviews of the phenomenon of particle trapping in planar quadrupolar microelectrodes are present in the literature [12-15].

In some examples, the disclosed sensor may include a microstructure, such as a cantilever (with one fixed end and one free end) or a fixed-fixed beam (with two fixed ends). Use of cantilever beams has been investigated for detecting changes in mass via resonant frequency, or deflection [16]. Ilic et al., reported a linear relationship between the shift in a cantilever's resonant frequency and the number of deposited bacteria [17]. In other studies, higher fundamental mode resonant frequencies were used to maximize sensitivity [18]. Dielectrophoresis-assisted capture of human cancer cells was demonstrated using cantilever beams where the cantilever beams acted as the electrodes [19]. However, two cantilever beams were needed to create the electric field and required up to 7 days of culturing before detection was realized, which may be unsuitable for practical use. A similar setup using the casing as the second electrode was used to demonstrate the capture of 20 nm carbon nanoparticles [20]. Islam et al. induced AC electroosmotic flow to drive polystyrene particles to a point near the anchor and detected a mass change after drying [21]. Also using AC electroosmosis, Arefin and Potter detected the HSV-1 virus from changes in the resistance of a piezoelectric cantilever with microelectrodes embedded on the surface [22].

Various MEMS vibrational sensors have been found to have increased intrinsic resonant frequencies and to consequently provide mass detection at the picogram [26-28], attogram [29] and zeptogram [30] level. To achieve such high sensitivity, these sensors typically require operation in a cryogenic, vacuum environment to suppress damping effects and thermal noise, which may be unsuitable for practical use. Recent advances in MEMS using higher-order flexural modes have been shown by Lai's group to provide high sensitivity mass detection in liquid media [37, 38].

Electrokinetic phenomena, including electroosmosis (EO) and dielectrophoresis (DEP), may be used to manipulate various target materials, including bioanalytes. EO may be defined as the bulk flow of an electrolyte induced by motions of ions in the double layer near surfaces under the influence of an external electric field, which under certain conditions can manipulate transport of target material(s) in the electrolyte [35, 36, 44-47]. DEP may be defined as the transport of target material(s) directly as individual dielectric particles under the influence of a spatially non-uniform electric field. Docoslis's group [33, 34] and other groups [41-43] have shown that electrokinetics may be used to move or isolate both inert and biological particles.

Electrohydrodynamics may be considered a subset of electrokinetic phenomena, for the purposes of the present disclosure. Electrohydrodynamics may refer to the manipulation of media (typically liquid media) carrying the target material(s), and may not directly manipulate the target material(s) itself (themselves) except by indirectly exerting drag forces on particles via the creation of fluid flow, for example. Electrohydrodynamics may include phenomena such as EO and electrothermal flow.

In some examples, the present disclosure provides a MEMS vibrational sensor using electrokinetics for driving (also referred to as “collecting”) target material(s), including biological target material(s) such as bacteria, towards a sensing region of the sensor. Proof-of-concept studies, such as described in [66], illustrate that E. coli bacteria could be actively collected and detected on the MEMS microelectrode sensor, and may result in a higher signal than in the absence of electrokinetics. The use of MEMS technology may enable compatibility with array designs, label-free detection through specific surface immobilization, relatively high sensitivity due to its microstructural size, and/or relatively low cost for mass production. For example, the disclosed sensor may be fabricated using commercially available technology at a relatively low cost.

The present disclosure also describes a MEMS device (e.g., a MEMS chip) including one or more sensors suitable for electrokinetics-assisted driving of target material(s) (e.g., target particles including biological particles). In some examples, the disclosed device may be fabricated using commercially available micro-fabrication processes, which may be useful for relatively low-cost mass production.

In various example aspects and embodiments, the present disclosure provides a sensor that may combine electrokinetics-assisted (e.g., electrokinetically-accelerated) sampling with electromechanical signal transduction in a single sensor. The disclosed sensor may employ the phenomenon of DEP (e.g., as described in [15, 69]) to drive target material(s) towards the sensing region.

In some examples, detection of pathogens may be possible without the need for cultivation by employing an example of the disclosed sensor. The sensor may include one or more microelectrodes on or near a sensing region (e.g., a surface and/or an internal region) of a microstructure. For example, the microelectrode(s) may be embedded directly on or in the microstructure (e.g., embedded on a surface of the microstructure and/or at least partially internal to the microstructure). In some examples, the present disclosure provides a quadrupolar microelectrode design integrated onto a microstructure sensor, such as a cantilever, which may be suitable for DEP-assisted collection and detection of bacteria. The sensor may include one or more functionalized surfaces that may serve to capture target material(s) while avoiding detection of non-target materials. Other example embodiments of the disclosed sensor are also described.

In some examples, the disclosed sensor may be used as a biosensor, which may be able to detect the presence of certain target bacteria from an aqueous sample in a relatively short time frame (e.g., on the order of minutes) rather than the conventional time frame (typically on the order of hours to days), which may allow the disclosed sensor to be suitable for practical real-time or near real-time detection of bacteria (e.g., in the field or in the home).

In some examples, the disclosed sensor may be a mass-sensitive microsensor that may have the ability to deterministically attract and selectively capture target material(s), such as target bacteria, onto one or more regions (e.g., a selected sensing region, such as a sensing surface and/or an internal sensing region) of a mass-sensitive microsensor. For example, the sensor may include a microstructure that is a microscale mechanical resonator, or microresonator, that may be responsive to changes in its mechanical properties and mechanical boundary conditions. These changes may arise as a result of, but are not limited to, alterations to its structural mass and/or stiffness (e.g., due to the presence of target material(s) at its sensing region).

Boundary conditions for the resonator may include, for example, geometric positions where the microstructure is fixed, and other forces, moments and/or initial conditions applied at specific positions on the microstructure that may be expected to affect its dynamics. For example, a microstructure that is a beam of cross section, A, and length, L, clamped at only one region of the beam may be considered a cantilever and is expected to have a certain inherent resonant frequency. This same geometry beam otherwise clamped at more than one region may have a different resonant frequency even though the beam's total static mass remains the same. This may be relevant where collection of material on the microstructure may result in changes in the boundary condition (e.g., material collecting strongly at a specific position on the microstructure, near an electrode in close proximity to but not on the microstructure, may build up to the point where the microstructure becomes mechanically coupled to the nearby electrode, leading to a sudden change of resonant frequency that may be larger than that induced by mass-loading).

### DEFINITIONS

The present disclosure may refer to sensors that operate in the “dynamic” mode and/or the “quasi-static” mode. Both the dynamic mode and the quasi-static mode may refer to methods by which a micromechanical sensor may respond to the presence of added material (e.g., the target material(s) or analyte) on, in or otherwise coupled to the sensor. When response signals are time-dependent dynamic parameters, such as resonant frequency, phase and/or amplitude, the sensor is said to be in its dynamic mode of operation. In this mode of operation, the sensor may act as a resonator. In the quasi-static mode of operation, the response signal from the sensor may arise from displacement due to substantially time-constant (i.e., not time-varying) elastic and/or plastic deformation of the sensor. In various example embodiments, the disclosed sensor may exhibit one or both modes of response. Although some examples may be described with respect to their dynamic mode, such examples may also operate in a quasi-static mode (e.g., by measuring quasi-static parameters such as static displacement and/or stress/strain of the sensor, which may occur in the absence of dynamic excitation). Some examples may operate only in dynamic mode or only in quasi-static mode.

The present disclosure may use the term “material-loading” to refer to an event where one or more materials (which may include target material(s) as well as non-target materials) become coupled to (e.g., attached to or adsorbed on) the sensor (e.g., coupled to a sensing surface and/or sequestered in an internal sensing region) and form a mechanically-coupled body with the sensor. The result of material-loading may be an increase in mass of the coupled sensor-material body, which may result in a detectable response signal from the sensor. The response signal may be a change in the resonant frequency, phase and/or oscillation amplitude of the sensor, when a sensor is operating in its dynamic mode, as described above. The response signal may also be a displacement of the sensor and/or change in its stress/strain behavior, when the same or a different sensor is operating in its quasi-static mode, as described above. A common material-loading mechanism may be surface adsorption. Other mechanisms may include lock-and-key binding (e.g., where the sensor includes a functionalized surface including enzymes and/or antibodies targeted towards a target material) or other specific binding. Specific binding may include, for example, hydrophobic interactions, formation of ionic bonds and formation of hydrogen bonds (e.g., for binding to oligonucleotides and/or polynucleotides such as DNA), among others. Non-specific binding may including, for example, charge-based binding, such as binding to a polyelectrolyte (e.g., non-specific binding of a substantially negatively charged cell membrane to poly-L-lysine). Other material-loading mechanisms may be possible. An example of non-surface adsorption material-loading may be internal sequestering of material by the sensor (e.g., by absorption, by infiltration of material into the structure of the sensor, and/or by adsorption on the surface of an internal pore of the sensor).

In some examples, where the sensor includes a functionalized surface, processes such as washing or mechanical shaking of the sensor may ensure that most or substantially all non-target materials are removed from the sensing region, such that the response signal of the sensor arises substantially only from loading of target material(s) on and/or in the sensor. Target materials may also be removed from the sensing region, for example, to enable the sensor to be reused. Where the target material is bound to the sensor (e.g., due to specific binding, such as at a functionalized surface), the target material may be removed by, for example, washing of the sensor using appropriate solutions. For example, the sensor may be washed with a solution having relatively high ionic strength (e.g., a NaCl or MgCl₂ solution), in order to remove any bound target material from a functionalized surface.

The present disclosure may refer to improving the “performance” of a sensor. The performance of a sensor, for example a biosensor, may be evaluated by various criteria including one or more of: mass responsivity (typically measured in Hz/g), time required to obtain a measurement (typically measured in seconds), temporal resolution (typically measured in seconds) and measurement precision (typically measured in +/−g). Enhancement of the performance of a sensor may include increase in mass responsivity (e.g., a greater change in frequency per change in unit mass of the coupled sensor-material body), reduction in measurement time, increase in temporal resolution (e.g., faster detection signal can be obtained after material-loading occurs) and/or increase in measurement precision (e.g., reduction in measurement error). Other performance criteria and enhancements may be possible.

The present disclosure may refer to improving the “core competencies” of a sensor, which may mean the creation and/or facilitation of new or existing functions of the sensor. Such improvements may include one or more of: facilitating multiple target materials to be detected with one sensor as opposed to detection of only one target material, inclusion of an ability to gauge the precision of a measurement, and facilitating concurrent or overlapping actions that may be conventionally performed independently as series processes (e.g., collection of material and obtaining a response signal). Other sensor functions may be improved and/or added.

The present disclosure may use the term “electrokinetics” to generally include various phenomena in which an electric field and/or a gradient in electrical properties may give rise to a driving force on material. In the present disclosure, electrokinetics may include phenomena such as electrohydrodynamics, electroosmosis, dielectrophoresis and electrothermal flow.

The present disclosure may refer to a “microstructure” in the sensor. A microstructure may refer to any microscale or nanoscale structure (e.g., having dimensions in the range of one to several hundred micrometers, or in the range of one to several hundred nanometers). The microstructure may have a geometry that exhibits a response in its quasi-static and/or dynamic mode. For example, a microstructure may be a beam (which may include a cantilever or a fixed-fixed beam), a platform, a pronged structure, a V-shaped structure, a cross-shaped structure, a network structure, or any other microscale structure having a suitable geometry. The geometry of the microstructure may be designed to reduce excess mass (e.g., by eliminating regions of the microstructure where little or no material is expected to collect and/or by eliminating regions that do not contribute much to maximizing frequency shift based on expected material collection). By reducing excess mass on the microstructure, the sensitivity of the sensor may be increased. Higher-order modes with smaller frequency separations between resonant frequencies may be achieved, allowing more high-order modes to be measured for a given measurement bandwidth. Different configurations of the microstructure may enable different capabilities for detection of the target material. In some examples, the microstructure may comprise two or more microscale structures (e.g., two beams) that may or may not be coupled in their mechanical behavior. In other examples, the microstructure may comprise a single unitary structure.

### Example Embodiment

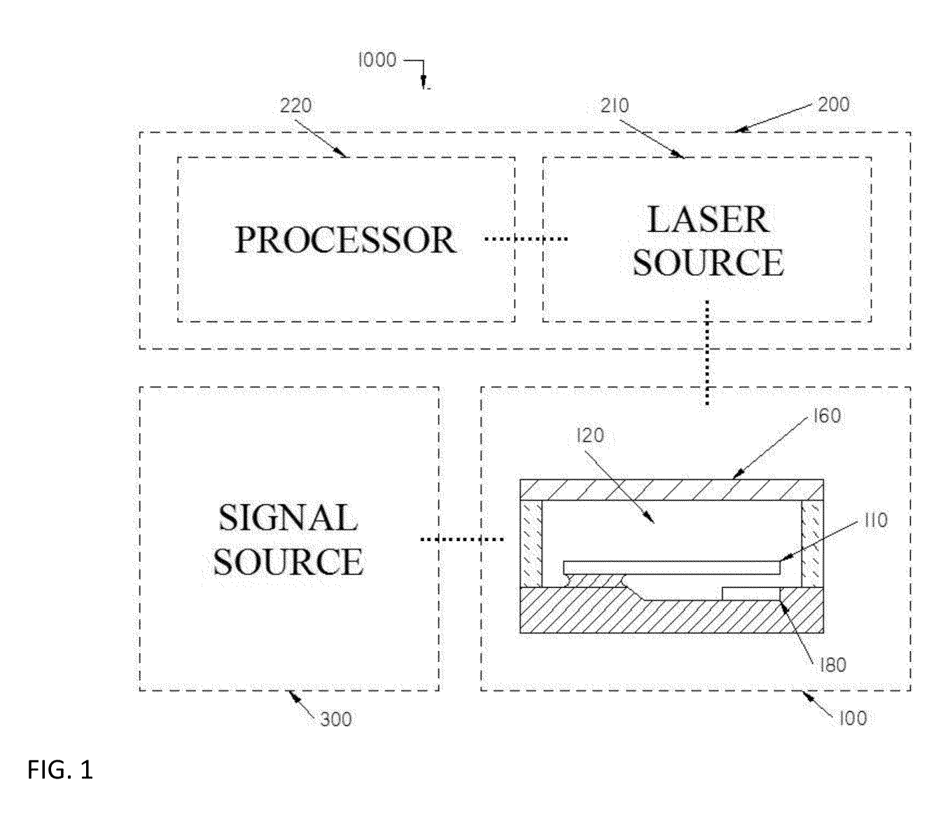

Reference is first made to FIGS. 1-3, illustrating an example detection system 1000 including an example of the disclosed device 100. The device 100 may include an example of the disclosed sensor 110 and a chamber 120 housing the sensor 110.

As will be described, the disclosed systems, devices and sensors may employ AC or DC electrokinetic phenomena. Electrokinetics-assistance may facilitate one or more of: enhanced rate and/or probability of material-loading at a sensing region of the sensor 110, control of spatial distribution of materials adsorbed on or otherwise coupled to the sensor 110, particle separation for discrimination of different materials, and structural excitation of the sensor 110 as a microresonator (e.g., when using AC electrokinetics).

The disclosed systems 1000, devices 100 and sensors 110 may provide one or more advantages over conventional systems and techniques including, for example, one or more of: reduction in measurement time, improved detection sensitivity and/or precision, improved selectivity for target material(s), reduction in complexity of system integration into larger systems and/or improved system reliability, and facilitation of multi-target detection strategies.

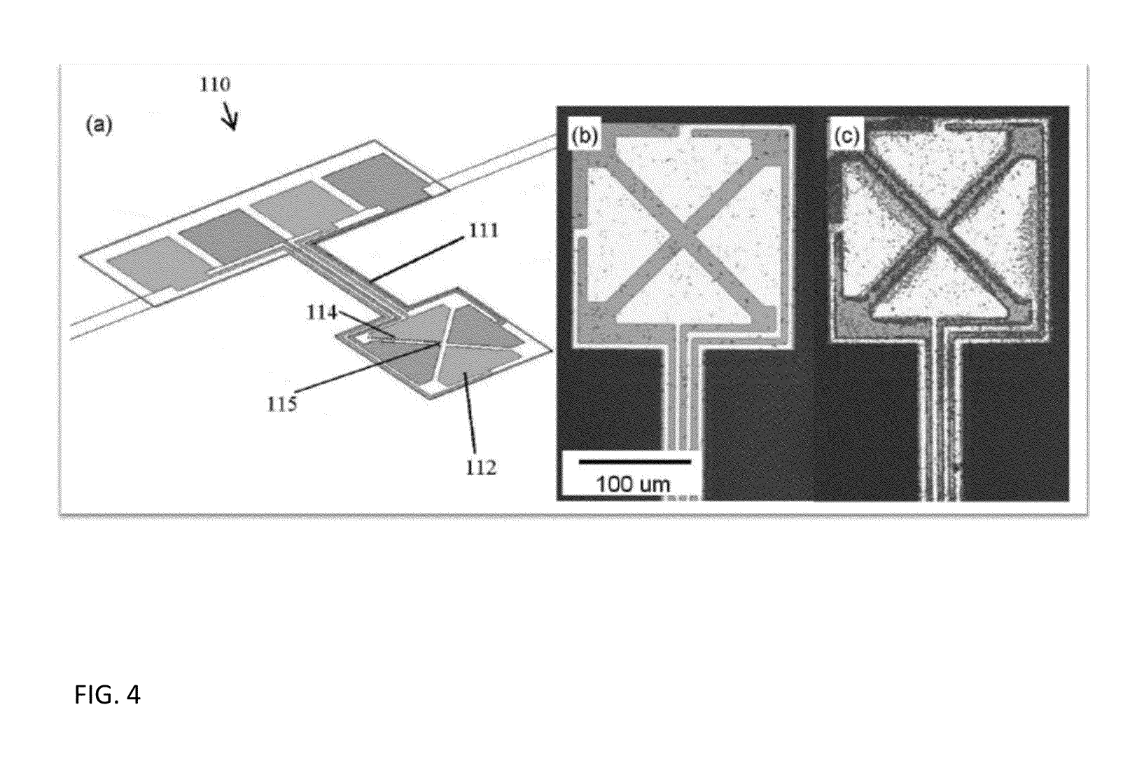

The sensor 110 may include a sensing microstructure 111 (e.g., a beam) and one or more features (e.g., electrical features or components), such as one or more microelectrodes 112 (see FIG. 4a), that generate an electrical field when a suitable electrical signal is applied. The microstructure 111 may have any suitable geometry that may respond to minute mass changes by a detectable change in its quasi-static (e.g., stress/strain and/or deformation) and/or dynamic (e.g., resonant frequency, phase and/or amplitude) mode. The feature(s) may enable the generation of an electrical field in the vicinity of the microstructure 111, designed to cause electrokinetic effects for driving material towards the sensor 110, as described further below. The feature(s) may be a resistive or capacitive feature, and may be provided by the microstructure 111 itself and/or be provided by one or more components added to the microstructure 111. For example, the feature(s) may include one or more of: microelectrode(s) 112, resistor(s), material(s) of higher or lower conductivity on or in the microstructure 111, change(s) in the cross-sectional area or conductivity of the microstructure 111, or any other feature that may give rise to an electrical field when an electrical signal (e.g., a current) is applied.

For example, the sensor 110 may include an array (e.g., a planar array) of microelectrodes 112. The microstructure 111 may be beam, such as a cantilever beam (in which one end of the beam is substantially fixed while the other end is substantially free to move) or a fixed-fixed beam (in which both ends of the beam is substantially fixed). The sensor 110 may be in electrical communication with one or more bonding pads 113 (which may be provided on the sensor 110 or may be provided on the device 100) for connection to a signal source 300.

The microelectrode(s) 112 may be provided on, in or near the microstructure 111 by deposition, for example, using any suitable deposition methods (e.g., e-beam evaporation and sputtering, among others). In some examples, one or more microelectrode(s) 112 may be provided on the microstructure 111 while one or more other microelectrode(s) 112 may be provided near the microstructure 111. The microelectrode(s) 112 may include one or more metal/oxide layers. For example, the microelectrode(s) 112 may be made of a conductive metal material such as gold, platinum or silver, among others. The microelectrode(s) 112 may include chromium, titanium, or any other metal as an adhesion promoter with the microstructure 111. The microelectrode(s) 112 may be coated with a passivating layer (e.g., to protect the microelectrode(s) 112 from direct contact with the sample). The microelectrode(s) 112 may have similar or different compositions, shapes and/or properties, as appropriate.

The sensor 110 may include a sensing region (e.g., a sensing surface) on the microstructure 111 that may be a functionalized surface (not indicated) including one or more functional groups or compositions targeted towards (e.g., complementary to) the target material, or multiple target materials. The functionalized surface may serve to capture the target material(s) on the sensor 110 while non-target materials are removed from the sensor 110 (e.g., by washing or mechanical shaking), such that the response signal from the sensor 110 may be due to substantially only presence of the target material(s). Where a microelectrode 112 is provided on the surface of the microstructure 111, that microelectrode 112 may be coated with functional molecules to provide the functionalized surface.

The functionalized surface may be specific for a certain target material or be non-specific. For example, the functionalized surface may include one or more macromolecules specific for a biological target material. Such macromolecules may include, for example, antibodies, antigen-binding antibody fragments, enzymes and polynucleotides, among others. The macromolecules may be selected to be complementary to a known surface chemistry of the target material. For example, such specific binding may bind to the target material in a lock-and-key mechanism.

The functionalized surface may be non-specific but still sufficient to capture the target material(s) and not non-target materials. For example, the functionalized surface may include one or more macromolecules that provide sufficient discrimination between target material(s) and non-target materials, based on known properties (e.g., inherent charge, surface chemistry or mass) of the target material that differ from non-target material within a sample. Such macromolecules may include, for example, polyelectrolytes, charged polymers or non-specific binding proteins. Non-specific binding may include, for example, hydrophobic interactions, formation of ionic bonds and formation of hydrogen bonds (e.g., for binding to nucleotides such as DNA), among others.

For example, for capturing and detecting bacteria, the functionalized surface may be functionalized using a complementary antibody (e.g., poly-L-lysine), in order to electrostatically immobilize target bacteria that contact the functionalized surface. Antibodies (or other functional coatings) may be provided on the microstructure 111 by deposition, for example, using any suitable deposition techniques (e.g., by physical adsorption or chemical crosslinking, among others). Where the functional coating includes antibodies, monoclonal antibodies, polyclonal antibodies, and/or antibody fragments may be used as appropriate. The use of monoclonal antibodies and/or antibody fragments may allow for more cost-effective and/or more specific targeting of target material(s).

Different functionalization may be used for sensing of different target materials. For example, the sensor 110 may be used for the sensing of not only bacteria, but also other biological materials, including eukaryotic cells, yeast cells and protozoa, among others. The sensor 110 may also be used for sensing other organic or inorganic materials including viruses, or antigens conjugated to polymeric or inorganic particles in a liquid sample. The functionalized surface may be functionalized as appropriate for these and other different target materials.

Although described as a functionalized surface, this term may refer to any functionalized region of the sensor 110 including internal regions (e.g., surface of a pore) of the sensor 110.

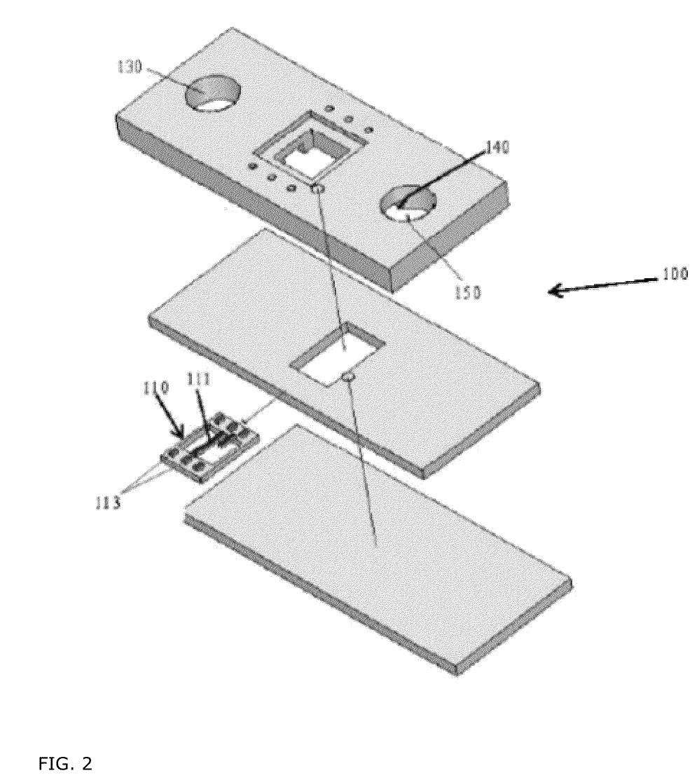

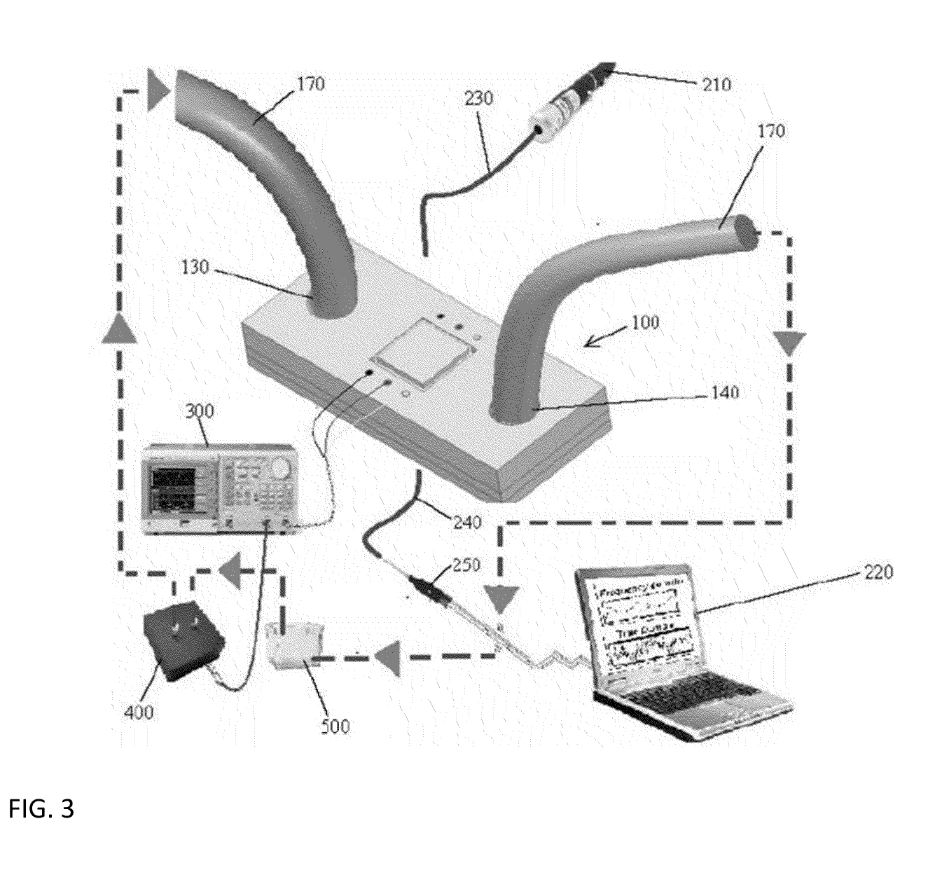

The device 100 may house the sensor 110 in a chamber 120. A sample (e.g., a liquid sample) to be tested may be loaded into the chamber 120. Where the device 100 is designed for flow-through sample detection (e.g., as shown in FIGS. 2 and 3), the chamber 120 may be in fluid communication with an inlet 130 and an outlet 140 to enable inflow and outflow of the sample, respectively. One or more microchannels 150 may provide fluid communication between the chamber 120 and each of the inlet 130 and the outlet 140. Alternatively, where flow-through testing is not required or not desired, the device 100 may not include the inlet 130, outlet 140 and microchannel(s) 150, and a sample to be tested may be introduced directly into the chamber 120. A transparent or translucent cover 160 may be provided over the chamber 120. One or more fluid conduits 170 may be connected to the inlet 130 and/or outlet 140.

In some examples, the device 100 may be fabricated from a suitable material such as polydimethylsiloxane (PDMS) on a microscope slide (e.g., made of borosilicate glass). For example, a PDMS slide with a pocket in the centre to define the chamber 120 may be bonded to a base glass slide. The PDMS slide may have a thickness substantially equal to the sensor 110 (e.g., about 0.5 mm). A cover PDMS slide may be bonded on the top to complete the chamber 120. The microchannel(s) 150 (e.g., having dimensions of about 150 μm×200 μm) may be patterned in the PDMS slide using any suitable techniques, such as etching. The PDMS slide may include a stepped pocket located above the chamber 120 to provide an observation window supporting the cover 160 (e.g., a thin glass cover slide). The PDMS slide may include one or more small through-holes (e.g., to accommodate pogo pins), which may be used to connect bonding pads 113 on the device 100 to connect to an external power (e.g., a signal source 300, described below). Such a device 100 may facilitate flow-through testing of a fluid sample, which may enable surface functionalization, device cleaning, collection of target material(s) and/or dynamic testing by simply changing the fluid introduced into the device 100 via the inlet 130.

The system may include a detector 200 for detecting a response from the sensor 110 and generating a detection signal. The detector 200 may include a laser source 210 (e.g., where the detector 200 includes a laser interferometer), that may produce a laser signal indicative of the response of the sensor 110. The detector 200 may include a processor 220, such as a spectrum analyzer, for processing the laser signal to produce a detection signal. In some examples, the processor 220 may be separate from the detector 200. The detection signal may indicate the frequency, phase and/or amplitude of resonance of the sensor 110, for example. In some examples, the detection signal may indicate a frequency, phase and/or amplitude change indicative of the presence of target material(s) on the sensor 110, in which case the target material(s) may be detected.

The laser source 210 may be configured to direct a laser beam towards the sensor 110 (e.g., through the transparent or translucent cover 160). The laser beam may be reflected off the surface of the sensor 110 and the reflected beam may be detected by a photodetector 250 (e.g., a photodiode) in the detector 200. Where the detector 200 includes a laser interferometer, this may provide laser interferometric monitoring of any vibrations of the sensor 110.

The detector 200 may include an emitter optical fiber 230 (e.g., a multimode optical fiber) coupled to the laser source 210 (which may be a low power laser) for directing emitted light from the laser source 210. The emitter fiber 230 may be positioned (e.g., above the chamber 120) to direct a laser beam through the cover 160 towards the sensor 110. A receiver optical fiber 240 (e.g., a multimode optical fiber) may be positioned (e.g., below the chamber 120) to receive the laser beam after reflection off the sensor 110 and to transmit the received laser signal to the photodetector 250 (a photodiode is shown in this example). Deflection (e.g., dynamic vibrations or quasi-static deformation) in the sensor 110 may change the laser signal (e.g., change the intensity of the laser signal) received by the receiver fiber 240, and consequently may change the signal generated by the photodetector 250. Other laser testing techniques, including those described in [32], may be suitable.

The processor 220 may monitor the laser signal (e.g., received via the photodetector 250) to monitor deflection of the sensor 110 (e.g., determining the frequency, amplitude and/or phase of vibrations) and may determine any changes in the dynamic (e.g., vibrations) and/or quasi-static (e.g., deformation) modes of the sensor 110. Such changes may be indicative of increased mass on the sensor 110 and/or a change in stiffness of the sensor 110, which may be due to the presence of target material(s) at the sensing region of the sensor 110. For example, target material(s) (e.g., bacteria) captured by the functionalized surface of the sensor 110 may change the sensor's 110 vibration performance (e.g., frequency, amplitude and/or phase) which change may be monitored and detected by the detector 200, and may result in a detection signal indicating that the target material(s) has been detected.

Other detectors 200 and other detection techniques may also be suitable. For example, the detector 200 may include a piezoelectric detector, where a change in deflection of the sensor 110 gives rise to a piezoelectric signal in the piezoelectric detector indicative of the change. In another example, the detector 200 may incorporate the sensor 110, such as where the microstructure 111 is one component of a capacitor-based detector, such that deflections in the microstructure 111 are detectable as changing capacitance of the detector 200.

In some examples, the device 100 may include one or more actuators, such as one or more excitation electrodes 180, for mechanical excitation of the sensor 110. The actuator may be positioned in the device 100 (e.g., near the sensor 110, such as under the sensor 110) to provide in-situ mechanical excitation to the device 100 via electrostatic force (or magnetic force, such as a Lorentz force), as described further below. In some examples, one or more microelectrode(s) 112 on the sensor 110 may serve as the excitation electrode(s) 180.

The system 1000 may include a signal source 300, such as a function generator, for providing an electrical signal to the microelectrode(s) 112 and optionally the excitation electrode(s) 180 (or other actuator). The signal source 300 may provide AC signals and/or DC signals to the microelectrode(s) 112 to create an electrokinetic force driving (and increasing local concentration of) target material(s) towards the sensor 110.

In some examples (such as where the device 100 does not include an actuator, such as an excitation electrode 180, for mechanically exciting the sensor 110), the system 1000 may include an actuator (not shown) to actuate the sensor 110 into a resonant mode. Such an actuator may be any suitable component including, for example, a piezoelectric element or a heating element. Another signal source (not shown) may provide an electrical signal to the actuator to cause actuation of the sensor 110.

Where the device 100 is designed for flow-through testing, the system 1000 may include a pump 400 (e.g., a piezo-pump) for pumping a fluid sample from a sample source (e.g., from a source such as a reservoir 500, which may be part of the system 1000, or another source external to the system 1000) into the inlet 130. In FIG. 3, an example flow-through system 1000 is illustrated, with an example path traveled by the sample fluid shown in dashed arrows.

### Example Operation

The disclosed systems, devices and sensors may be operated in various operating conditions. The present disclosure may employ one or more electrokinetic phenomena, such as DEP, EO, and electrothermal fluid flow, to drive target material(s) towards the sensor 110. For ease of understanding, example operations will be described with reference to microelectrode(s) 112. However, other features (such as resistive or capacitive features), including other electrical components (e.g., resistors or conductive materials) and microstructure features (e.g., changes in cross-sectional area or inherent resistance) may be used instead of or in addition to microelectrode(s) 112. In some examples, two or more spaced-apart microelectrode(s) 112 on the same unitary microstructure 111 may serve as a capacitive feature of the sensor 110.

An electric field may be created by the microelectrode(s) 112 when an electrical signal (e.g., from the signal source 300) is applied to the microelectrode(s) 112. Where there is only one microelectrode 112, the sample itself may serve as the ground. The generated electric field may give rise to the electrokinetic phenomenon(a).

The applied electrical signal may determine one or more characteristics of the generated electric field, as described further below. For example, alternating current (AC) and/or direct current (DC) signals may be used to generate an electric field that is AC, DC or a simultaneous or serial combination of both. Where the electric field is an AC electric field, the generated electric field may be sinusoidal, orthogonal, or any other periodic or random type. The generation of an electric field having two or more simultaneous or serial different AC frequencies (i.e., a multi-frequency electric field) may be also possible.

The electric field may be applied continuously or intermittently during operation (e.g., by controlling the electrical signal applied and/or by controlling the electrical pathway between the signal source 300 and the microelectrode(s) 112). Other regular or irregular electric fields may also be generated, depending on the applied electrical signal to effect different electrokinetic phenomena.

The voltage (i.e., potential difference) across oppositely charged microelectrode(s) 112 (or between a microelectrode 112 and ground) may vary (e.g., from about 0.1 V or less to about 100 V or more), for example to suit different modes of sensor operation, size of particles and/or sample properties. A suitable voltage range may be dependent on the application. Some considerations for the choice of voltage value may be whether or not it is desirable to avoid electrochemical effects, such as electrolysis, that may generate air bubbles and/or degrade the microelectrode(s) 112. Other factors to consider may include whether the microstructure 111 is intended to resonate in the linear region or non-linear regime. A higher voltage may lead to better signals and response. On the other hand, a lower voltage may help to avoid electrolytic breakdown, and may help to keep the microstructure 111 resonating in the linear regime, possibly at the expense of slower rate of collection and/or lower signal response.

### Discussion of Electrokinetics

The present disclosure, in various example aspects and embodiments, may employ the phenomenon of electrokinetics to drive target material(s) (as well as non-target material in some cases) towards the sensor 110. To assist in understanding the present disclosure, a discussion of electrokinetics is provided. This discussion includes various example equations, theories and models. However, these are not intended to be limiting and the present disclosure is not bound by any such equations, theories or models.

One or more of the phenomena described below may be effected by the disclosed systems 1000, devices 100 and sensors 110. The sensor 110 may be designed (e.g., with different microelectrode 112 and/or microstructure 111 size, shape and/or configurations) to control how material may be driven by electrokinetic effects, for example based on the equations, theories and models provided herein. The following discussion may make reference to particles as the driven material, as an example.

### AC Electrokinetics

AC electrokinetics may generally describe the effects of an alternating electric field on an electrical double layer, charged particles and/or induced electric dipoles in particles. These forces may influence the movement of particles and/or the fluid and may help to improve the collection of material (including target material(s)), typically material in an aqueous environment. Electrokinetic phenomena may effect certain forces on target or non-target material(s) in a fluid sample. Such forces may include: drag forces due to electrokinetic fluid flows, which may include EO and electrothermal flow, and/or particle polarization forces, which may include DEP.

In particle DEP, a non-uniform electric field may act on a polarizable particle.

When acting on a fluid, an AC electric field can cause deterministic motion by producing an AC electrokinetic force, AC EO, at relatively low frequencies and an electrohydrodynamic force, electrothermal flow, at relatively high frequencies. These forces can create non-uniform streamlines to convex and mix [72] and/or to separate a mixture of particle sizes [74].

Typical bioparticles, including cells and viruses, behave as dielectrically polarized particles in the presence of an external electric field. Using AC electric fields for particle manipulation may allow operation at relatively low voltages, which may be useful for implementation in portable devices (e.g., a portable embodiment of the disclosed device 100) and for reducing or avoiding unintentional electrolysis and chemical reactions.

Electrokinetics may help to improve the rate of analyte mass transport from the bulk sample to the sensor 110. Another use of electrokinetics may be to control the spatial distribution of analytes on the sensor 110. Understanding the particle trajectories inside the control volume system may assist in better understanding of the present disclosure.

### Theory of Electrokinetics

The electrical domain is first defined. The analysis of a system begins by setting up Laplace's equation, ∇²φ=0, to describe the electric potential φ in the control volume system. Boundary conditions are then defined. For surfaces with zero potential (such as insulated walls or the substrate), the normal component of the electric field are described by n·∇φ=0, where n is the surface unit normal vector. For electrode-electrolyte surfaces, a basic model to describe the potential may be:

$$n \cdot {σ}_{f} ∇ \tilde{φ} = j \frac{ {ωɛ}_{f} Δ ( \tilde{φ} - {V}_{p} )}{{λ}_{D}} \qquad ( 1 )$$

Where σ_{f} is the conductivity of the medium, ∈_{f} is the permittivity of the medium, λ_{D} is the Debye screening length, \tilde{φ} is the potential of the extent of the double layer, Vₚ is the applied potential to the p-th electrode, ω is the frequency of the applied potential and j=(−1)^{0.5}.

The electrical system may be solved to determine the electric field distribution in the control volume.

### Dielectrophoresis

DEP is a force acting on the induced dipole of a polarizable particle (even for a charge-neutral particle) in a suspending fluid due to the presence of a non-uniform electric field [74]. In contrast to some other electrokinetic phenomena that generate a force on a particle due to viscous drag, DEP force may be considered more of a direct force acting on the particle.

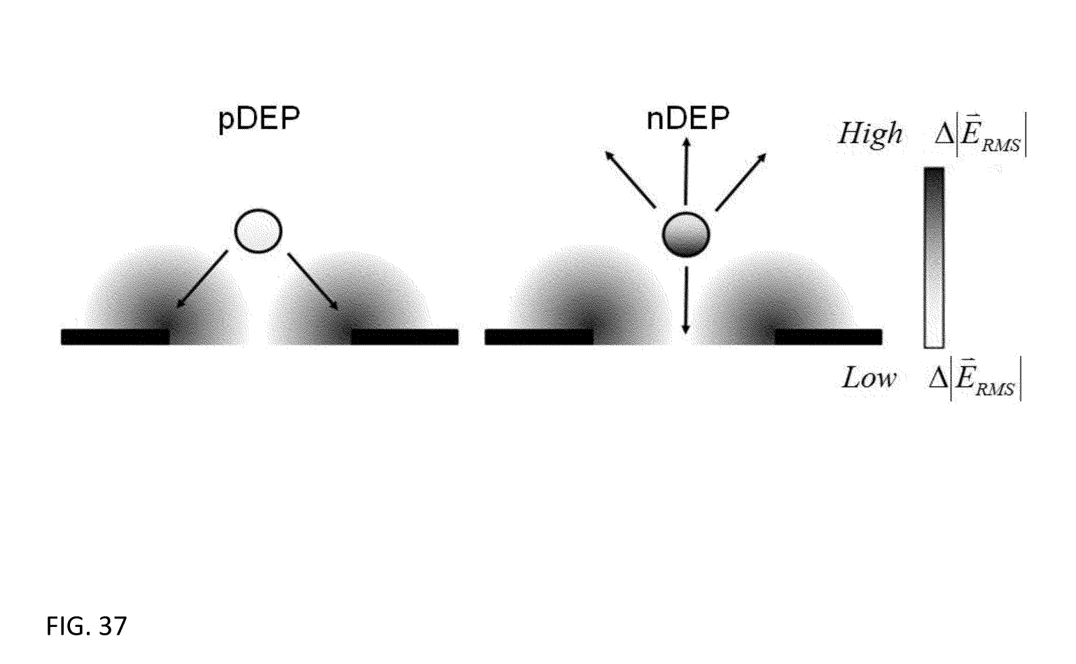

DEP was first used to remove suspended particles from a polymer solution and named by Pohl. In brief, if a particle, such as a bacterium or virus, is more polarizable than the surrounding medium, the particle undergoes positive DEP (pDEP) and tends towards areas of high electric field gradients (FIG. 37, left image, where electrodes are represented by black horizontal bars). If a particle is less polarizable than the surrounding medium, it undergoes negative DEP (nDEP) and tends towards areas of electric field gradient minima (see FIG. 37, right image).

The first order time averaged DEP force for a spherical particle in an electric field with a constant phase is presented in equation (2) [15].

$$\begin{matrix}< {\vec{F}}_{DEP} >= 2 {πɛ}_{M} {r}_{p}^{3} R [ {\tilde{K}}_{e}^{*} ] ∇ {\vert \vec{E} \vert}^{2} & ( 2 ) \\ R [ {\tilde{K}}_{e}^{*} ] = \frac{{ɛ}_{P}^{*} - {ɛ}_{M}^{*}}{{ɛ}_{P}^{*} + 2 {ɛ}_{M}^{*}} & ( 3 )\end{matrix}$$

Equation (2) shows that the DEP force (F_{DEP}) is a function of a particle's size (r_{P}), and the real part of the Clausius-Mossotti factor (equation 3) which is a function of the medium's complex permittivities (∈*_{P} for the particle and ∈_{M} for the medium) as well as the gradient of the applied electric field (∇|\vec{E}|²).

The real component of the Clausius-Mossotti factor shows the relative polarizability between the medium and the particle. When the real component is greater than zero, the particle experiences pDEP where the direction of the force is towards regions of high electric field intensity (i.e., towards the microelectrode(s) 112). The reverse is true when the real component is less than zero, where the particle will experience nDEP and move towards regions of low electric field intensity (i.e., away from the microelectrode(s) 112).

Since the force of DEP varies with particle size and the electric field gradient, it may allow for separation between different sized particles (e.g., cells). By measuring the velocities of single particles as a function of distance and voltage, DEP can be used to characterize their electrical properties [75].

In some examples, the disclosed sensor 110 may effect DEP by using microelectrode(s) 112, in order to amplify concentration of material (including target material(s)) at or near the sensor 110. The use of DEP may cause the deterministic motion of particles. The range of the DEP effect may be dependent on the system configuration (e.g., microelectrode placement and/or geometry), the properties of the liquid and material, the applied signal, and/or any competing forces governing particle motion within the system. Successful collection of material by only DEP forces may occur where the DEP force contribution outweighs other force terms influencing particle motion. For example, in a closed system considering only particle Brownian motion, with coplanar electrodes, this condition may be described by the spatial boundary whereby the DEP force becomes larger than the competing thermal force term. Within this boundary, particles may be under the primary influence of DEP. One such example is described in reference [81]. In the present disclosure, forces in addition to DEP may contribute to collection of material. For example, bulk viscous flow (e.g., electrothermal flow) may introduce longer range effects than DEP forces.

The same electric field effecting DEP can have an effect on the sample medium as well, for example through electrothermal and/or EO effects (described further below). Generation of an electric field may thereby overcome diffusion limitations by enabling both a short-range force (e.g., DEP) near the microelectrode(s) 112 and a mid-range force (e.g., electrothermal and/or EO effects) by causing desirable fluid flows from the bulk to the local area of the sensor 110 [76].

DEP may be useful for manipulating where material is collected on and/or in the sensor 110 because DEP may act as deterministic forces on the particles and may be controlled by patterning the microelectrode(s) 112 in a suitable manner. DEP may also be used to create particle “traps” using either pDEP or nDEP.

Since pDEP tend to direct particles to high field regions, pDEP may have a tendency to drive particles to edges of the microelectrode(s) 112. As such, the sensor 110 may be designed with microelectrode(s) 112 having edges that direct particles to select regions on the microstructure 111 (e.g., towards regions that effect greater changes in deflection or resonance of the microstructure 111).

Reducing electro-gap spacing and/or increasing the sharpness of the geometries of the microelectrode(s) 112 may also increase DEP force due to the increased non-uniformity of the electric field in the vicinity of the electrode(s) 112.

DEP forces in a system may have distance dependency due to the gradient of the electric field squared. Typically, for planar microelectrode(s) 112, most of the non-uniformity may occur near the vicinity of the microelectrode(s) 112.

In some examples, it may be difficult to control particle motion through DEP. For example, in a high conductivity medium, particles may only experience nDEP. By understanding the expected environment where the sensor 110 is intended to operate, appropriate design changes may be made. In some cases, the sensor 110 may be designed to enable both pDEP and nDEP. For example, a sensor 110 having two or more microelectrodes 112 on a single unitary microstructure 111 (e.g., on the same beam) may have an enhanced capability to enable both pDEP and nDEP.

### AC Electroosmosis

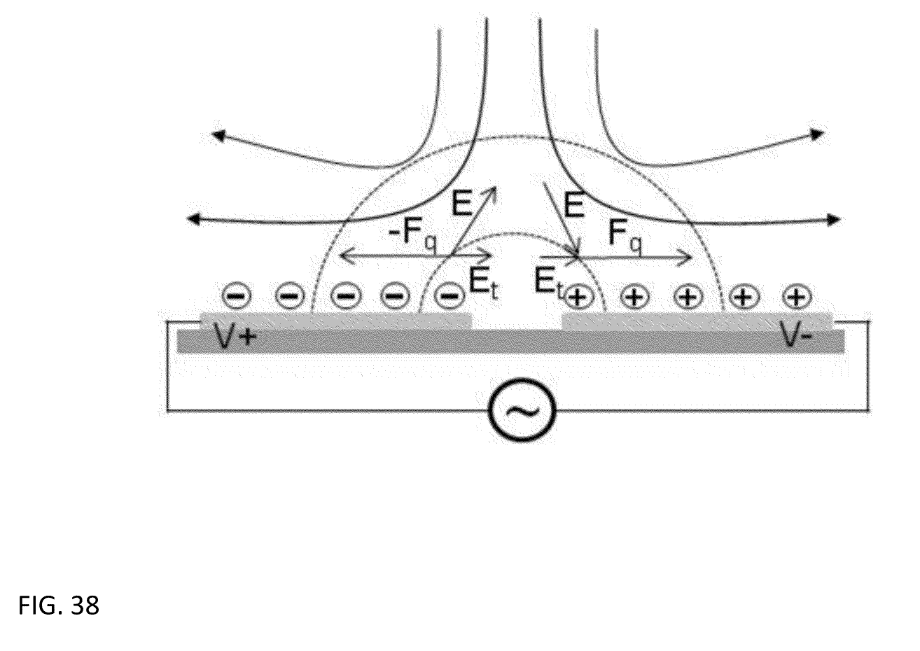

EO is described in detail in [35, 70, 71], for example. AC EO (ACEO) flow is typically produced from the interaction of the non-uniform electric field and the diffuse electrical double layer formed by the polarization of an electrode (e.g., the microelectrode 112) by the counter ions in an electrolyte solution (see FIG. 38).

FIG. 38 (adapted from [74]) shows a mechanism for ACEO. The arrows indicate fluid flow driven down towards the electrode gap and out along the surface of the electrode (indicated by horizontal bars) due to the force of the tangential component of the electric field on the ions in solution.

The tangential component of the electric field (Eₜ) at the electrode surface applies a force (F) on the ions present on the electrode, pushing them out across the surface of the electrode and thus dragging fluid down into the center of the gap.

ACEO is a function of the surface charge density (σ_{qo}), fluid viscosity (η), the Debye length (κ⁻¹) and the tangential component of the electric field (Eₜ).

The movement of ions may be considered to cause a “slip” fluid velocity to develop at the electrode surface due to the electric field component that is tangent to the surface acting on the ions. This may be modeled in the fluid domain as a time averaged ‘slip’ velocity boundary condition on the electrode surface, [symbol] u [symbol] , which may be described as:

$$〈 u 〉 = - \frac{{ɛ}_{f}}{2 η} Λ Re [ ( \tilde{φ} - {V}_{p} ) t \cdot {\tilde{φ}}^{*} ] \qquad ( 4 )$$

Where η is the viscosity of the fluid, Λ is a correction factor to account for the Stern layer, and t is the surface tangent unit vector. The conventional incompressible Navier-Stokes equations (below) and mass continuity conditions of ∇·u=0 are applied and solved for the flow velocity in the control volume.

$${ρ}_{f} [ \frac{\partial u}{\partial t} + ( u \cdot ∇ ) u ] + ∇ p - u {∇}^{2} u - 〈 f 〉 = 0 \qquad ( 5 )$$

Where ρ_{f} is the fluid density, u is the fluid velocity vector, p is the pressure and [symbol] f [symbol] is the body force.

Equation (4) may be used to describe the boundary condition of the electrodes in a finite element simulation. This equation describes what may be referred to as the “slip velocity”′ condition at the electrode surfaces due to the applied electric field generating electroosmotic (EO) flow. This equation describes the tangent velocity at the electrode surface only.

With the boundary condition for the electrodes described by the prior equation, Equation (5) may be then used to simulate the actual viscous flow profile within the entire control volume.

Both equations may be used together to simulate the environment behavior for flow velocities within the control volume. This then helps to determine the drag forces within the control volume due to EO flow.

The circuit formed across the medium can be represented in a simplified manner. The electrical double layer at each of the electrodes is represented by a capacitor while the medium acts as a resistor. Therefore, the circuit can be described as a capacitor in series with a resistor follow by another capacitor.

The magnitude of ACEO flow is expectedly a function of the properties of the fluid, surface and applied signal. Moreover, there is a frequency dependency of ACEO flow due to the capacitive charging nature of the electrode-electrolyte equivalent circuit and for which the maximum ACEO velocity normally occur at the inverse RC relaxation time of the circuit. This can be of the order of up to hundreds of kHz depending on the system and may rapidly decay at higher frequencies.

ACEO typically dominates at frequencies between about 100 and about 100,000 Hz while above about 100,000 Hz, AC electrothermal flow may be predominant [74]. At lower frequencies, due to the presence of counter-ions near the electrode surface, the majority of the potential typically drops across the double layer near the electrodes. Therefore, the remaining voltage drop across the medium may be small in comparison. The capacitance of the double layer is inversely proportional to frequency and at high frequencies the capacitance may become negligible resulting in a relatively small voltage drop across the double layer. For an irrotational electric field, the tangential component is expected to be constant between the two electrodes. If the potential drop across either the medium or the electrical double layer is negligible, the tangential component of the electric field may be weak. Therefore, the resulting velocity due to ACED may be negligible.

In the disclosed sensor 110, the flow profile caused by ACEO may be dependent on the design and/or geometric placement of the microelectrode(s) 112. Each design may be analyzed to determine specific flow profiles. For example, particle drag forces for spherical particles can be estimated using Stoke's law.

Typically, symmetric microelectrode 112 pairs may generate sustained ACEO re-circulating vortices, while microelectrodes 112 with broken symmetry (e.g., microelectrode 112 pairs with different geometries, dimensions and/or height) may sometimes induce net flow. The presence of net flow or re-circulating vortices may be useful for creating advection of material, for example, to improve mass transfer to the sensor 110.

### Electrothermal Flows

Electrothermal flow is described in detail in [33, 34], for example. ACEO and electrothermal effects may produce similar flow patterns in some cases, but they may be considered to be of different origin.

Temperature distribution within a bulk medium is often not homogeneous. Temperature gradients are often unavoidable due to fluctuating environment conditions and possibly ohmic heating of the bulk due any applied electrical potential. Electrothermal flow arises by uneven temperature in the fluid (e.g., due to uneven Joule heating of the fluid), which gives rise to non-uniformities in conductivity and permittivity. These non-uniformities are affected by the presence of an electric field which in turn generates flow, typically in circulating patterns [78]. This is often more significant for mediums of higher conductivities.

The time averaged body force on the medium responsible for the generation of electrothermal fluid flow for a constant phase electric field is presented in equation (6) [77].

$$< {{f}^{->}}_{e} >= \frac{1}{2} \frac{{ɛ}_{m} ( α - β )}{{σ}_{m}^{2} + {( {ωτ}_{CR} )}^{2}} ( ∇ T \cdot {E}^{->} ) {E}^{->} - \frac{1}{4} {ɛ}_{m} α {\vert {E}^{->} \vert}^{2} ∇ T \qquad ( 6 )$$

where E is the electric field, T is temperature, α and β are the effects of temperature on the gradients of permittivity and conductivity respectively (specifically,

$$α = ( \frac{1}{{ɛ}_{f}} ) ( \frac{\partial {ɛ}_{f}}{\partial T} ) \\ and \\ β = ( \frac{1}{{σ}_{f}} ) ( \frac{\partial {σ}_{f}}{\partial T} ) ) ;$$

and τ_{CR}, the charge relaxation time of the medium defined as the ratio of a medium's permittivity (∈ₘ) to its conductivity (σₘ). The first term on the right hand side of equation (6) is the Coulombic contribution while the second term is the dielectric contribution to the total force. The Columbic term dominates at low frequencies while the dielectric term dominates at higher frequencies and the cross over frequency is the same order as a/E, the inverse of the charge relaxation time [79].

With the electrical domain solved, an energy balance is applied to first solve for the thermal domain:

$${ρ}_{f} {c}_{p} \frac{\partial T}{\partial t} + {ρ}_{f} {c}_{p} ( u \cdot ∇ ) T - ∇ \cdot ( {k}_{f} ∇ T ) - {σ}_{f} {\vert E \vert}^{2} = 0 \qquad ( 7 )$$

Where cₚ is specific heat at constant pressure, T is temperature and k_{f} is fluid thermal conductivity. Together with the solution from equation (6), [symbol] f_{E} [symbol] is solved and applied to satisfy incompressible Navier Stokes equations and the continuity equation.

With the velocity profile determined, it becomes possible to determine drag forces on particles using a number of valid assumptions, such as Stoke's law for spherical particles.

### Sensor Design

The shape, physical dimensions, and spatial arrangement (i.e., configuration) of the microelectrode(s) 112 (or other features, such as other electrical components or inherent features of the microstructure 111, for generating an electric field) on or near the microstructure 111 may be design parameters that may be tailored for various applications. Although various sensor 110 examples are disclosed herein, other designs may be possible within the scope of the present disclosure.

For example, as described further below, the sensor 110 may be designed based on consideration of one or more of the following: mode of sensor operation, type of target material(s), properties of the fluid sample, and microstructure dimensions. These and other considerations may influence the shape, dimensions and/or configurations of the microelectrode(s) 112 or other electric field-generating features.

### Mode of Sensor Operation

The sensor 110 may be operated under conditions of nDEP, in which material may tend to collect near the centre of a microelectrode array. This operation may be due to a relatively focused electric field, which may be generated by quadrupolar or multipolar microelectrode geometries (as in various disclosed examples, such as the example of FIG. 4). Here, the design may be to increase the area at or near the centre of the microelectrode pattern, where material is expected to collect. Similar design considerations may be used for other electric field-generating features.

In the opposite case (i.e., pDEP), material may tend to collect at or near the edges of the microelectrode(s) 112. Although multipolar microelectrodes 112 may be used, simpler configurations may also be possible (e.g., two “finger” microelectrodes 112), which may increase the length of the microelectrode edges, where collection of material is expected to take place. Examples of this may be found in the examples described below where microelectrodes 112 coupled onto a microstructure 111 increase the electrode edge region on the microstructure 111, thereby improving the area of collection.

Other electrokinetic phenomena, including EO and electrothermal fluid flow (e.g., as described above), may occur simultaneously with pDEP and/or nDEP.

Microelectrode design, physical dimensions, and/or spatial arrangement may affect the strength of these phenomena, and hence may affect the net/combined effect of particle collection by the electric field.

### Type of Target Particles

As explained above, the strength of the DEP force is dependent on the particle volume (rₚ³) and the gradient of the electric field squared (∇E²). To compensate for the size of smaller particles (e.g., for detection of smaller bacteria, or viruses), stronger electric field gradients may be used.

A stronger electric field gradient may be achieved by decreasing the separation or gap between oppositely charged microelectrodes 112 and/or employing microelectrodes 112 with more features having higher curvatures (that is, “sharper” features).

The desired strength of the DEP force may be calculated based on the expected size of the target material(s), and the microelectrode(s) 112 (or other electric field-generating feature) may be designed to achieve or approach the desired DEP force strength using appropriate design techniques.

### Properties of the Fluid Sample

As explained above, the ionic strength (that is, amount or concentration of ions) of the liquid sample containing the target material(s) may influence the mode of DEP that is expected to occur. A general rule of thumb may be that, when the electrical conductivity of the sample medium is higher than that of the target material(s), nDEP may be expected to take place. This may be the case in, for example, biological fluids (e.g., blood samples) or other fluids having relatively high concentration of electrolytes. In the opposite case, such as for samples of potable water where the electrolyte concentration is expected to be relatively low, pDEP may be expected to occur. The mode of DEP may govern the selection of an appropriate design for the microelectrode(s) 112. For example, as described above, where pDEP is expected to occur, the microelectrode(s) 112 may be designed such that one or more edges of the microelectrode(s) 112 (or other electric field-generating feature) coincide with desired regions for collecting material on the sensor 110. On the other hand, where nDEP is expected to occur, the microelectrode(s) 112 (or other electric field-generating feature) may be designed such that one or more electrode gaps coincide with desired regions for collecting material on the sensor 110.

A carrying fluid having relatively high ionic strength may tend to favor the intensity of electrothermal fluid flow, whereas relatively low ionic strength may result in EO being the dominant mechanism of material transport to the sensor 110. Again, different microelectrode designs may be used depending on the desired effect. For example, the expected material transport path may be simulated for different microelectrode designs, according to EO or electrothermal flow models.

For example, the geometry of the microelectrode(s) 112 may influence EO flow in the sense that symmetric microelectrodes 112 commonly generate recirculating vortex flows, while asymmetric microelectrodes 112 may generate time-averaged directional flow in the vicinity of (e.g., about tens of micrometers above) the microelectrodes 112 due to asymmetric flow vortex.

For electrothermal (ET) flows, the microelectrode(s) 112 (possibly with the geometry of the sensor 110) may influence the electric field distribution and/or where Joule-heating of the fluid may occur. This may lead to changes to the flow profile. Usually joule heating is greatest at or near the central region between microelectrodes 112 and away from thermal-boundary conditions (which are often at a cooler temperature than the Joule-heated media).

The frequency dependency of the magnitude of the contribution of each electrokinetic phenomenon may depend on the properties of the sample fluid. Generally, though not necessarily a rule, EO flow is expected to be more significant at lower frequencies while ET flow is expected to be significant over a wider band of frequencies and expected to have influences at higher frequencies than EO.

Typically, a suitable microelectrode design may be arrived at from numerical simulations that link the microelectrode geometry to the intensity of the expected electrokinetic phenomenon(a) for a given fluid sample.

### Microstructure Dimensions

The overall surface area available for location of microelectrode(s) 112 (or other electric field-generating feature) on the microstructure 111 may also influence the microelectrode arrangement to be used, the spacing between the microelectrode(s) 112, and/or the overall length of a microelectrode array.

Since the sensor 110 may be mechanically responsive, it may be useful, when designing the sensor 110, to consider design implications on the performance of both the mechanical resonator (i.e., the microstructure 111) and the layout of the microelectrode(s) 112 (or other electric field-generating feature) used to elicit electrokinetics. In some cases, there may be competing interests when trying to improve the performance of each function. For example, on one hand total quantity of analytes collected may be improved by designing larger and more microelectrodes 112 on the microstructure 111, however a larger network of microelectrodes 112 and a larger surface area of the microstructure 111 may lead to a reduced mass-responsivity for the sensor 110. In some cases, the net effect of a higher collection may not outweigh the negative influence of a reduced mass responsivity.

By considering and modeling various contributing factors related to electrokinetics, it may be possible to plot out the total expected force field produced by the microelectrode(s) 112 (or other electric field-generating feature) in a control volume (e.g., within the chamber 120). This can help to create a representation of expected particle trajectories. Test particles can then be introduced into the model at different positions and tracked, or streamline representations may be used, to represent the expected trajectory of existing and/or introduced materials in the device 100.

Other contributing forces may be considered, which may include gravity, other force terms such as centrifugal forces, other drag forces terms (e.g., due to bulk fluid flow, such as due to pressure driven flow in the microchannel 150), among others

When designing the sensor 110, it may be desirable to enhance the rate of collection of material (in particular target material(s)). Electrokinetic effects may help improve mass transport of target material(s) to the sensor 110. It may also be desirable to design the sensor 110 to encourage better conditions for particle collection and/or encourage target material(s) to adsorb to the sensing region of the sensor 110 (e.g., the functionalized surface of the sensor 110).

Such design may be based on knowledge of the target material(s) to be sensed, their properties as well as the sample medium and its properties. Excitation conditions may be selected for any given sensor design to help enhance overall collection based on the excitation characteristics (including frequency and applied electrical potential).

Generally, reducing gap spacing between microelectrodes 112 and increasing the sharpness of microelectrode features may help to increase electric field non-uniformity which is expected to assist in creating stronger DEP forces on material.

It may also be desirable to control the spatial distribution of the target material(s). This can be done with polarization forces and/or with fluid flow.

DEP force has been found to be an effective method for controlling the spatial distribution of adsorption of target material(s). Both pDEP and nDEP can be used. Typically, for nDEP, the lowest field region occurs at a position slightly above the surface plane of planar microelectrodes 112, therefore collection to enhance surface contact may not be as efficient or direct. On the other hand, pDEP is typically strongest at the high field regions, which is typically at the microelectrode edges. This may make designing microelectrodes 112 for pDEP-based material collection relatively simple, for example by design of the microelectrode edge positions, such as described above.

Other phenomena and effects not discussed herein, such as electrorotation, traveling wave DEP, and others, may also play a role in driving material to the sensor 110 and suitable techniques (e.g., simulations) may be used to consider such phenomena when designing the sensor 110.

### Design for Mass Transport to the Sensor

The efficiency and/or effectiveness of mass transport of material from the sample environment to the sensing region of the sensor 110 may affect the temporal performance and/or the reliability of material collection by the sensor 110.

Materials experiencing slow rate of mass transport to the sensor 110 may increase the measurement time. Materials mass-transported away and/or adsorbed onto non-sensing regions (whether on the sensor 110 or elsewhere on the device 100, such as the walls of the chamber 120) may become non-detectable and may thus affect the sensitivity of the device 100. One or more electrokinetic phenomena elicited by the sensor 110, such as described above, may be used to improve the rate of mass transport to the sensor 110 and/or improve collection efficiency.

Material trajectories in the device 100 may be influenced by (among other factors): gravity, particle-surface and particle-particle interactions, bulk advection and diffusion. Trajectories may also be a function of one or more electrokinetic forces at play.

One or more electrokinetic phenomena, when used under suitable conditions, may help to enhance the overall rate of material transport from the sample environment to the sensor 110 (in particular to a sensing region of the sensor 110). This may help to improve the probability of capturing material and/or achieving material-loading. An improved rate of material transport may translate to reduced measurement time required to detect a certain quantity of the target material(s).

One or more electrokinetic phenomena may also improve material detection sensitivity. For example, by manipulating material trajectories within the device 100 to be more directed towards the vicinity of the sensor 110, reliability and probability of capturing the target material(s) from the sample environment may be improved. In so doing, the likelihood of material escaping collection and detection, such as by adsorbing onto non-sensing regions or being transported away (e.g. by diffusion or bulk advection), may be reduced.

Enhancing efficiency of collecting material may be particularly useful for environments with lower concentrations of the target material(s) and/or larger sample volumes.

### Control of Material Distribution on Sensor

As described above, the sensor 110 may act as a microresonator whose frequency, phase and/or amplitude of resonance may change in response to the presence of material (including target material(s)) coupled to the sensor 110. Dynamic properties (e.g., vibrational properties) of microresonators may be sensitive to the quantity of material adsorbed to the sensor 110 (e.g., on the surface of the sensor 110 and/or sequestered internally in the sensor 110) and/or their positions of adsorption.

Conventionally, for systems without bulk advection, adsorbate distribution on a surface is typically relatively random and uniform, assuming material was evenly distributed in the sample environment and boundary effects are ignored. For example, gravity sedimentation of material onto a flat surface in a closed system is often uniform and random.

In the disclosed systems, devices and sensors, electrokinetics may enable deterministic control of the distribution and/or density of material adsorbed on and/or in the sensor 110. This may enable enhancement of mechanical performance (including resonant response) of the sensor 110 itself.

Use of electrokinetics to control spatial distribution of adsorbed material on and/or in the sensor 110 may also provide one or more of the following advantages: increase in mass-responsivity of the sensor 110, higher precision measurement, unique detection methods to gauge precision of measurements, and ability to redirect different material to different regions on the sensor 110 which may enable detection of multiple different target materials.

The ability to control adsorbate spatial distribution on the sensor 110 may enable loading of material at preferred position(s) that may give rise to greater mass-responsively (Hz/g) of the sensor 110. For example, material may be distributed to or near positions of greater or maximum dynamic displacement (also referred to as antinodes) for a given resonant mode of the sensor 110. For example, when considering the pDEP effect, microelectrode(s) 112 may be designed to have edges at known positions of greatest dynamic displacement for a given resonant mode of the sensor 110.

Electrokinetics may also be used to limit material adsorption to non-preferred regions on the sensor 110. Typically, material adsorbed on the microstructure 111 can both increase the mass and the stiffness of the microstructure 111. However, stiffness increase accompanying mass increase can be counter-productive to producing a strong response in the sensor 110 (e.g., a strong frequency shift). By restricting adsorption of material to specific preferred regions of the microstructure 111, stiffness changes to the microstructure 111 due to material-loading in other non-preferred regions of the microstructure 111 may be reduced.

The ability to control distribution of material may also be useful for facilitating precision measurements with the sensor 110, particularly where it may be otherwise difficult, impossible or impractical. For example, in typical scenarios where material distribution is random, repetition of the same experiment under similar conditions may yield a different response, even when total quantity of target material(s) remains constant. This can be related to random variations in material adsorption positions on or in the sensing region. By confining the regions where material can adsorb onto the sensor 110, measurements of the same quantity of target material(s) may become more repeatable and/or reproducible. This may provide improved reliability, which may enable a given sensor response to be referenced to an expected quantity of target material(s). In this way, calibration standards can be created to assist precision measurements (e.g., for use in the field).

The ability to control material distribution may also be useful for facilitating measurement of material dispersion emanating away from a known region of enhanced collection. This may be done by applying the null-sensitivity criterion of eigenfrequencies to masses that load at one or more nodes of the sensor 110. In this example, certain eigenmodes may be used for conventional detection, while other higher-order modes may be used to measure the level of material dispersion from the known collection region. The null-sensitivity criterion may be where the nth-eigenfrequency is expected to have no frequency shift when mass is loaded at the nodes of that nth-mode. By relying on this null-sensitivity criterion, lower dispersion of material from the collection region may be expected to result in little or no frequency shift of a given resonant mode. On the other hand, larger dispersion of material from the collection region may be expected to result in a larger frequency shift of a given resonant mode. Electrokinetics may help to concentrate material to specific region(s) on the sensor 110, which may enable unique and unexpected mechanical detection techniques that may be used to determine the dispersion of a concentrated quantity of material.

For example, electrokinetics may be used to focus particles to a specific location on or near the microstructure 111. Fundamental and higher-order resonant frequencies are expected to be sensitive to material-loading positions on the microstructure 111. Material-loading at the nodal positions of a resonant mode is expected to lead to zero frequency shift. This may be referred to as the “null-sensitivity” criterion. For purposes of material sensing it may be desirable for the material to load on the microstructure 111 anywhere but at the resonant nodes. Higher-order resonant modes may be used to detect adsorption of material away from the expected region of collection.

For example, electrokinetics may be used to concentrate material to a specific region on the microstructure. Certain resonant modes may be used for actual detection of material collected in an expected central region. At the same time, other higher-order modes may have nodes that occur where the material is collected, and such higher-order modes may be used to measure dispersion of the adsorbed material away from the expected region of adsorption by exploiting the null-sensitivity. Thus, for a low dispersion adsorption profile, these higher-order modes may be expected to exhibit little or no resonant shift (e.g., shift in frequency, amplitude and/or phase) due to null-sensitivity. If adsorption dispersion is high, these modes may be expected to show more resonant shift.

Thus, the present disclosure may employ resonant modes for detection, and may employ other special higher-order resonant modes that may help determine dispersion based on the null-sensitivity criterion.

The ability to design for and control distribution of material may also be useful for detecting different types of target materials using a single sensor 110. For example, target materials may differ not only by taxonomy, but by other properties such as electrical properties. For example, bacteria under certain electrical driving conditions may experience either pDEP or nDEP (e.g., depending on if the same species of bacteria are alive or dead). These dead or alive bacteria of the same species may still be expressing the same surface antigens prior to any appreciable degradation occurring. Therefore, they may both be captured by the functionalized surface. Electrokinetics may enable the bacteria to be adsorbed at different regions of the sensor 110 to enable a simultaneous readout of both alive and dead bacteria, for example using the null-sensitivity criterion of microstructure eigenfrequencies described above. Electrokinetics may also enable rejection of certain cell types from being sensed.

For example, a sensor 110 having a chemically mono-functionalized or multi-functionalized surface may employ electrokinetics to limit exposure of select areas of the microstructure 111 to select types of target materials coexisting in a sample environment. In doing so, non-specific binding by the target materials may be reduced, which may help to improve detection reliability. This may be useful for different types of target materials that share similar association constants, which may make them suitable for retention by surface receptors (which may increase odds of non-specific binding). In other words, by electrokinetically routing different target materials to different positions on the microstructure 111, detection of multiple types of target materials at or about the same time may be facilitated. For example, the null-sensitivity criterion may enable the sensing of different target materials to be reflected in different mechanical modes.

Differentiation between different types of target material may be based on, for example, different target material having different electrical properties, and/or mechanical null-sensitivity of the resonator. For example, certain cells may experience slightly different electrical properties depending on whether the cell is dead or alive. This can be attributed to cell membrane damage on dead cells allowing cross-membrane diffusion to occur more readily with the bulk sample, thereby changing internal properties, for example. Other conditions that change the electrical properties of a target material may also occur. These and other such conditions may be used to distinguish between different types of material.

For example, the sensor 110 may be configured with an arrangement of microelectrodes 112 (e.g., having two or more microelectrodes 112 on a single unitary microstructure 111) such that the sensor 110 has regions for pDEP collection as well as for nDEP collection of material, either simultaneously or serially. The expected result is that material of one type experiencing pDEP collects in one region, while material of another type experiencing nDEP collects exclusively in another region. Using the null sensitivity criterion, the material-loading contributions due to each type of material may be de-coupled, depending on their location. This may enable independent response signals in response to each type of material using the same microstructure 111. That is, the nodes of one particular resonant mode may be designed for collection of one type of material while the nodes of another different resonant mode may be used for collection of a different type of material, within the same microstructure 111. In such a case, the frequency shift due to material-loading by different types of material may be de-coupled and independent of each other. This may enable simultaneous (and/or serial), independent sensing of more than one type of material using the same sensor 110.

### Selectivity Towards Target Material(s)

Selectivity of the sensor 110 towards the target material(s) may be provided by surface functionality (e.g., in the functionalized surface of the sensor) and/or other upstream separation of material and sample preparation processes. Electrokinetics may provide additional localized discrimination capabilities, which may help to further improve selectivity towards the target material(s).

For example, material may be separated by their relative polarizability (e.g., the Clausius-Mossotti factor) based on whether a given material experiences pDEP or nDEP under a given driving condition. Conventional fluid mechanics separation techniques may also be employed for material separation, with fluid flows that may be electrokinetically driven. For example, material can be sorted by particle properties (e.g., mass or geometry) using micro-vortexes that may be created through electrokinetic effects (e.g., EO or electrothermal flow), based on known or expected properties of the target material(s) and/or non-target materials.

### Mechanical Excitation of Sensor

Where the sensor 110 is intended to operate as a microresonator, mechanical excitation of the sensor 110 may enable measurement of its dynamic properties.

The mechanical excitation signal may be provided by or independent of the electrical signals used for eliciting electrokinetic phenomenon(a). Mechanical excitation and electrokinetic manipulation need not occur simultaneously. For example, electrokinetically enhanced material-collection (e.g., during which electrical signals may be provided to the microelectrode(s) 112 to cause electrokinetic effects) and detection of target material(s) (e.g., during which excitation signals may be provided to the excitation electrode(s) 180 to cause mechanical excitation of the microstructure 111) may occur as separate serial (that is, not simultaneous) stages. Because of these independent stages, temporal resolution of detection may be limited in such instances.

In some examples, electrokinetic phenomenon(a) may be used for mechanically exciting the sensor 110. This may be done at or about the same time while material is also being manipulated by electrokinetic phenomenon(a). This may enable material collection and sensing at or about the same time, which may be useful for continuous and/or real-time in-situ sensing applications where high temporal resolution of detection may be desired.

With sensing and material collection at or about the same time, information relating to the adsorption process (e.g., information about binding kinetics) may not be lost.

Electrokinetic phenomenon(a) may be used to mechanically excite the sensor 110 by, for example, allowing the microstructure 111 itself to also experience induced polarization (e.g., by altering the boundary conditions when designing the generated electric field). For example, a mechanically fixed potential plane may be added to system calculations to represent the microelectrode(s) 112, in addition to the microstructure 111. The microstructure 111 may then be actuated by DEP. Other electrokinetic mechanisms, such as electrokinetic fluid flows or particle-structure interactions, may also provide driving forces to cause mechanical excitation of the sensor 110 and may be designed for using suitable techniques.

In some examples, mechanical excitation of the sensor 110 may be through application of a magnetic field (e.g., using an actuator provided by the device 100 or the system 1000), such that Lorentz forces may cause actuation of the sensor 110 into its resonant mode, as described further below.

### Mass Responsivity

In general terms, mass responsivity of a resonator can be described by:

$$\frac{d {f}_{i}}{d m} = \frac{{f}_{i}}{2 M} \qquad ( 8 )$$

where dfᵢ/dm is the mass responsivity [Hz/g], fᵢ is the resonant frequency [Hz] of the i-th mode, M is the total mass of the resonator [g]. This design parameter may be useful for sensing presence of a material based on detecting a negative resonant frequency shift (as opposed to a stiffness change). Resonators designed with higher fundamental frequencies and lower dynamic mass may be more mass-responsive. This may also result in higher-order modes that are more sensitive.

Thus, the sensor 110 may be designed with scaled down dimensions (e.g., down to the sub-micron scale) to both increase fundamental resonant frequency and reduce dynamic mass. The sensor 110 may include materials having relatively high Young's Modulus and relatively low density.

Equation (8) may relate to other system considerations. For example, immersing the sensor 110 in a liquid may cause the resonant frequencies to be reduced (e.g., may be reduced by a factor of about 3 or possibly more, for example by a factor of about 100) due to fluid damping and/or the virtual mass effect of the surrounding fluid. This may reduce mass-responsivity of the sensor 110. Furthermore, when material accumulates onto the sensor 110, the mass-responsivity of the sensor 110 may further progressively decrease.

The degree to which the sensor 110 may be scaled down may be dependent on other considerations, such as performance or economic considerations, including, for example, the smallest feature size attainable from a fabrication process, the manufacturing cost and reliability of a fabrication process, among others. The choice of a fabrication technique may influence what features may be implemented on the sensor 110. Generally, the basic geometry of a sensor 110 and/or individual design concepts may be scalable.

The size of the sensor 110 may influence the method for detecting displacement of the sensor 110. For example, by scaling the sensor 110 towards the nanoscale and making the sensor 110 more mass-responsive, choices for displacement detection techniques may become more limited. Detection techniques such as optical interferometry may become diffraction limited and may be ineffective when the sensor 110 is scaled down to the wavelength of laser light, for example. However, other detection techniques may be suitable for detection in smaller scales.

The resonant frequencies may also be sensitive to mass loading positions on the sensor 110. When the sensor 110 acts as a resonator, it may be modeled as a classic mass-spring eigenvalue problem:

[K−λM])Φ=0 (9)

where K is the stiffness matrix, M is the mass matrix, λ is the eigenvalue (i.e. resonant frequency), and φ is the eigenmode (mode shape). First order eigenvalue sensitivity analysis performed by differentiating with respect to mass element Mⱼ under mass normalization condition gives:

$$\frac{d {λ}_{i}}{d {M}_{j}} = {Φ}_{i} \cdot [ \frac{\partial K}{\partial {M}_{j}} - {λ}_{i} \frac{\partial M}{\partial {M}_{j}} ] {Φ}_{i} \qquad ( 10 )$$

where Mⱼ represents the mass at the j-th geometric position in the system, λᵢ is the i-th eigenvalue, φᵢ is the i-th eigenmode and dλᵢ/dMⱼ is the sensitivity of the i-th eigenvalue to changes in Mⱼ. Equations (9) and (10) can be solved for a given system. It can be demonstrated that where dφᵢ/dMⱼ is zero (which may be commonly the case for simple fixed-fixed beam configurations) and

$$\frac{\partial K}{\partial {M}_{j}} = 0 ,$$

mass changes at nodal positions of the microstructure 111 will yield dλᵢ/dMⱼ=0. This may be referred to as the null-sensitivity criterion.

On the other hand, mass increase at dynamic deflection maxima (or antinodes) will yield high dλᵢ/dMⱼ. This may be because the most sensitive expression of equation (10) under the current assumptions relate to

$${λ}_{i} ( \frac{\partial M}{\partial {M}_{j}} )$$

and the multiplication with the eigenvector. If mass is increased at a certain position, but for which that position yields zero dynamic displacement according to the mode shape (i.e. at nodes), that expression becomes a zero vector, thus equation (10) becomes zero. The reverse may be true for masses loading at antinodes that will yield maximum dλᵢ/dMⱼ. This may be a consideration in design of the disclosed sensor 110.

Thus, performance and/or capability of the sensor 110 may depend on both increasing mass responsivity as well as exploiting the null-sensitivity. The microelectrode(s) 112 (or other electric field-generating feature) may be designed with this in mind, for example to increase the accumulation of material towards regions of highest or lowest mass sensitivity on the sensor 110, depending on the aim (e.g., in order to direct target material(s) towards regions of higher mass sensitivity and non-target materials to regions of lower mass sensitivity).

Typically, the first resonant mode of the sensor 110 may be the mode targeted for achieving higher mass sensitivity. This may be because the first resonant mode has the lowest resonant frequency and may be the easiest to measure. Typically, as resonant frequencies increase, detection and characterization of the resonant frequency may become more complex.

Another design consideration may be to limit material-loading to only certain desired regions on the microstructure 111. This may be because stiffness variations may reduce mass responsivity of the sensor 110. From the discussion above regarding equation (9), it was assumed that

$$\frac{\partial K}{\partial {M}_{j}} = 0 ,$$

which in reality may not be the case. Limiting the mass collection to specific regions of the microstructure 111 may help to ensure that stiffness is not changed for most of the microstructure 111, and so may lead to higher sensitivity.

### Other Mechanical Considerations

Other design considerations may include designing to reduce dissipative losses which can lower the Quality (Q) factor of the response. This may be useful because a lower Q-factor response may tend to have lower signal-to-noise ratio. The peak broadening in the frequency domain of a low Q response may make frequency determination harder and/or less precise. As such, the material choice for the microstructure 111 may be a starting point for improving the Q-factor. For example, materials used for the microstructure 111 may have relatively low intrinsic losses. Single-crystal resonators of relatively high Young's Modulus materials may be suitable for this purpose.

Another factor that may be considered is the environment in which the microstructure 111 is resonating. A vacuum environment may lead to higher mass-responsivity and higher Q-factor. However, the operating environment may be dependent on the sensing application. For example, to sense biological materials, the sensor 110 may be intended to operate in liquids. This may lead to dampening of resonance due to the virtual mass effect, as well as the fluid medium acting as an extrinsic loss mechanism. This challenge may be addressed through the use of a gas bubble, as described further below.

### Electrode-Free Sensor

In some examples, the sensor 110 may include microelectrode(s) 112 for generating an electric field in order to elicit electrokinetic phenomena, while in other examples the sensor 110 may include some other electric field-generating feature in place of or in addition to microelectrode(s) 112.

Microelectrode(s) 112 may be formed by depositing conductive metals on the microstructure 111. Although metals tend to have relatively high electrical conductivity, they may also tend to have relatively high mass-densities. Lower mass-density materials with a sufficiently good degree of electrical conductivity may be used for the electrodes (e.g., doped poly- or single-crystal-silicon), however their electrical conductivity tends to be lower.

Mass-responsivity of the sensor 110 may be diminished by having the microstructure 111 covered in metal microelectrodes 112. The gain of more analyte-loading from the increased electrode coverage may be outweighed by a reduction in mass-responsivity due to the patterning of the microelectrodes 112.

In some examples, electrokinetic effects may be elicited without having discrete microelectrodes 112 incorporated onto the microstructure 111. For example, the microstructure 111 may include features such as one or more regions that may act as an electrical resistor. For example, the microstructure 111 may be a substantially continuous material with substantially homogenous electrical properties, and with regions of different cross-sectional areas. Regions of the microstructure 111 with smaller cross-sectional area may have larger electrical resistance than regions with greater cross-sectional area. Such regions of smaller cross-sectional area may be referred to as a choke point of the microstructure 111, and may act as a resistance element. When current is passed through the microstructure 111, most of the potential drop may be expected to occur at the choke point(s). This high potential drop may cause a potential difference that may give rise to electrokinetic effects.

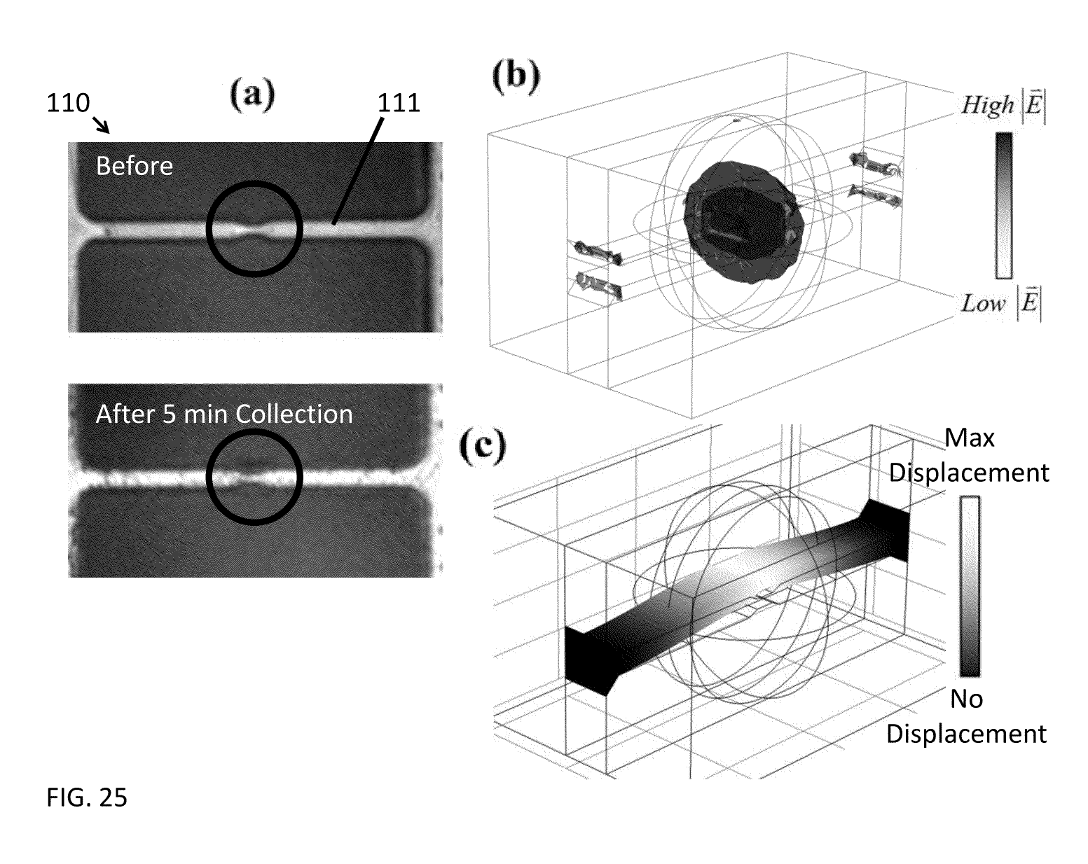

As an example, consider example sensor design 9 (FIGS. 25a-c) described below. The microstructure 111 in this example is a fixed-fixed beam with one choke point (circled) near the center of the beam. This choke point may be the region of highest electrical resistance on the microstructure 111. The choke point may also be designed with sharp edges that may elicit stronger DEP forces.

When AC signals are passed across the entire microstructure 111, most of the potential drop may be expected to occur at or near the choke point. This may result in the generation of an electric field to help elicit electrokinetic effects for particle collection, for example through DEP. FIG. 25a shows, for example, that material is collected at or near the center of the microstructure 111 as expected, likely due to DEP. In this example, the microstructure 111 may be substantially planar. In other examples, fixed sidewalls of the device 100 may have larger widths on both ends of the microstructure 111 (i.e. the microstructure 111 may be positioned at or near the center of the device 100).

In this example, the choke point may be positioned at or near the mass loading position that is expected to yield higher mass-responsivity for the first mode of the sensor 110 and/or close to null sensitivity for all other even ordered higher-order modes.

### EXAMPLE STUDIES

The examples described below illustrate exemplary characteristics and designs of the disclosed systems 1000, devices 100 and sensors 110. These examples may demonstrate implementation of one or more design principles described above, and possibly other appropriate design principles. These examples are for the purpose of illustration only and are not intended to be limiting.

### Example Study 1

Example sensors 110 were fabricated using a user-customizable MicraGEM process, (from Micralyne, Canada) such as described in [23]. The fabricated sensors 110 in this example included microstructures 111 that were about 10 μm thick high electrical resistivity single-crystal silicon cantilevers, with about 200 nm thick gold microelectrodes 112 deposited on the surface. The sensors 110 in this example rested in a device 100 with a Pyrex substrate with about 10 μm deep substrate-etched microchannels 150 over the free-standing regions of the sensors 110.

In this example, the microstructure 111 had a paddle-like cantilevered geometry. The device 100 included a Pyrex substrate about 500 μm thick that was lithographically patterned and wet-etched to create about 10 μm deep microchannels 150. A silicon-on-insulator (SOI) substrate with about 10 μm deep buried oxide (BOX) layer was then anodically bonded to the Pyrex substrate, where the BOX side of the SOI interfaced with the wet-etched Pyrex surface. The silicon handle of the SOI substrate and the BOX layer were then etched away, leaving a high electrical resistivity (111-plane) single crystal silicon structural layer bonded to the Pyrex substrate. An about 200 nm thick gold layer with an about 50 nm thick titanium-tungsten adhesion layer was then lithographically patterned and deposited on the silicon surface. A patterned mask was used to assist the deep reactive ion etching of the exposed areas of the silicon substrate, resulting in the completed fabrication of the microstructure 111 having a free-standing silicon paddle-cantilever configuration.

In some examples, the microstructure 111 may be made from a single crystal silicon about 10 μm thick with an overall planar footprint of about 200×500 μm. It should be noted that these dimensions are exemplary and not intended to be limiting. For example, suitable fabrication techniques may be used to fabricate a sensor 110 that is much smaller (e.g., a ten-fold or more decrease in size). By decreasing the footprint of the sensor 110, intrinsic responsivity of the sensor 110 may be increased. For example, a ten-fold decrease in each width and length of the sensor 110 may result in an over 100-fold increase in sensitivity, according to scaling laws.

The microelectrodes 112 (which were embedded in the microstructure 111 in this example) in this example were made of PadMetal using Silicon-On-Insulator Multi-User MEMS Processes (SOIMUMPs) [31]. Any other suitable methods may be used. The layout of the microelectrodes 112 was designed for better collection and capture of the target material(s) using electrokinetic phenomenon(a) (e.g., as described above).

Part of the substrate under the sensor 110 may be etched away to provide accessible space underneath for a measurement laser of the detector 200. The sensor 110 may be excited in-situ by planar electrostatic force (e.g., using one or more excitation electrodes 180). The microelectrode(s) 112 on the sensor 110 may be connected to respective bonding pads 113 (see FIG. 2, for example), which may be about 150×150 μm² in size, located along a border and with spacing gaps of about 1.5 mm between adjacent bonding pads 113.

In some examples, the sensor 110 may include a functionalized surface for targeting the target material(s). For example, where the target material(s) is a biological material, such as bacteria, the functionalized surface may include antibodies (such as described in [33, 34]). For example, the silicon surface of the sensor 110 may be functionalized (e.g., covalently) with an antibody capable of capturing a target bacteria, such as a specific strain of E. Coli. Functionalization may be carried out using a technique which builds up from the silicon surface of the sensor 110 using a silinizing agent, which may form a covalently-bound monolayer, and may react with a crosslinking agent. The crosslinking agent may be reacted with the terminal amine of monoclonal and/or polyclonal antibodies and may provide a covalently-bound antibody bound to the surface of the sensor 110 while retaining the activity of the antibody, thus forming a functionalized surface on the sensor 110. This example functionalization method may have versatility to sense different bacteria (e.g., different E. coli strains) by using different types of antibody and may thus provide a sensor 110 that may be designed to selectively detect certain target materials (e.g., certain strains of bacteria) when analyzing a mixed sample (e.g., having a mixture of different bacteria).

In this example study, the functionalized surface may be formed by attaching antibodies to the surface of the microelectrodes 112 via covalent boding. Antibody-functionalized microelectrodes 112 may be fabricated using any suitable method, for example a procedure adapted from Bhatia et al [80]. Suitable chemicals in the method described here may be obtained from Sigma Aldrich (Oakville, Ontario, Canada). In this example, the microelectrodes 112 were rinsed with acetone, ethanol, and de-ionized water and subsequently cleaned for about 30 minutes in solutions of firstly, about 50/50 v/v methanol/hydrochloric acid (about 4.0 M), then, about 30 wt. % sulphuric acid, and finally boiling de-ionized water. The microelectrodes 112 were then exposed to UV/O₃ and allowed to dry overnight before transferring to a DRI-LAB dry box (Vacuum Atmospheres Co., Hawthorne, Calif., USA). The microelectrodes 112 were rinsed in toluene and then immersed in an about 3% by volume solution of (3-mercaptopropyl)trimethoxysilane (MTS) in toluene preheated to about 80° C. The microelectrodes 112 were allowed to react for about two hours and the temperature was allowed to drop to about room temperature. The microelectrodes 112 were then washed with toluene and allowed to react for about 2 hours with a suitable crosslinking agent (e.g., N-γ-maleimidobutyryloxy succinimide (GMBS) (Sigma-Aldrich), which was dissolved in a minimum amount of dimethylformamide (DMF) and diluted with ethanol to a final concentration of about 5 mM). Finally, the microelectrodes 112 were washed with phosphate buffered saline (PBS) and were allowed to react overnight with a about 0.6 mg/mL of anti-avidin (IgG fraction, produced in rabbit, obtained from Polysciences, Warrington, Pa., USA) in PBS solution, after which the substrate was rinsed with PBS. The functionalized microelectrodes 112 were kept immersed in PBS buffer and at about 4° C. until used.

After collection of the target material, the microelectrode 112 may be cleaned using a suitable chemical, such as a mild acid of HCl with a pH of about 3.0, enabling the microelectrode 112 to become usable again for collection of the target material (with the same or less efficiency).

In some examples, the sensor 110 may include a functionalized surface that is functionalized with poly-L-lysine. Functionalization may be carried out using any suitable method, such as the method described in [8]. This may result in a positively charged surface to electrostatically retain the target material(s).

An example process for fabrication microelectrodes 112 functionalized with poly-L-lysine is now described. The microelectrodes 112 were rinsed with acetone, ethanol, and deionised water and subsequently exposed to UV/O₃ for a period of about 2 hours. A sealed environment was prepared with excess water and allowed to come to equilibrium in order to saturate the air with water vapor. The microelectrodes 112 were washed in phosphate buffered saline, then millipore de-ionized water and then placed in the sealed environment. An about 30 μL droplet of about 0.1 w/v % solution of poly-L-lysine (Sigma Aldrich), was placed on the microelectrodes 112 and allowed to react for between about 30 min to about two hours in the sealed environment. The microelectrodes 112 were then washed with phosphate buffered saline and subsequently millipore filtered water and stored dry and at about 4° C. until used.

The strain of E. coli (EMG 31) used in this example was donated by the department of Microbiology & Immunology at Queen's University. The E. coli was kept alive on Luria Bertani agar plates until needed. E. coli was killed via UV exposure over about an 8 hour period and stained using a final concentration of 0.05 g/L of methylene blue. Samples were placed in a centrifuge at about 5800 g for about 10 minutes, decanted, refilled with Millipore® filtered water and shaken vigorously; this process was repeated three times. The final concentrations were prepared by dilution with Millipore® water. Suspensions containing 10⁸ E. coli particles/mL were used immediately after preparation. A droplet of about 40 μL was placed in the chamber 120 of the device 100. For all experiments, collection times were about 30 minutes, after which, the device 100 was rinsed with Millipore® water and allowed to dry overnight.

For characterization of the example sensor 110, the microstructure 111 having a cantilever configuration was mechanically excited under ambient conditions in air by applying an electrical potential between the sensor 110 and an in-situ tungsten probe that was situated in close proximity to the sensor 110. Sweeping sinusoidal excitation signals (at about 50Vₚₚ 25V_{Dc}) were generated using a signal generator (from Polytec, Germany) and voltage amplifier (from Tabor Electronics, Israel) as the signal source 300. A commercially available optical heterodyne interferometer (from Polytec, Germany) was used as the detector 200 for displacement detection of the excited sensor 110. Single-point displacement measurements were performed at the free-end of the microstructure 111 on an anti-node location of the first and second mode-shape of the resonant sensor 110. A commercial Fast Fourier Transform (FFT) algorithm (from Polytec, Germany) with 6400 FFT bins was used to Fourier decompose the displacement-time signals to extract the mechanical frequency response of the sensor 110. The resonant frequency of a functionalized sensor 110 with a cantilever beam configuration was determined prior to the collection of E. coli particles and compared with the resonant frequency after collection.

FIGS. 4a-c show the sensor 110 of this example. FIG. 4a shows a wireframe model of a microstructure 111 having a cantilever design and including quadrapolar microelectrodes 112. Here, the first and third microelectrodes 112 have the same phase. The second and fourth microelectrodes 112 are 180 degrees out of phase relative to the first and third microelectrodes 112. As shown in FIG. 4a, the microelectrodes 112 may be arranged in a clover-leaf formation, with a non-conductive electrode channel 114 between adjacent microelectrodes 112 and a non-conductive electrode gap 115 in the center of the microelectrodes 112.

To test the ability of the sensor 110 to cause enhanced bioparticle collection in solution, two scenarios were investigated: unassisted collection and collection with the assistance of electrokinetics. FIGS. 4b and 4c are optical images of a dried poly-L-lysine functionalized cantilever design sensor 110 after about 30 minutes of exposure to about 10⁸ particles/mL of UV killed, MB stained E. coli with unassisted capture (FIG. 4b) and DEP-assisted capture (at about 8 Vₚₚ, 1 MHz) (FIG. 4c).

For unassisted collection, suspensions of about 10⁸ E. coli particles/mL were allowed to settle over about a 30 minute period on the poly-L-lysine functionalized sensor 110 having a cantilever beam design. Any material found on the surface of the sensor 110 would be due to stochastic movement and gravitational effects. An example result of unassisted collection is shown in FIG. 4b.

For assisted collection, an AC electric potential (at about 8 Vₚₚ, 1 MHz) was applied to the microelectrodes 112. Again, with suspensions of about 10⁸ E. coli particles/mL were allowed to settle over about a 30 minute period. The results are shown in FIG. 4c, demonstrating a greater number of material present on the sensor 110. The locations of highest material concentration, as illustrated in FIG. 4c, may be expected to occur at electric field maxima, such as at the edges of the microelectrodes 112. Such collection patterns may be characteristic of material undergoing pDEP [8]. The bacteria on the surface of the sensor 110 remained bound to the sensor 110, due to the electrostatic forces between the bacteria and the positively charged poly-L-lysine functionalized surface on the sensor 110, thus resulting in a net increase in mass on the sensor 110. Assuming that the stiffness of the sensor 110 is not affected by the presence of the captured E. coli particles, an increase in mass may be expected to result in a decrease in resonant frequency [24] of the sensor 110. Such a change in vibration of the sensor 110 may be detectable and may thus indicate detection of the target material(s) (in this example, E. coli particles).

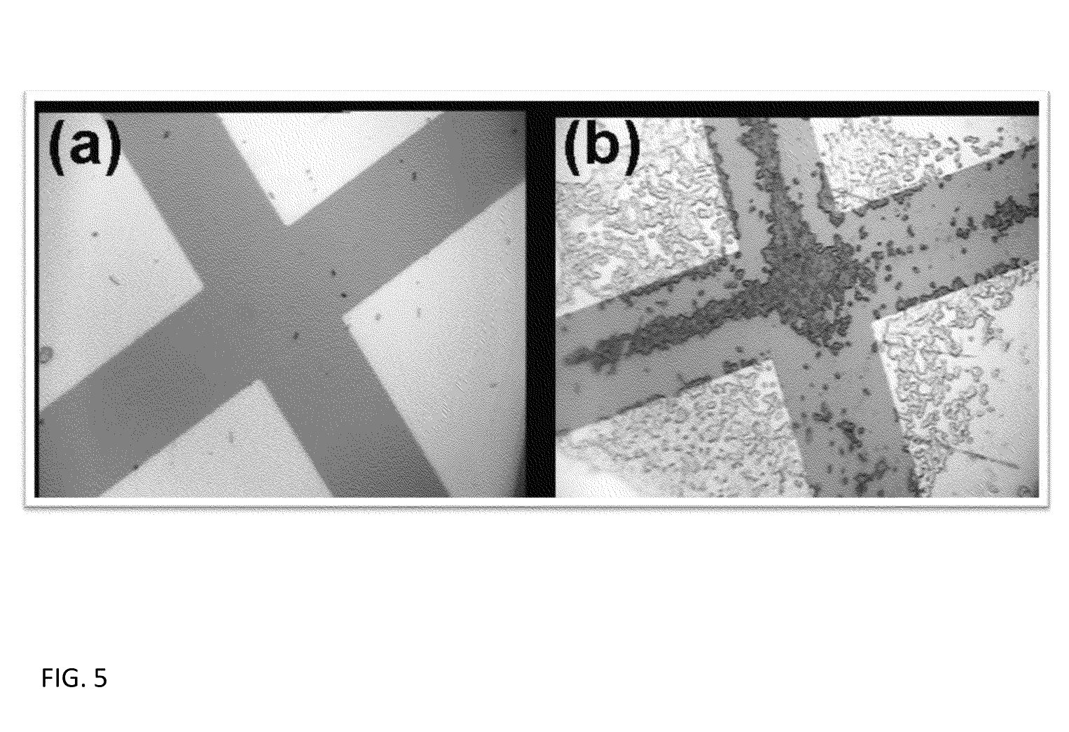

FIGS. 5a-b are further images showing results of unassisted and assisted collection of E. Coli on the surface of the sensor 110, where the sensor 110 includes a functionalized surface targeting E. Coli. FIG. 5a shows the surface of an example sensor 110 after E. Coli collection of live and dead bacteria for about 20 min and subsequent wash after unassisted deposition (that is, resulting from material settling due to gravity alone). FIG. 5b shows the surface of the sensor 110 after collection for about 20 min and subsequent wash, with the aid of electrokinetics (that is, with an electrical field generated by the microelectrodes 112) collecting live bacteria at or near the centre of the sensor 110 while dead bacteria were collected at or near the edges of the microelectrodes 112. FIG. 5b illustrates the effect of combined accelerated collection/antibody-mediated capture of the target bacteria, showing more effective collection of the target bacteria combined to unassisted collection.

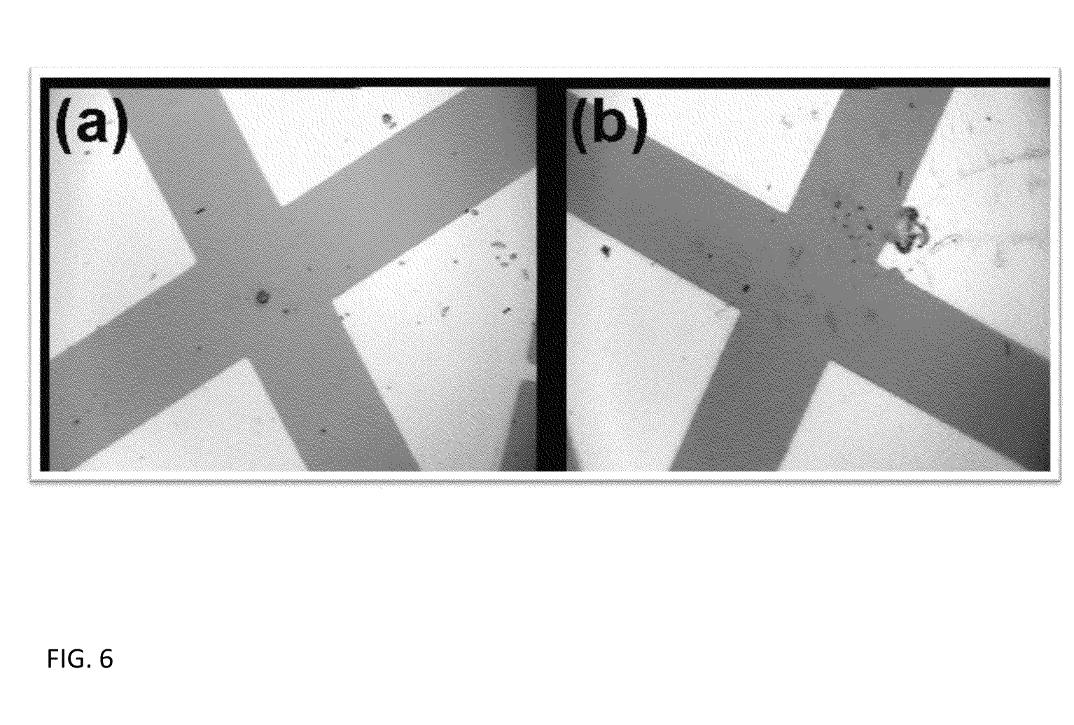

FIGS. 6a-b show images illustrating selectivity of the sensor 110, where the sensor 110 includes a functionalized surface targeting E. Coli. In this example, a sample containing an untargeted material, Pseudomonas Fluorescens, was introduced to the sensor 110 for about 20 min and the sensor 110 was subsequently washed. FIG. 6a shows the result after unassisted collection (that is, resulting from material settling due to gravity alone). FIG. 6b shows the result with the aid of electrokinetics (that is, with an electrical field generated by the microelectrodes 112). No significant retention of the untargeted bacteria was observed. This demonstrates the ability for the sensor 110 to be selective—that is, non-target material may not be captured and thus may not result in a false-positive detection.

The effects of functionalization (in this example by poly-L-lysine) on the resonant frequency of the sensor 110 were examined in over 100 cases for a variety of different sensors 110 having microstructures 111 with different cantilever paddle designs for five resonant modes. The sensors 110 were observed to have experienced negligible changes in the resonant frequency due to functionalization. Thus, it appears that functionalization had a negligible effect on the resonant frequency of a sensor 110 having a microstructure 111 with a cantilever configuration. It was also found that cantilever sensors 110 coated with poly-L-lysine and exposed to an electric field for 30 minutes in Millipore® filtered water did not show a change in their resonant frequency.

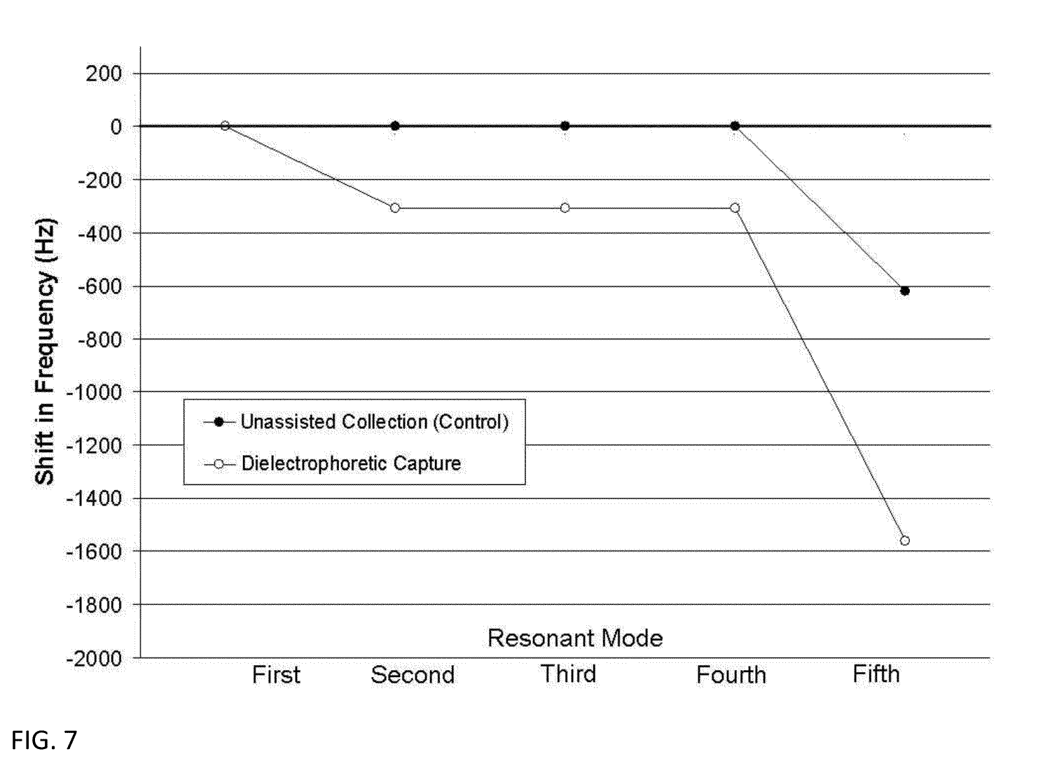

FIG. 7 illustrates the resonant frequency shift results of the sensor 110 shown in FIG. 4. FIG. 7 is a chart of the frequency shift (which may be defined as the frequency after collection of material minus frequency prior to collection) vs. resonant mode after about 30 minutes of collecting 10⁸ particles/mL of UV killed, MB stained E. coli for a sensor 110 having a single microstructure 111 with a cantilever design. Results from DEP-assisted capture (at an applied voltage of about 8 Vₚₚ, 1 MHz) and unassisted collection (where no voltage was applied) are presented from a detector 200 having a bandwidth of about 2 MHz. For the first resonant mode the shift was found to be about 0 Hz for both data series, while for the fifth mode, the frequency shifts were 600 for unassisted collection and 1600 Hz for assisted collection. For unassisted collection, there was no measurable resonant frequency shift for the first four flexural modes. For the fifth flexural mode, a negative shift of over 600 Hz was recorded. For assisted collection, there was no measurable resonant frequency shift for the first flexural mode. However, the second, third and fourth flexural modes recorded a negative frequency shift of over 300 Hz. In the fifth flexural mode, the recorded frequency shift was nearly three times that of the result from unassisted collection.

In this example, the case of unassisted capture represents a detection scenario that may be rate-limited in sedimentation by gravity and/or Brownian motion. It may also be sensitivity limited by the random distribution of adsorbed analytes onto the sensor. The results for the case of unassisted capture showed that frequency shifts of the first four modes of the sensor 110 were substantively undetectable, given the limited FFT frequency resolution of conventional detection instruments (which may have lower detection limits at about 312.5 Hz).

On the other hand, in the case of assisted capture, generation of an electrical field by the microelectrodes 112 helped to enhance the sensitivity of the sensor 110. By applying appropriate voltage to the microelectrodes 112, an electrical field was generated that resulted in electrokinetic forces that accelerated analyte sedimentation onto the sensor 110. The configuration and placement of the microelectrodes 112 also caused the spatial distribution of E. coli to be biased towards locations near or at the deflection maxima of the fifth flexural mode of the sensor 110. These effects, including an increased rate of particle collection and mode-matching of adsorbed masses with the resonant mode, were found to enhance the sensitivity of the sensor 110. The results in this case showed measurable frequency shifts for all but the first mode, and resulted in a particularly sensitive fifth mode under electrokinetics-assisted collection. This may be an improvement over the case of unassisted capture.

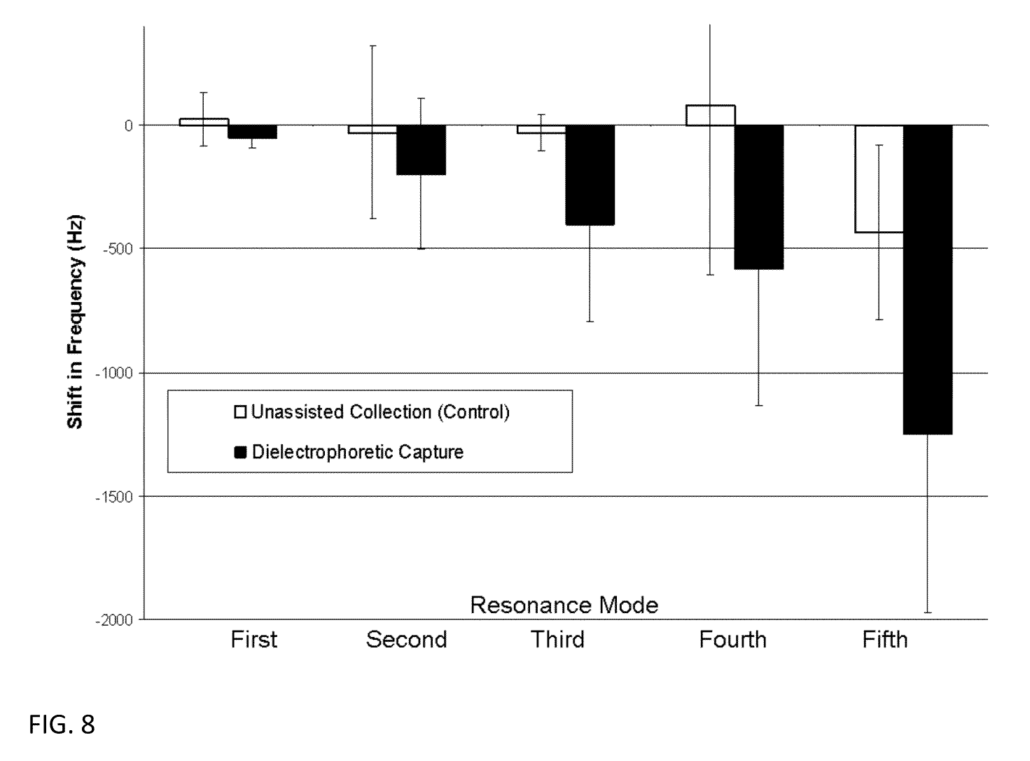

The collective results for the changes in resonant frequency in the five measurable modes over a number of tests on different example sensors 110 are presented in FIG. 8. FIG. 8 is a chart showing frequency shift vs. resonant mode after assisted and unassisted capture of 10⁸ particles/mL of UV killed, MB stained E. coli after about 30 minutes with an AC applied voltage of about 8 Vₚₚ with a frequency of about 1 MHz. Shifts are presented using the smallest scanning range able to capture the mode being investigated. Error bars indicate one standard deviation (Number of data points for each flexural mode: first N=9, second N=8, third N=9, fourth N=7 and fifth N=5).

FIG. 8 compares the frequency shift for a group of sensors 110 with microstructures 111 having cantilever beam designs in assisted and unassisted capture of the target material, in this case E. Coli. Statistically, for unassisted deposition, a 0 Hz shift was found to lie within one standard deviation of the mean shift measured for the first four modes, while the fifth mode showed a mean shift of 450 Hz for the entire group of sensors 110. The results from this statistical analysis of multiple sensors 110 were found to validate the response behavior for the single sensor 110 studied in FIG. 7 above. In comparison, results for assisted collection did not include a 0 Hz shift within one standard deviation for the third, fourth and fifth modes. The fifth resonant mode was found to exhibit a threefold increase in the magnitude of the mean shift in comparison to relying on unassisted deposition.

These example results indicate that the use of microelectrodes 112 with a quadrupolar configuration on sensors 110 with a microstructure 111 having a cantilever beam configuration may help to enhance the collection and detection of target material(s). For all resonant modes measured, the use of an electric field to enhance the collection of material was found to result in a greater negative resonant frequency shifts than when relying on unassisted collection. The results also suggest that the detection of captured material at lower resonant modes may be possible, while higher modes may be more sensitive to smaller amounts of captured material (and may thus have a lower detection limit).

The sensitivity of the sensor 110 may be subject to the location of captured material on and/or in the sensor 110, since vibrations of the sensor 110 may be dependent on the distribution of mass on the sensor 110. For example, the sensor 110 may have little or no detectable response if material accumulates in the area of a node, whereas the sensor 110 may be particularly sensitive if material accumulates in an area of maximum displacement (also referred to as an antinode). Thus, selective positioning of microelectrodes 112 on the sensor 110 may promote capture of material at or near locations on the sensor 110 to promote greater displacement and avoid resonant nodes.

Similar results may be expected for other variations of the sensor 110, including different configurations of the microstructure 111 and/or microelectrode(s) 112 (or other electric field-generating feature(s)), and for different functionalization, such as discussed below.

### Example Study 2

In this example, the sensor 110 may include a microstructure 111 having a fixed-fixed beam configuration, in which both ends of the beam are substantially fixed.

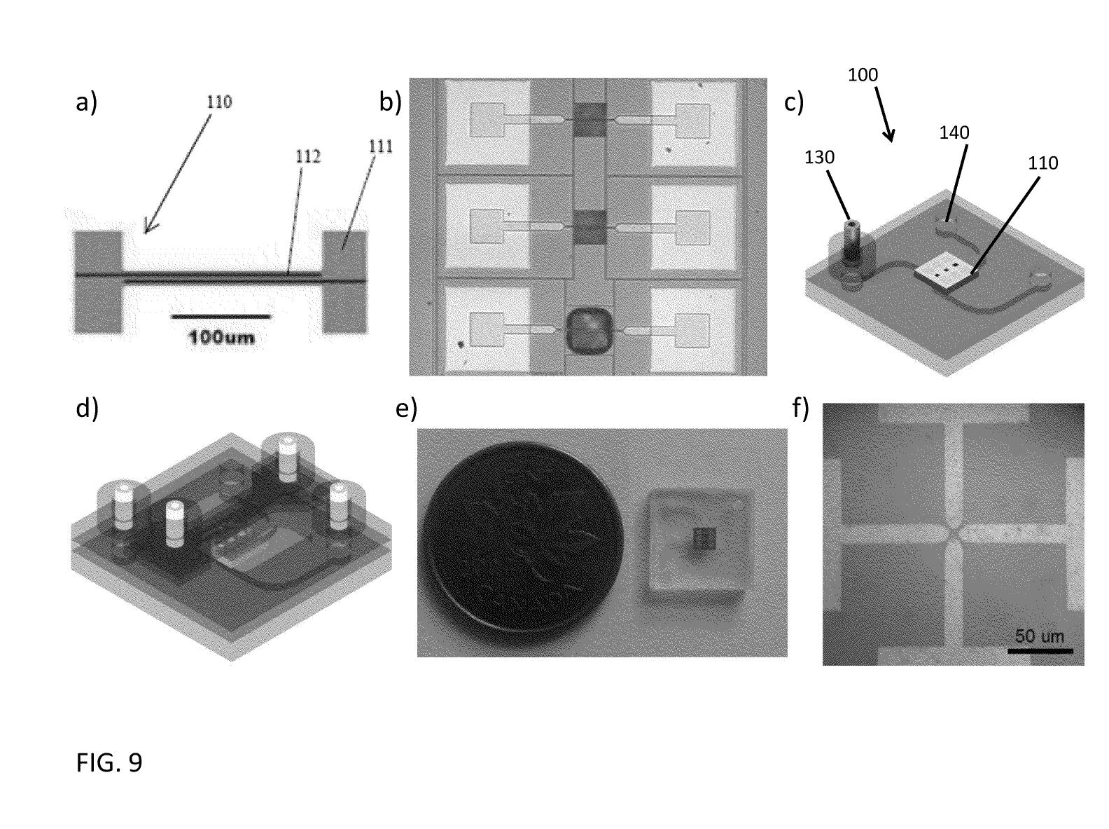

In this example, the sensor 110 was provided in a device 100 in the form of a MEMS chip. The sensor 110 included a microstructure 111 with embedded microelectrodes 112. Fabrication was carried out using the SOIMUMPs process (from MEMSCAP). The layout of an example sensor 110 with a microstructure 111 having a fixed-fixed beam configuration is shown in the schematic of FIG. 9a. In this example, a total of 14 chip devices 100 were manufactured with each device 100 containing three sensors 110 and measuring about 2 mm×2 mm, as shown in FIG. 9b. For each device 100, a fluidics PDMS system was developed to securely hold the device 100 while allowing contact with electrical probes and delivery of a sample solution, as shown in FIG. 9c. In this example, three channels are included in the device 100 to enable the wetting of each sensor 110 independently. Each device 100 included two bonded layers of PDMS that were cast from molds fabricated by micromilling. An example of this setup is shown in FIG. 9d, including conduits 170 (in this example, PDMS tubing) for inflow and outflow of sample media. The two PDMS layers were stacked and bonded by applying a thin layer of uncured PDMS at the interface and then allowed to cure. The device 100 may be designed to allow for each sensor 110 to be used independently. A syringe (not shown) was used to deliver fluid to the sensors 110. FIG. 9e shows a size comparison of the device 100 with a coin (Canadian penny).

Preliminary and supporting measurements were conducted with planar gold microelectrodes 112 (as shown in FIG. 9f) fabricated on an oxidized silicon wafer (SiO₂ thickness was about 500 nm). These microelectrodes 112 had overall dimensions of about 1.5 cm×1.5 cm and were fabricated using photolithography and metal evaporation (gold deposition). The adhesion of the gold microelectrodes 112 (having a thickness of about 100 nm) to the substrate was facilitated by the deposition of a thin layer (about 50 nm) of chromium between the gold and silicon oxide. The tip-to-tip separation between opposite microelectrodes 112 was about 10 μm. The microelectrodes 112 were connected to a signal source 300 in an alternating fashion (180° phase difference between adjacent microelectrodes 112). The value of the applied voltage (about 8 Volts, peak-to-peak) and applied frequency (about 1 MHz), were monitored by an oscilloscope (Tektronix 465, Tektronix, Beaverton, Oreg., USA).

The microelectrodes 112 were functionalized by adapting a procedure from [22]. In brief, the microelectrodes 112 were submerged overnight in a solution of about 250 μg/mL biotinylated-bovine serum albumin (BSA) in phosphate buffered saline (PBS). After washing with PBS, an about 20 μL droplet containing about 250 μg/mL avidin in PBS was placed on the surface and allowed to sit in a high humidity environment for about 2 hours. The sensor 110 was washed in PSB again for about 15 min and an about 20 μL droplet of polyclonal biotinylated anti-E. coli (Abcam Inc., Cambridge, Mass., USA) in PBS was placed on the surface and allowed to sit in a high humidity environment for about a further 2 hours. The sensor 110 was washed a final time with PBS for about 15 min and dried with compressed nitrogen gas passed through an about 200 μm filter. This methodology may allow for the customization of the functional antibody layer to coat a surface with any biotinylated antibody and may provide an adaptable framework for fabricating a functionalized surface targeting a variety of target materials, including a variety of pathogens.

The strain of E. coli (K12) used in this example study was donated by the department of Microbiology & Immunology at Queen's University. The Pseudomonas fluorescens used was donated by the department of Chemical Engineering at Queen's University. The bacteria were kept alive on Luria Bertani agar plates until needed. Samples with known concentrations were prepared by dilution with Millipore® filtered water. Suspensions were used immediately after preparation. For all experiments, collection times were about 30 minutes, after which, the sensors 110 were thoroughly rinsed with Millipore® filtered water, to remove any uncaptured material, and allowed to dry.

Electrical potential (at about 50 Vₚₚ, 25 V_{Dc}) was applied to the sensors 110 and a tungsten probe was placed in close proximity to electrostatically excite the sensors 110, while the resonant frequencies of the sensors 110 were measured using a commercially available MSA-400 vibrometer (from Polytec, Hopkinton, Mass., USA) as the detector 200. Resonant frequencies of the sensors 110 were recorded before and after bacteria collection.

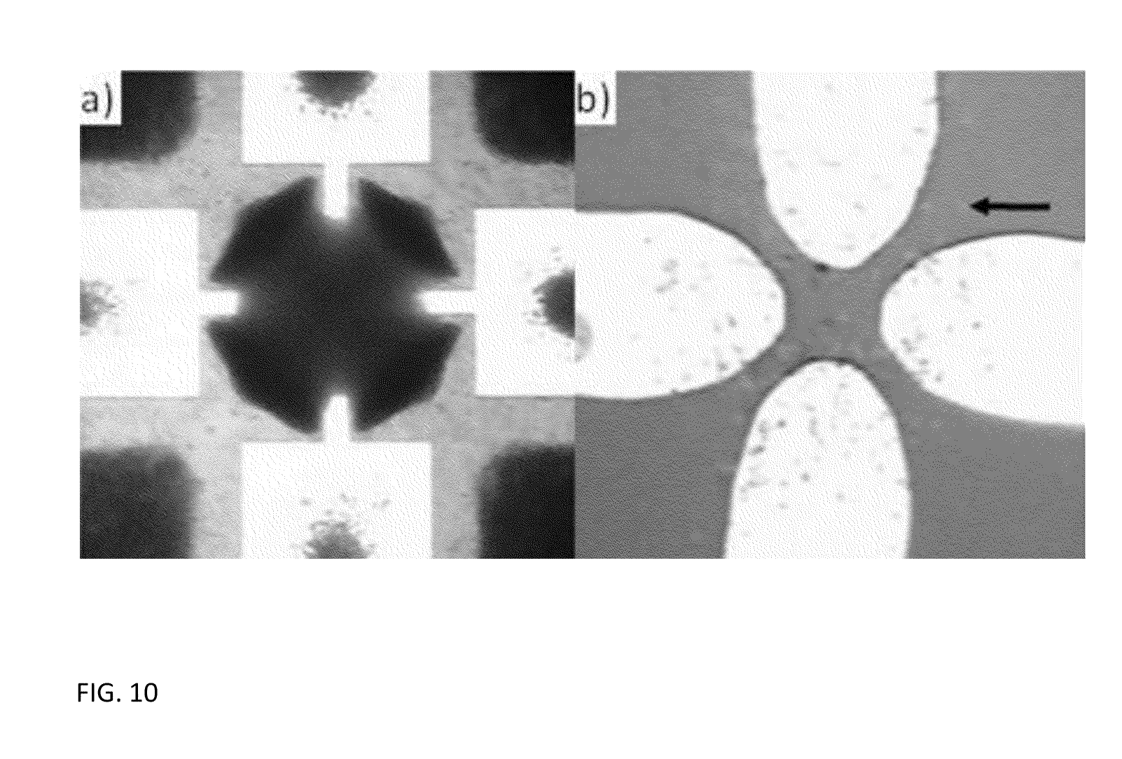

Tests were carried out to verify the specificity of the sensor 110 in the presence of a mixture of suspended solids/foreign matter in the sample. In this example, the planar microelectrodes 112 were functionalized with a polyclonal anti-E. coli antibody. Specificity tests were conducted with aqueous heterogeneous sample comprising 2.0 μm silica spheres (at a concentration of about 10⁹ particles/mL) and K12 E. coli (at a concentration of about 10⁹ particles/mL). An example of the result of this test is shown in FIGS. 10a-b. During collection, the silica particles (observed as spherical and opaque) and K12 E. coli (observed as spheroidal and translucent) were virtually equally driven towards the sensor 110. FIG. 10a shows a top-down view of the microelectrodes 112 after about 16 minutes of electrokinetics-assisted collection. After about 20 minutes of collection and washing the sample in phosphate buffered saline, the silica particles were no longer observed on the surface of the sensor 110 and only the greenish spheroidal objects of the K12 E. coli remain (one of which is identified with an arrow), as shown in FIG. 10b.

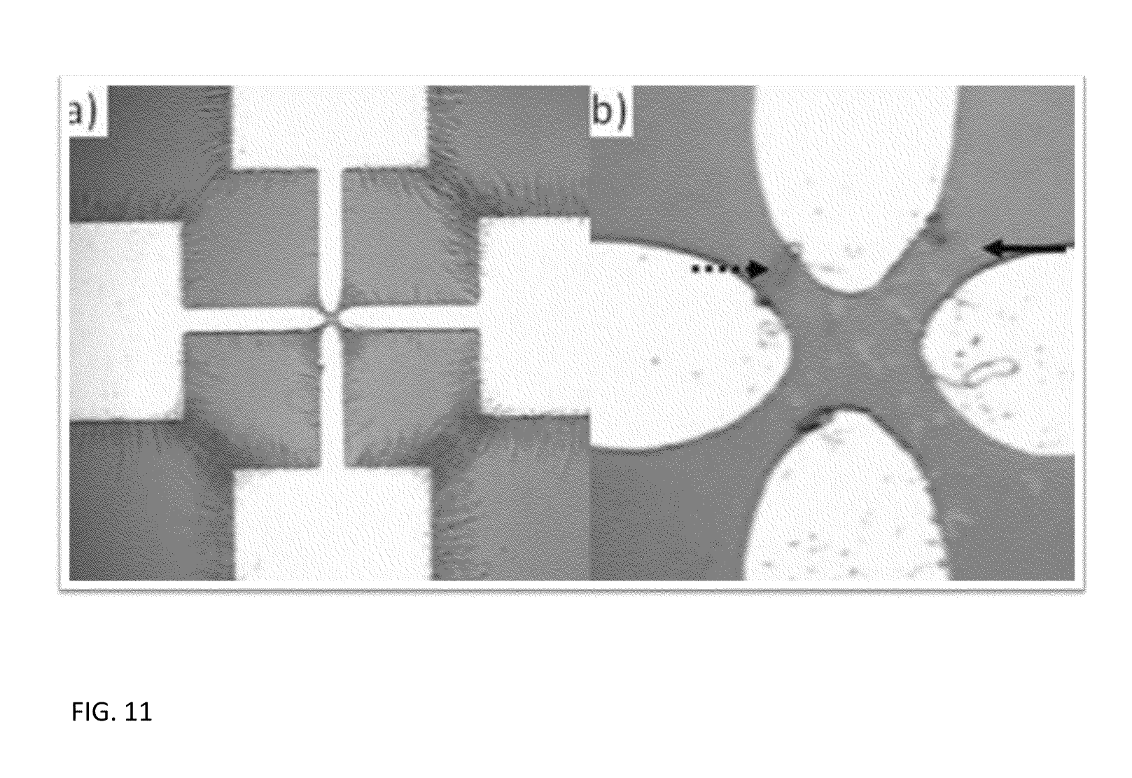

In order to demonstrate selectivity of the sensor 110, a similar approach to that of the above-described specificity tests was used. In this test, samples included mixtures of the target material, K12 E. coli (at a concentration of about 10⁹ particles/mL), and a non-target material, Pseudomonas fluorescens (at a concentration of about 10⁹ particles/mL). An example of the results of this test is shown in FIGS. 11a-b. After about 20 minutes of collection and subsequent washing with phosphate buffered saline, the majority of the retained matter on the sensor 110 was K12 E. coli, and in comparison only a small number of P. fluorescens bacteria were observed. During collection, the bacteria formed “pearl chains” starting from the microelectrode edges, as shown in FIG. 11a, which is a top-down view of the microelectrodes 112 after about 16 minutes of collection. After washing (see FIG. 11b), while only a few P. fluorescens remained, appearing as long tubes or strings (dashed arrow), the majority of the retained bacteria were the K12 E. coli which appear as smaller spheroidal objects (solid arrow). The target E. coli bacteria were retained in an amount about five times that of the untargeted P. fluorescens. These results demonstrate the ability to tailor selectivity of the sensor 110 using different functionalization, in order to differentiate between target and non-target materials, even among different strains of bacteria.

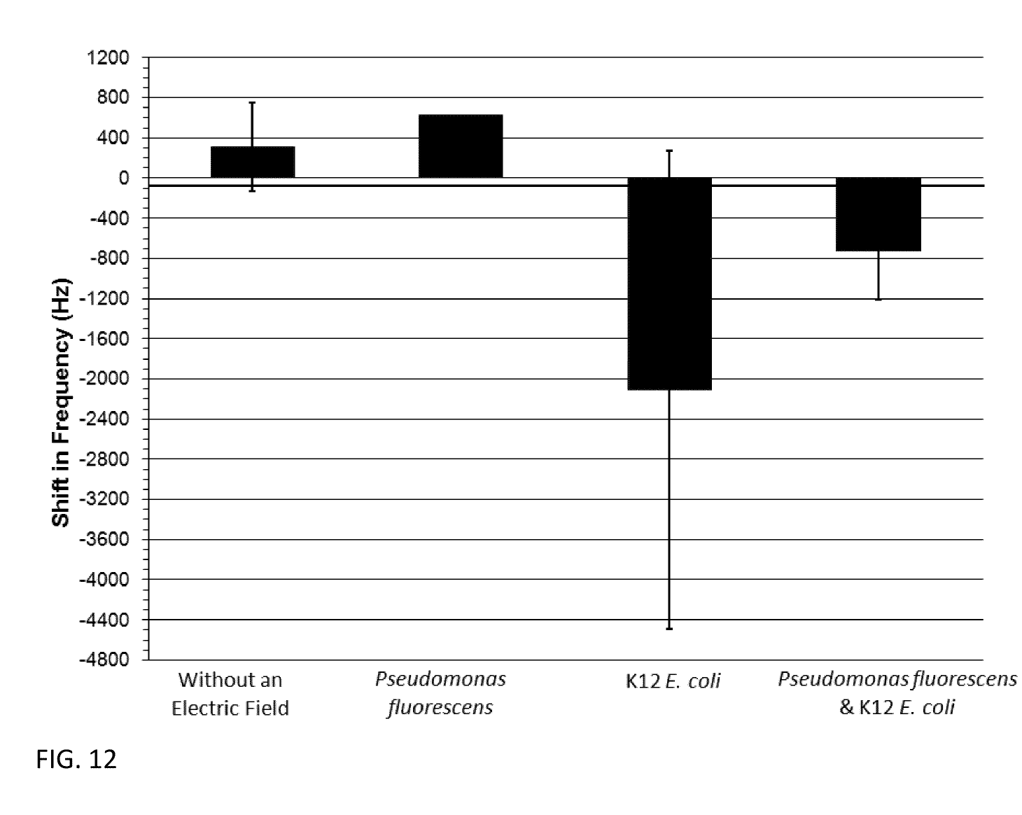

The visually observed selectivity and specificity described above was also found in the response of the sensor 110 as a whole. As shown in FIG. 12 (error bars indicating one standard deviation) and detailed in Table 1 below, the sensor 110 exhibited detectable frequency shift in the presence of the target E. coli. Table 1 summarizes the resulting frequency shifts after about 30 min of collection of samples (with an AC voltage of about 4 Vₚₚ and a frequency of 1 MHz being applied to the microelectrodes) containing targeted K12 E. coli (at a concentration of about 10⁹ particles/mL), untargeted Pseudomonas fluorescens (at a concentration of about 10⁹ particles/mL), and a mixture containing both E. coli and P. fluorescens (at a concentration of about 10⁹ E. coli particles/mL and about 10⁸ P. fluorescens particles/mL).

TABLE 1

| | | | Change in Frequency |
|---|---|---|---|
| Sensor | Pathogen | Electric Field | (1^{st} Mode) |
| A1.9 | E. coli | NO | 0 |
| A1.7 | E. coli | YES | −5625 |
| A1.10 | E. coli | YES | −1250 |
| A1.R5 | E. coli | YES | −312.5 |
| A1.R6 | E. coli | YES | −1250 |
| A1.R1 | P. flourescens | YES | 625 |
| A1.R3 | P. flourescens | YES | 625 |
| A1.13 | Mixture | NO | 625 |
| A1.R10 | Mixture | YES | −312.5 |
| A1.R12 | Mixture | YES | −625 |
| A1.R14 | Mixture | YES | −1250 |

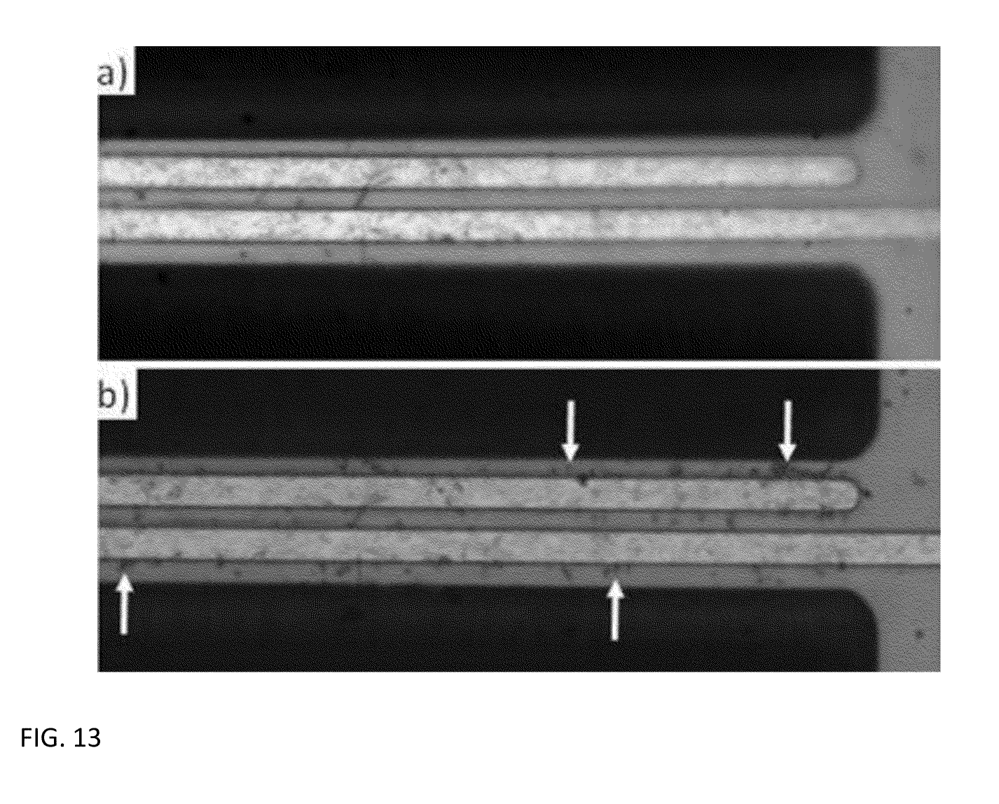

FIGS. 13-16 are example images of the sensor 110 with a microstructure 111 having a fixed-fixed beam configuration before and after collection. These images enable visual confirmation of the type of bacteria collected. K12 E. coli may be identifiable as small circular or ovoid shapes generally found as discrete particles while P. fluorescens may be identifiable as thinner and string-like shapes.

FIGS. 13a-b show images of an example of the sensor 110 before (FIG. 13a) and after (FIG. 13b) electrokinetics-assisted collection of targeted material (in this case, E. coli) from a homogeneous solution of K12 E. coli. K12 E. coli appear as small dark circles when dried or spheroidal and green when wet. Select areas of bacterial collection are indicated by arrows and typically occur at the edges of the electrodes. The sensor 110 was not completely free of debris prior to collection which may account for the presence of particles before collection.

The collection of E. coli bacteria with assistance of an electric field resulted in a negative frequency shift of the resonant frequency of the sensor 110 (see FIG. 12). The average shift in frequency for the first mode of vibration was about −2,109 Hz (one standard deviation was about 2,385). This indicated a deposition and retention of mass on the sensor 110 after the introduction of the target bacteria.

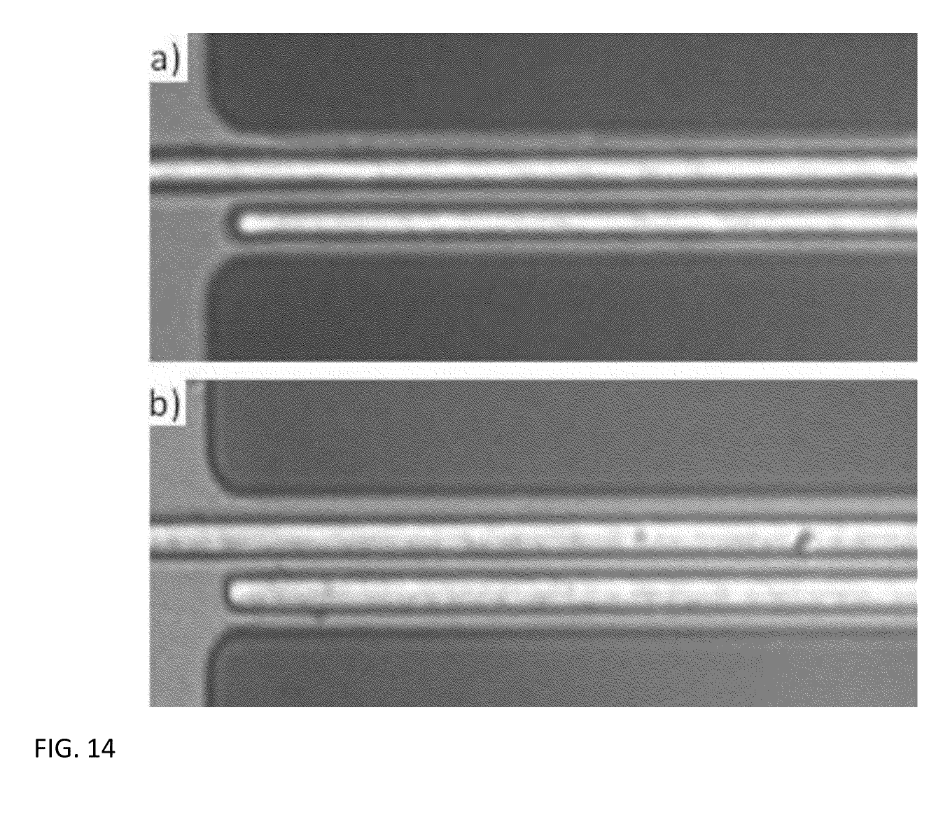

In the absence of an electric field, no negative shift in the resonant frequency was observed (see FIG. 12), highlighting the use of the electric field in enhancing detection. FIGS. 14a-b show images of example of an example portion of the sensor 110 before (FIG. 14a) and after (FIG. 14b) collection from a homogeneous solution of K12 E. coli without the use of an electric field. Note the absence of bacteria collected in FIG. 14b in comparison to FIG. 13b showing the results of assisted collection.

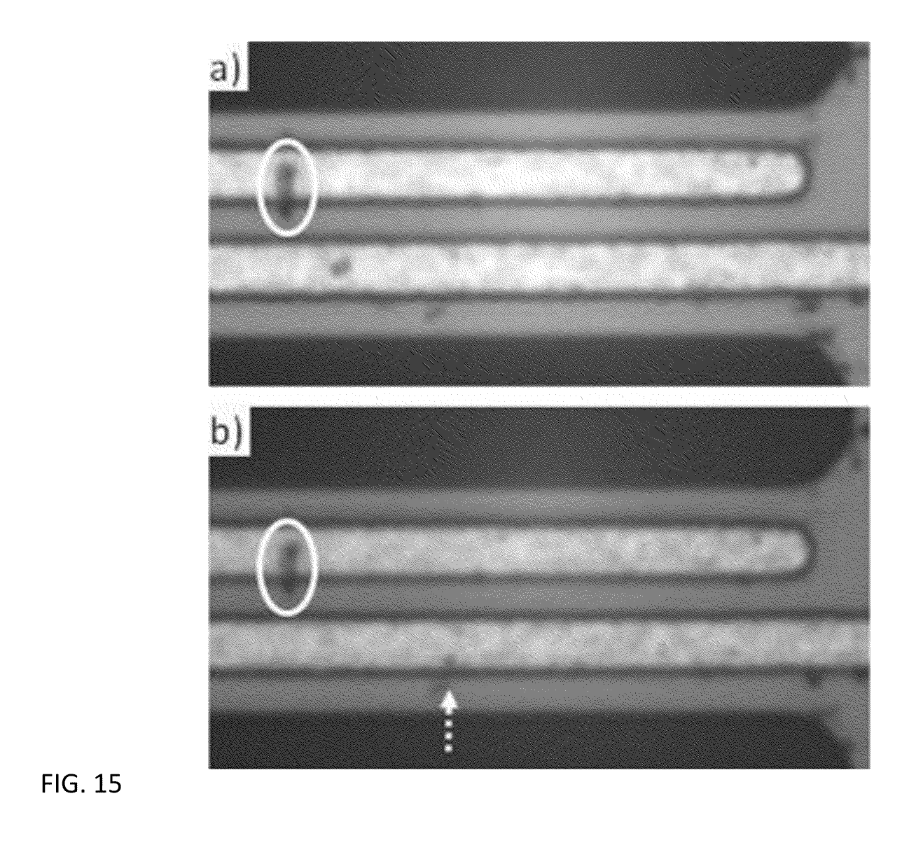

Under the same experimental conditions, the observed frequency shift for P. fluorescens was a small positive shift of the first mode of about 625 Hz for all tests (see FIG. 12). Images of an example device with the sensor 110 are shown in FIGS. 15a-b, before (FIG. 15a) and after (FIG. 15b) assisted collection from a homogeneous solution of P. fluorescens. As shown in FIG. 15b, there is limited collection of P. fluorescens. A typical P. fluorescens bacterium remaining on the sensor 110 is indicated shown by a dashed arrow. In this example, the sensor 110 was not completely free of debris as noted by the circled particle which is present before and after collection.

The results of this test indicate that the presence of any untargeted particles retained after collection and washing did not cause a significant shift in the frequency of the sensor 110, nor any increase in the stiffness of the sensor, nor any decrease in mass of the sensor 110 (e.g., due to protein desorption).

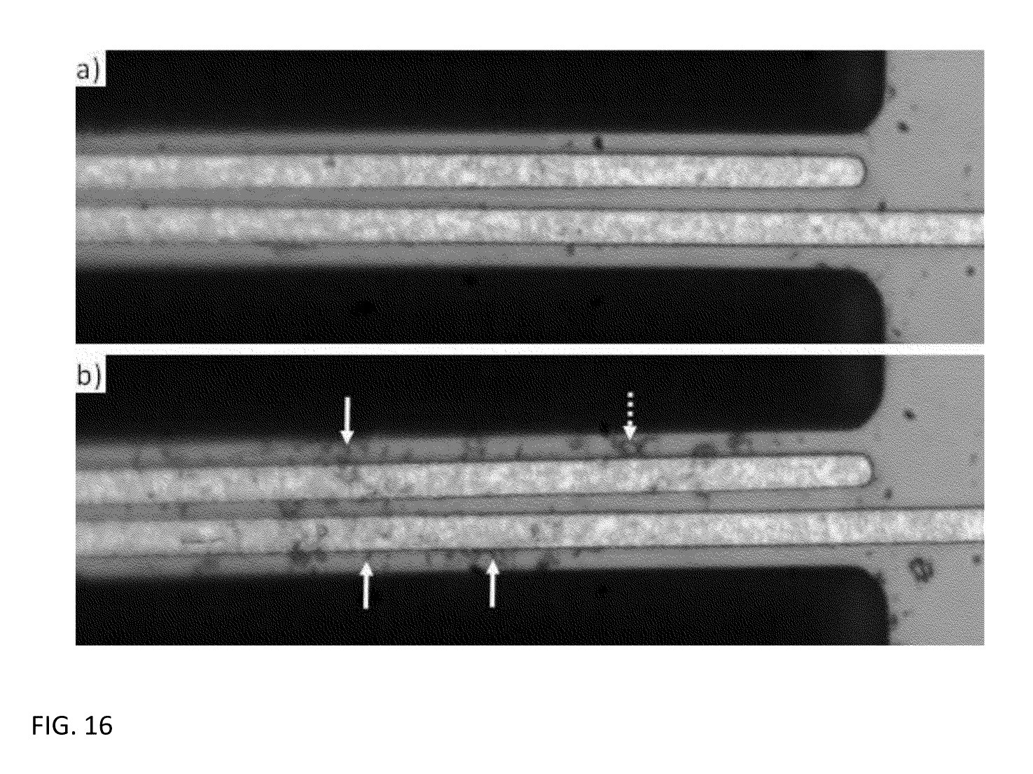

For tests with mixtures of targeted and untargeted bacteria, the results were found to be similar to that of the collection of the targeted K12 E. coli. The average shift in frequency was about −729 Hz (one standard deviation was about 477) (see FIG. 12). FIGS. 16a-b show images of example sensors 110 with a microstructure 111 having a fixed-fixed beam configuration, before (FIG. 16a) and after (FIG. 16b) assisted collection from a mixture of K12 E. coli and P. fluorescens. The sensors 110 were not completely free of debris prior to collection, which accounts for the presence of particles before collection. P. fluorescens may be observed as larger tube/string like structures (indicated by a dashed arrow). K12 E. coli may be observed as smaller spheroidal shapes (indicated by solid arrows). As shown in FIG. 16b, the targeted K12 E. coli account for a larger number of bacteria collected than the untargeted P. fluorescens.

The negative frequency shifts experienced by the sensor 110 in response to both E. coli-only and mixed samples demonstrate the ability of the sensor 110 to selectively and specifically detect the target pathogen (in this example, E. coli) from a mixture. Furthermore, the fixed-fixed beam configuration of the microstructure 111 in this example exhibited a greater shift in frequency in the first mode than did the cantilever beam configuration of the microstructure 111 in Example study 1 described above. Thus, in some examples, a sensor 110 having a microstructure 111 with a fixed-fixed beam configuration may be more sensitive to the presence of the target material(s) than a sensor 110 having a microstructure 111 with a cantilever beam configuration. Different sensors 110 may be suitable for detection of different target materials and/or generation of different electrical fields for different electrokinetic effects. Other such variations are described further below.

The above example studies illustrate sensitivity and selectivity of the sensor 110. The functionalization method used in these examples may provide selectivity and may enable functionalization of the sensor 110 at room temperature on a wet bench in a standard chemical laboratory. This may allow for creating selective functionalized surfaces on the sensor 110 without the need for specially trained personnel and may help to speed up fabrication of the sensor 110.

### EXAMPLE SENSOR DESIGNS

Several example designs for the sensor 110 are discussed below. Each design may be used to achieve different material collection and/or sensing results.

### Example Sensor Design 1

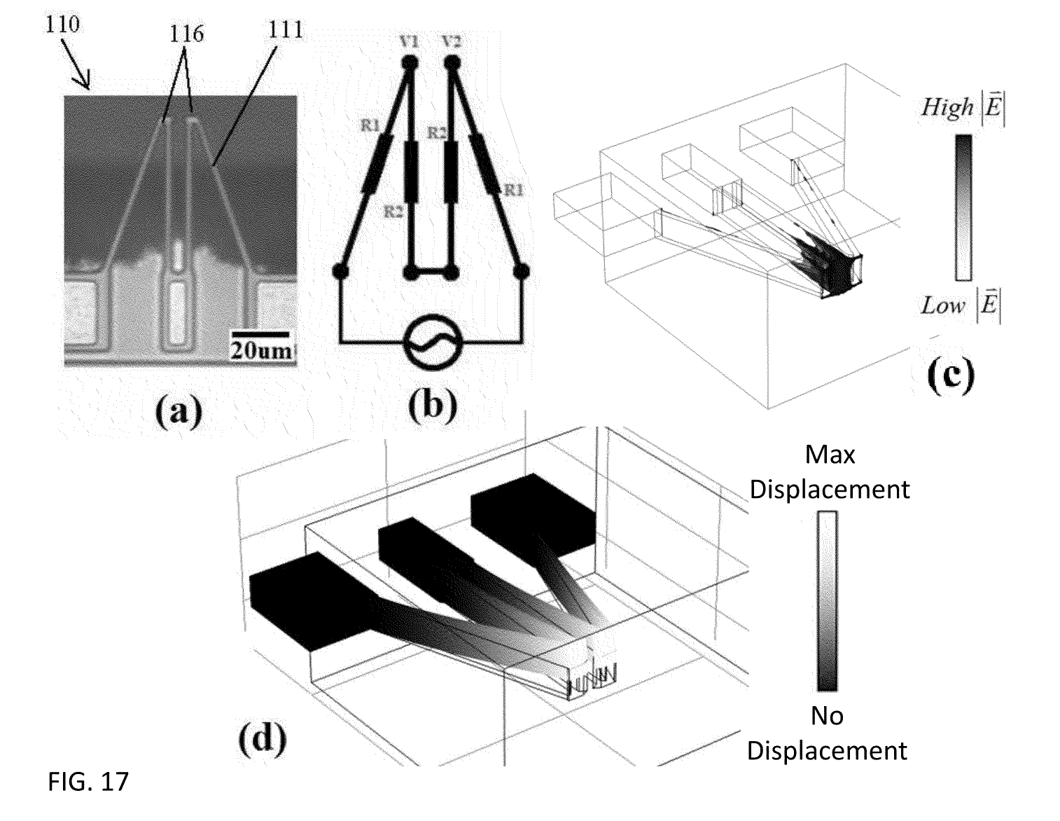

An example of a suitable sensor design is shown in FIGS. 17a-d. In this example, the sensor 110 may include a microstructure 111 having two beams configured as mechanically independent V-shaped cantilevers that may be electrically connected in series. In this example, rather than microelectrode(s) 112, the sensor 110 may use, as the feature for generating an electric field, inherent resistance of the microstructure 111, which may be modeled as resistors R1 and R2. FIG. 17a shows an optical micrograph of the example sensor 110, and FIG. 17b shows a circuit schematic of the example sensor 110, showing modeled resistive elements R1 and R2 suitable for generating a potential difference of |V2−V1| between the microstructure tips 116 when current is passed through the modeled resistors R1 and R2.

In this example, microstructure 111 may generate a suitably high electric field |E| at the free-end tips 116 by relying on: (i) the relatively small separation distances (e.g., on the order of several micrometers) between the collinear tips 116 of the adjacent beams, and (ii) resistively generated electric potential drop through the microstructure 111 (modeled as series resistors R1 and R2) as current is passed through both cantilever beams.

FIG. 17c shows an example electric field strength simulation showing regions of high |E| in the vicinity of the tips 116 of the microstructure 111. FIG. 17d shows an example simulation of mechanical displacement for the first out-of-plane mode of the sensor 110. It may be noted the tips 116 of the microstructure 111 (where |E| was found to be highest) may be coincident with or in the vicinity of the location of greatest mass-responsivity for material loading on the sensor 110.

When an example sensor 110 having this example design is immersed in a magnetic field of suitable orientation, the microstructure 111 may be mechanically excited in a desired direction using a suitable Lorentz force, while sufficiently high |E| may be generated at or about the same time for eliciting pDEP enhanced material collection, as described above. In the image shown, the current is expected to flow in the horizontal direction. A magnetic field may be applied in the out of plane direction. The Lorentz force generated may then be in the vertical direction. Any excitation force which elicits a dynamic displacement above the detector noise-floor threshold of a displacement transducer may be sufficient for a response to be detectable. The value of a sufficient amount of excitation force may be dependent on one or more factors, such as boundary and initial conditions and/or properties of the microstructure 111, and/or the choice of the displacement transducer, among others.

Material collection using this example sensor 110 may also be possible when material collection becomes large enough to result in the two formerly mechanically independent cantilever beams becoming mechanically coupled. This may result in a change (which may be relatively quick and significant) of their mechanical response. This may be useful to enable relatively quick detection of a threshold material collection quantity that may be correlated (all other conditions being relatively equal) to a threshold target material concentration, for example.

The threshold amount of material collected in order to elicit a response from the sensor 110 may be dependent on one or more factors. For example, the separation gap between neighboring microelectrodes 112 as well as whether material experience particle-particle attractive interactions when aggregating may play a role. Typically, the smaller the gap between microelectrodes 112 (depending on particle size of material), the smaller the amount of material needed to cause detectable mechanical coupling on the sensor 110. Typically, the stronger the attractive (or repulsive) attraction as well as the coupling forces generated, the greater the stiffness of the coupling. The coupling may be non-rigid (for example modeled as spring-damper coupling instead of rigid linkage) in some examples.

### Example Sensor Design 2

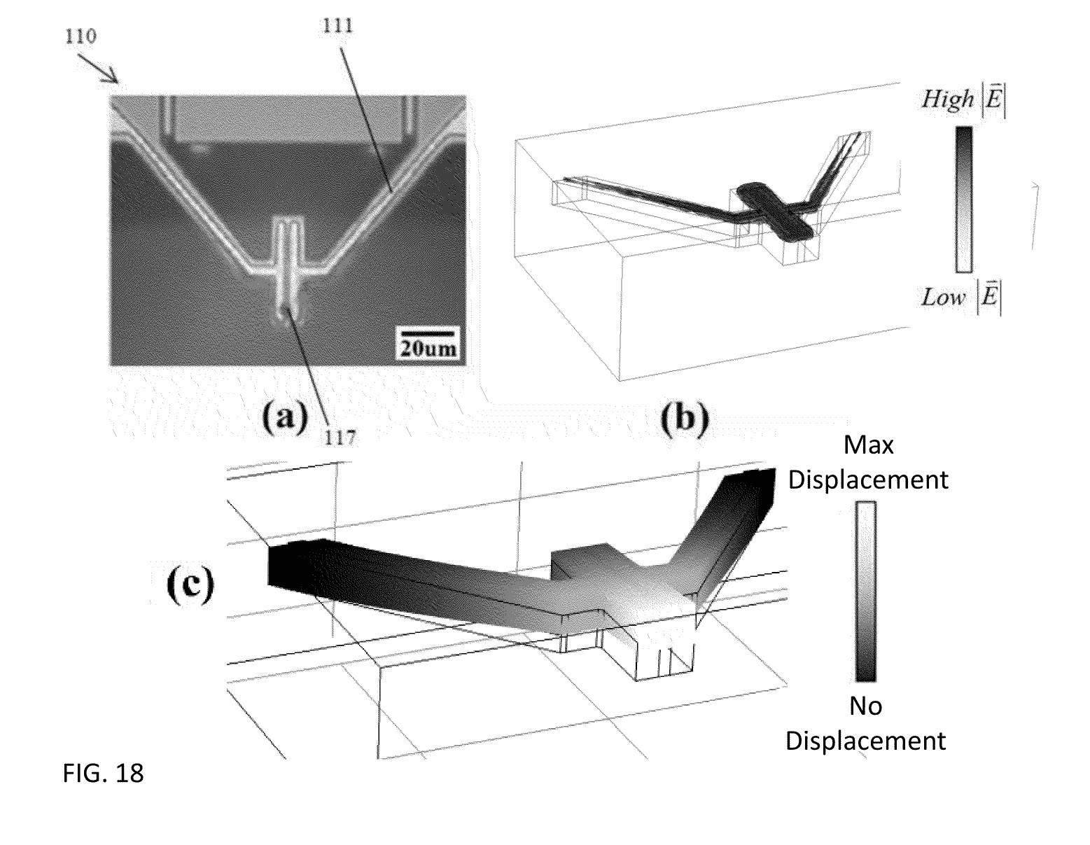

FIGS. 18a-c show another example design for the sensor 110. FIG. 18a shows an optical micrograph of the example sensor 110. In this example, the sensor 110 may be designed with the microstructure 111 as a V-shaped cantilever with a collection pad 117 at or near the apex of the V-shape (approximately at the center of the microstructure 111, for example). The pad 117 may be relatively large, for example larger than the tips 116 of example sensor design 1 above, which may be useful to accommodate more collected material. There may be one or more discrete microelectrodes 112 incorporated onto the example sensor 110, for example at or near the pad 117. This example sensor 110 may rely primarily on capacitive techniques for generating an electric field E in space (e.g., where two discrete microelectrodes 112 serve as a capacitive electric field-generating feature of the sensor 110). FIG. 18b shows an example simulated iso-surface plot of electric field strength showing regions of high |E| on the example sensor 110. FIG. 18c shows an example simulation of mechanical displacement for the first out-of-plane mode of the example sensor 110.

### Example Sensor Design 3

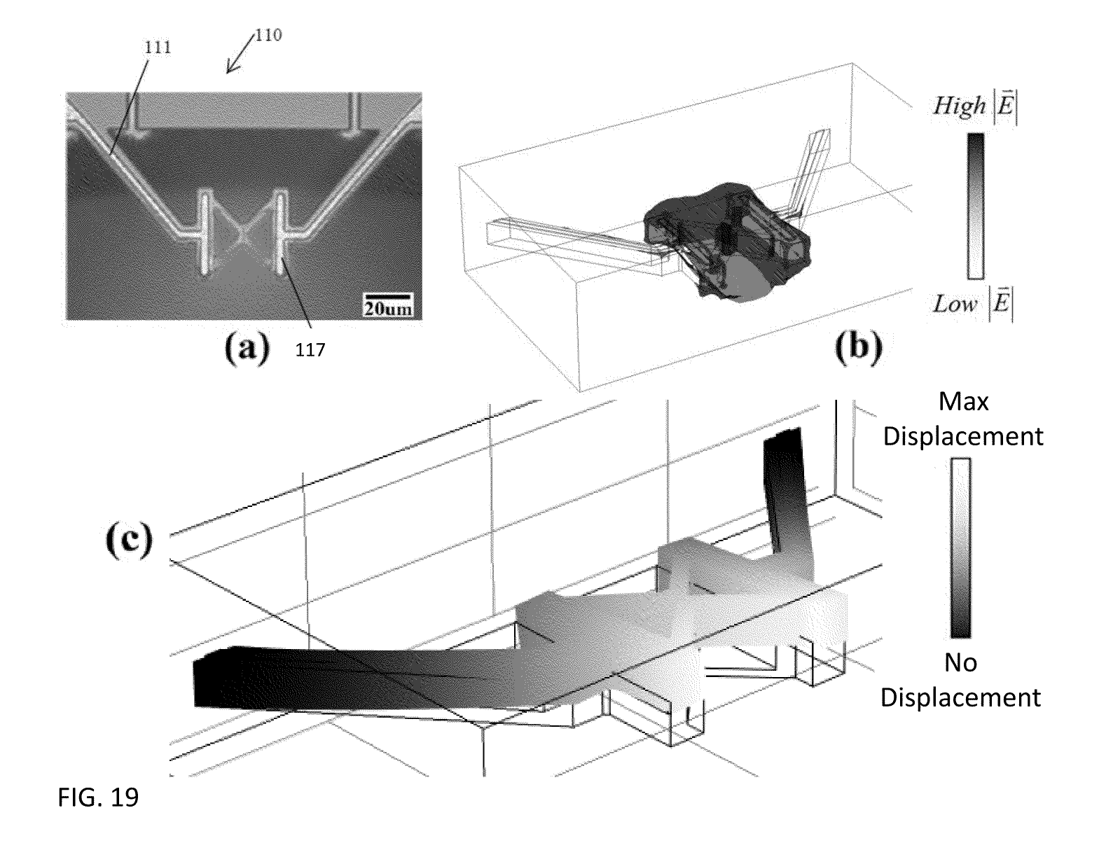

FIGS. 19a-c show another example design for the sensor 110. FIG. 19a shows an optical micrograph of the example sensor 110. In this example, the sensor 110 may be designed with the microstructure 111 as a V-shaped fixed-fixed beam with multiple higher-order modes that may have relatively small frequency separation from other modes. The pad 117 at the apex of the V-shape may be modified from a square pad by eliminating mass on the collection pad (e.g., by eliminating regions that do not contribute much to maximizing frequency shift based on expected material collection). This example design may introduce higher-order modes with smaller frequency separations allowing more higher-order modes to be measured for a given measurement bandwidth. In this example, there may be two microelectrodes 112 incorporated on the microstructure 111.

This design may offer multiple detectable modes for target material detection within a finite frequency range, which may be suitable for frequency measurement instruments having finite dynamic range. This example sensor 110 may rely primarily on capacitive techniques for generating an electric field E in space. FIG. 19b shows an example simulated iso-surface plot of electric field strength showing regions of high |E| on the example sensor 110. FIG. 19c shows an example simulation of mechanical displacement for the first out-of-plane mode of the example sensor 110. One or more of the higher modes may take advantage of the expected mass collection region (e.g., at the pad 117 on the apex of the V-shape) for enhanced sensitivity.

Although the higher-order modes were not shown, they can be used for detection purposes also. For example, at the pad 117, one or more higher order modes may be expected, where dynamic displacement is expected to be higher at the regions of expected collection. This may allow multiple higher-order modes to be used for detection. For example, different order modes can be cross-correlated for detecting the same finite quantity of collected material (e.g., for greater confidence in the sensed result).

### Example Sensor Design 4

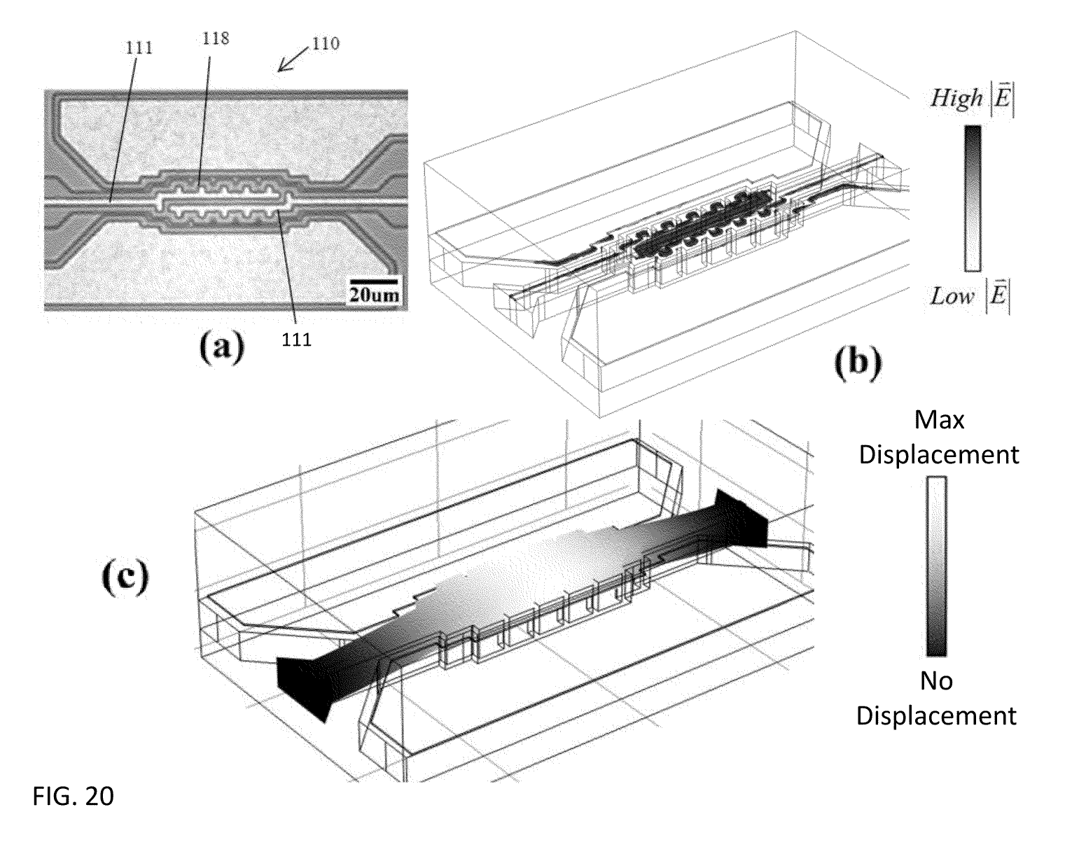

FIGS. 20a-c show another example design for the sensor 110. FIG. 20a shows an optical micrograph of the example sensor 110. In this example, the sensor 100 may be designed with the microstructure 111 as a fixed-fixed beam with microelectrode(s) 112 integrated onto the sensor 110. In this example, the microstructure 111 and the microelectrode(s) 112 may have one or more protrusions 118 extending away from the longitudinal axis of the microstructure 111, which protrusions 118 may help to increase local electric field E intensity and/or increase the material collection area. There may be mechanically fixed planar microelectrode(s) 112 having a relatively large surface area near or adjacent to the microstructure 111 on either side of the microstructure 111, which may help to enhance and/or modify the strength of the electrical field E at or near the microstructure 111. FIG. 20b shows an example simulated iso-surface plot of electric field strength showing regions of high |E| on the example sensor 110. FIG. 20c shows an example simulation of mechanical displacement for the first out-of-plane mode of the example sensor 110.

### Example Sensor Design 5

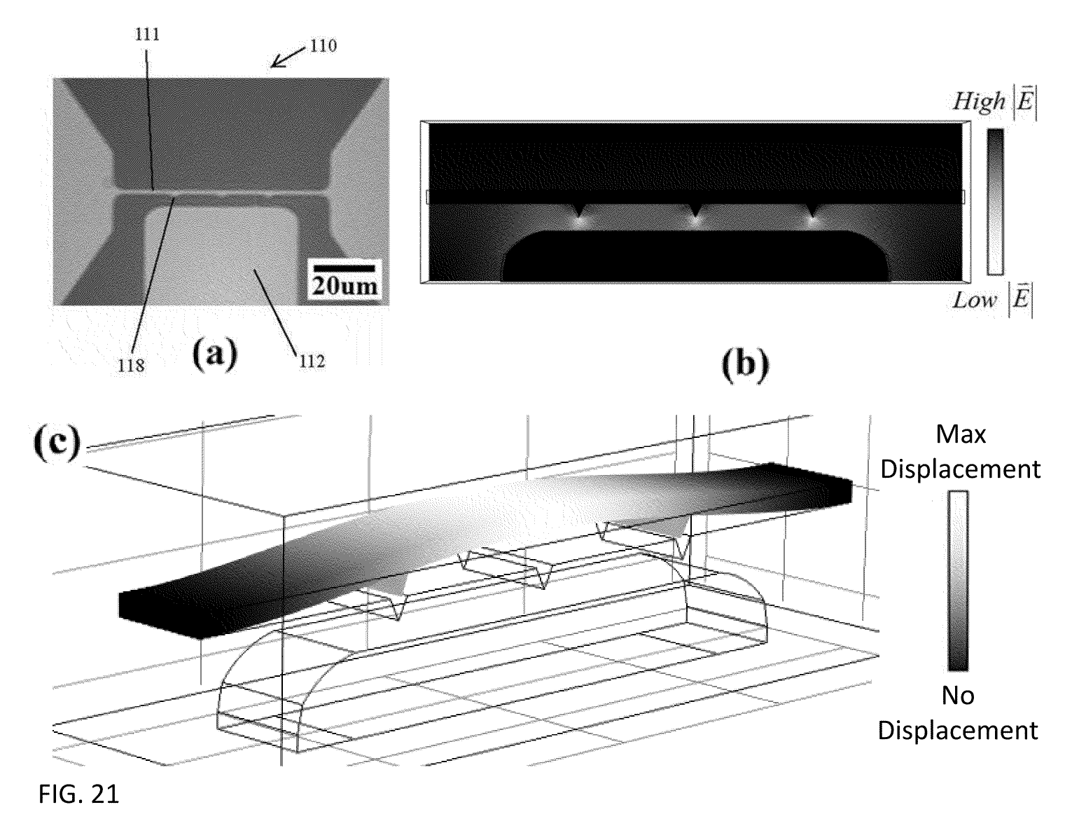

FIGS. 21a-c show another example design for the sensor 110. FIG. 21a shows an optical micrograph of the example sensor 110. In this example, the sensor 110 may be designed with the microstructure 111 as a fixed-fixed beam with microelectrode(s) 112 positioned at relatively pointed protrusions 118 along the length of the microstructure 111, and a stationary planar microelectrode 112 near or adjacent to the microstructure 111. FIG. 21b shows an example simulated iso-surface plot of electric field strength showing regions of high |E| on the example sensor 110. FIG. 21c shows an example simulation of mechanical displacement for the first out-of-plane mode of the example sensor 110. When a suitable potential is applied between the microelectrodes 112, or if AC current is passed through the microstructure 111 while the stationary electrode 112 is grounded, a relatively high |E| may be generated at the protrusions 118, which may result in the attraction of material by pDEP. The collection from pDEP at the microelectrode protrusions 118 may enhance higher-order mode sensitivity. The stationary electrode 112 may also be used for mechanical excitation of the sensor 110, as described elsewhere in this disclosure.

### Example Sensor Design 6

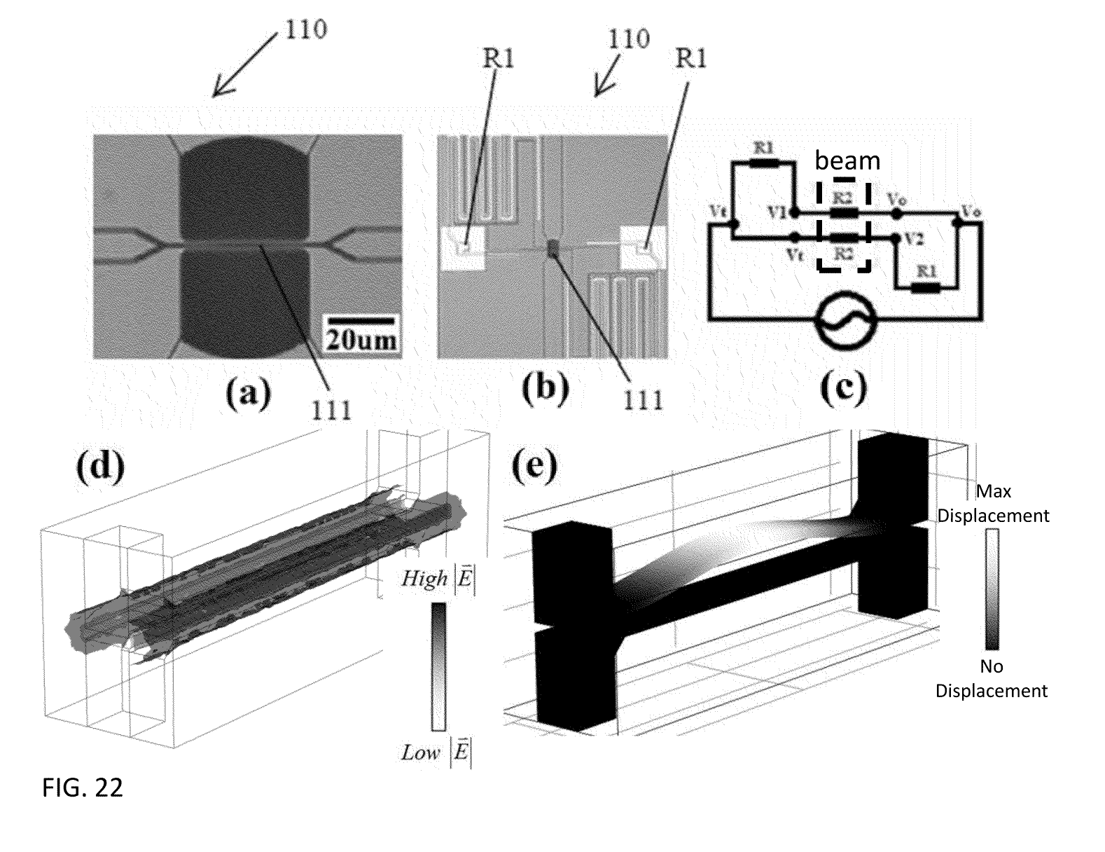

FIGS. 22a-e show another example design for the sensor 110. FIG. 22a shows an optical micrograph of the example sensor 110. In this example, the sensor 110 may be designed with the microstructure 111 configured as two mechanically independent fixed-fixed beams that may be near or adjacent to each other. As shown in the optical micrograph of FIG. 22b, the beams may each be electrically connected to respective on-chip resistors R1 (in addition to the resistance of the beams themselves, modeled as R2) that may be designed to create near or substantially constant potential difference between the two mechanically independent beams in the axial direction when a AC signal of zero offset is applied to the beams. FIG. 22c shows a schematic of the circuitry of the sensor 110 and on-chip resistors R1, with the beams being represented as resistors R2 inside a box. FIG. 22d shows an example simulation of the electric field strength E of the example sensor 110. FIG. 22e shows an example simulation of the first in-plane mode of one of the beams. Particle collection intensity may be relatively consistent between the two beams.

### Example Sensor Design 7

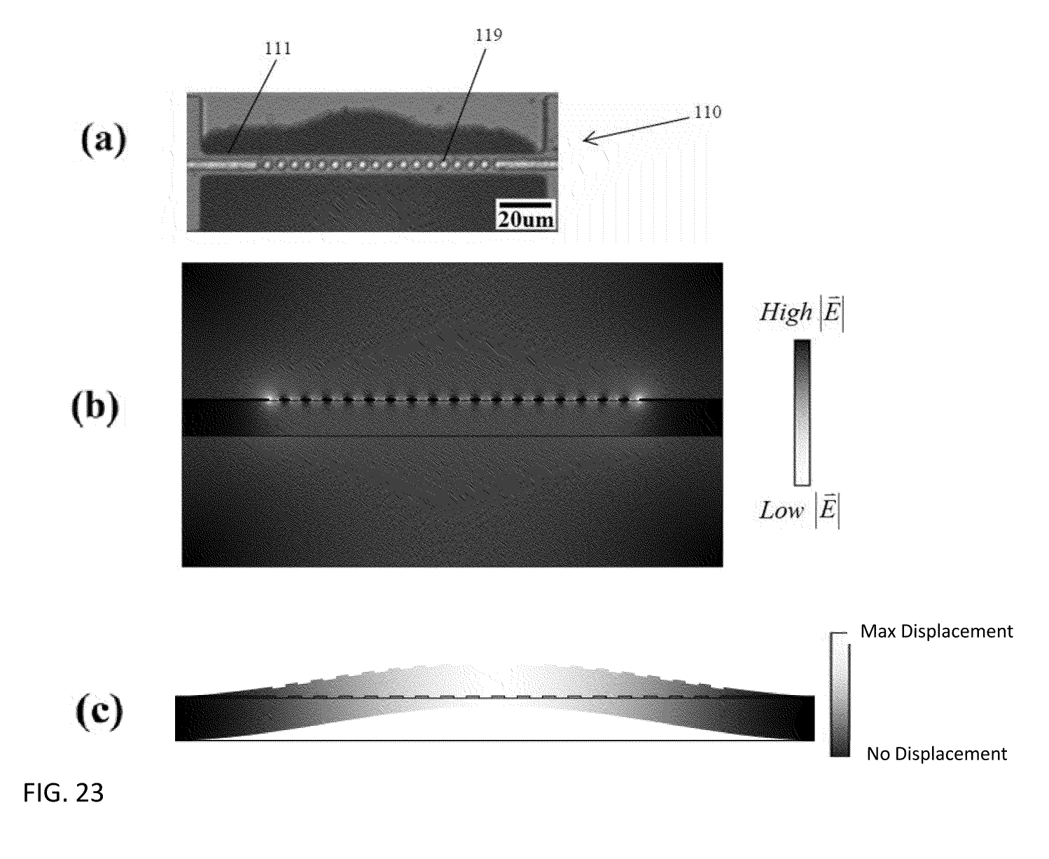

FIGS. 23a-c show another example design for the sensor 110. FIG. 23a shows an optical micrograph of the example sensor 110. In this example, the sensor 110 may be designed with the microstructure 111 as a fixed-fixed beam with a conductive material 119 (e.g., gold or other conductive metal) patterned intermittently or periodically on and/or in the microstructure 111. Electrically, the sensor 110 may be modeled as resistors in series that may have intermittent or periodic areas of high resistance (regions without gold) and low resistance (regions with gold deposited) elements. When a current is passed through the sensor 110, the current may cause a potential drop between high resistance elements, leading to relatively high electric field strength at the ends of the patterned gold regions, as shown in FIG. 23b, showing an example simulated field strength E in a cross-section of the sensor 110. FIG. 23c shows an example simulation of mechanical displacement for the first out-of-plane mode of the example sensor 110.

### Example Sensor Design 8

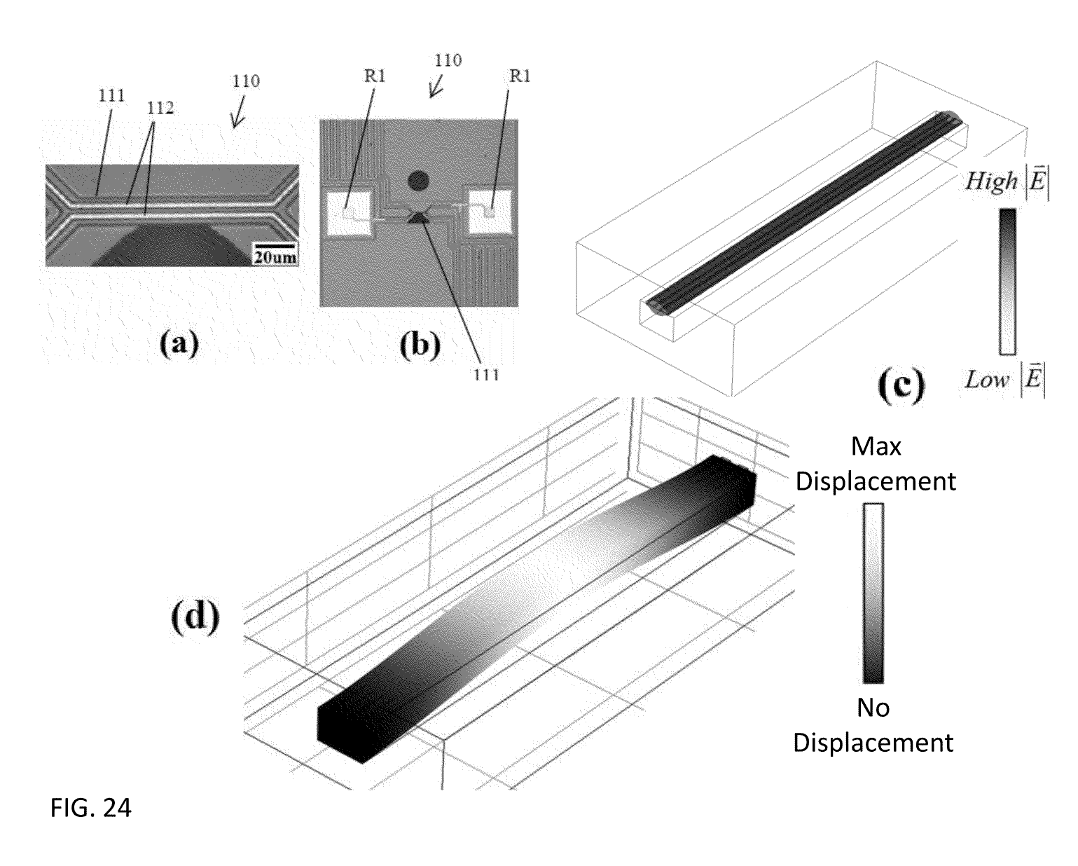

FIGS. 24a-d show another example design for the sensor 110. FIG. 24a shows an optical micrograph of the example sensor 110. FIG. 24b shows another optical micrograph of the example sensor 110, including on-chip integrated resistors R1. In this example, the sensor 110 includes a microstructure 111 configured as a fixed-fixed beam with two gold (or other suitable conductive material) microelectrodes 112 running along the axial direction of the microstructure 111. On-chip integrated resistors R1 (similar to example sensor design 6 described above) may be used to generate near or substantially constant potential drop across the entire microstructure 111. Compared to example sensor design 6 (which involves mechanically independent beams), the microelectrodes 112 in this example may be patterned on the same beam, and thus the collected material may be mass-loaded on the same beam. FIG. 24c shows an example simulated field strength in a cross-section of the sensor 110. FIG. 24d shows an example simulation of mechanical displacement for the first out-of-plane mode of the example sensor 110.

### Example Sensor Design 9

FIGS. 25a-c show another example design for the sensor 110. FIG. 25a shows an optical micrograph of the example sensor 110. In this example, the sensor 110 may include a microstructure 111 configured as a fixed-fixed beam with a reduction in cross-sectional area in a section (circled) of the microstructure 111, for example at or near the center along the length of the microstructure 111. This cross-sectional reduction may result in resistive potential drop in the vicinity of the reduction, resulting in a higher |Eᵣₘₛ| at or near that region of the microstructure 111. In this example, the cross-sectional reduction may occur at or near the middle of the length of the microstructure 111, and material collection may be expected near the center of the microstructure 111 by pDEP. FIG. 25b shows an example simulated iso-surface field strength in the example sensor 110. FIG. 25c shows an example simulation of mechanical displacement for the first out-of-plane mode of the example sensor 110.

FIG. 25a shows example experimental results before (top image) and after (bottom image) pDEP-assisted collection of E. coli, with an aggregate of the collected E. coli formed in the vicinity of the cross-sectional reduction (also referred to as a pDEP “trap”). This ability to retain and/or detect an aggregate of particles may extend the detection capability of the example sensor 110, since surface-based sensors typically have finite saturation adsorption capacity.

For example, the aggregate may collect target materials in spatial space, other than a surface. The ability to detect particle aggregates instead of only surface-based detection may be useful to overcome limitations of surface-based sensors, such as saturation of the sensing surface. For the aggregate-based method, an upstream separation process may provide material selectivity (p- and n-DEP may additionally provide another degree of selectivity). When a single type of material is introduced to the sensor 110, that material may form an aggregate that is then detected. It is possible this aggregate contains much higher total quantity of material than that provided by a finite sensing surface area. By detecting aggregates, it may be possible to limit coupling of material to only desired regions (e.g., antinodes) of the microstructure 111 while still detecting a larger amount of material. The ability to aggregates may thus extend the dynamic range of the sensor 110.

### Example Sensor Design 10

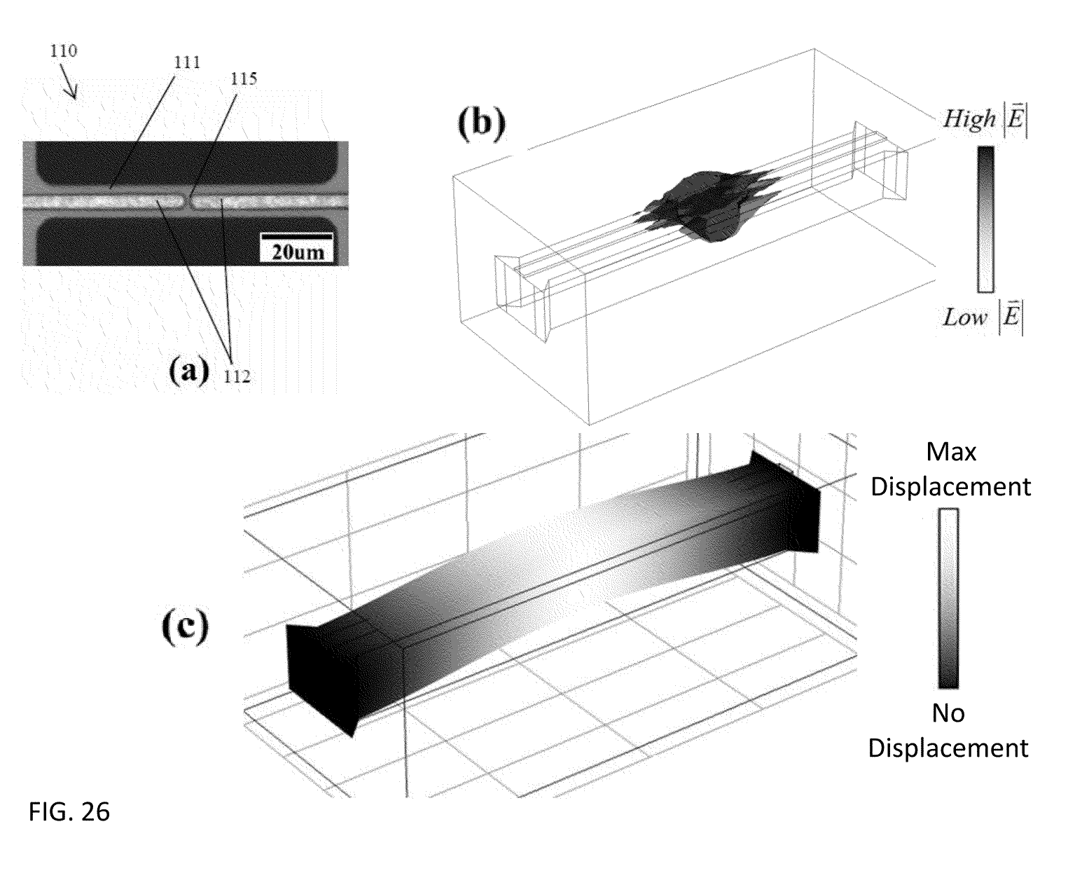

FIGS. 26a-c show another example design for the sensor 110. FIG. 26a shows an optical micrograph of the example sensor 110. In this example, the sensor 110 may include a microstructure 111 configured as a fixed-fixed beam with substantially co-linear microelectrodes 112, which may share substantially the same longitudinal axis with each other and with the microstructure 111, and which microelectrodes 112 may be separated by a gap 115. FIG. 26b shows an example simulated iso-surface field strength in the example sensor 110. FIG. 26c shows an example simulation of mechanical displacement for the first out-of-plane mode of the example sensor 110. Relatively high |Eᵣₘₛ| may be generated in the gap between the microelectrodes 112 in order to collect material at or near the gap 115.

### Example Sensor Design 11

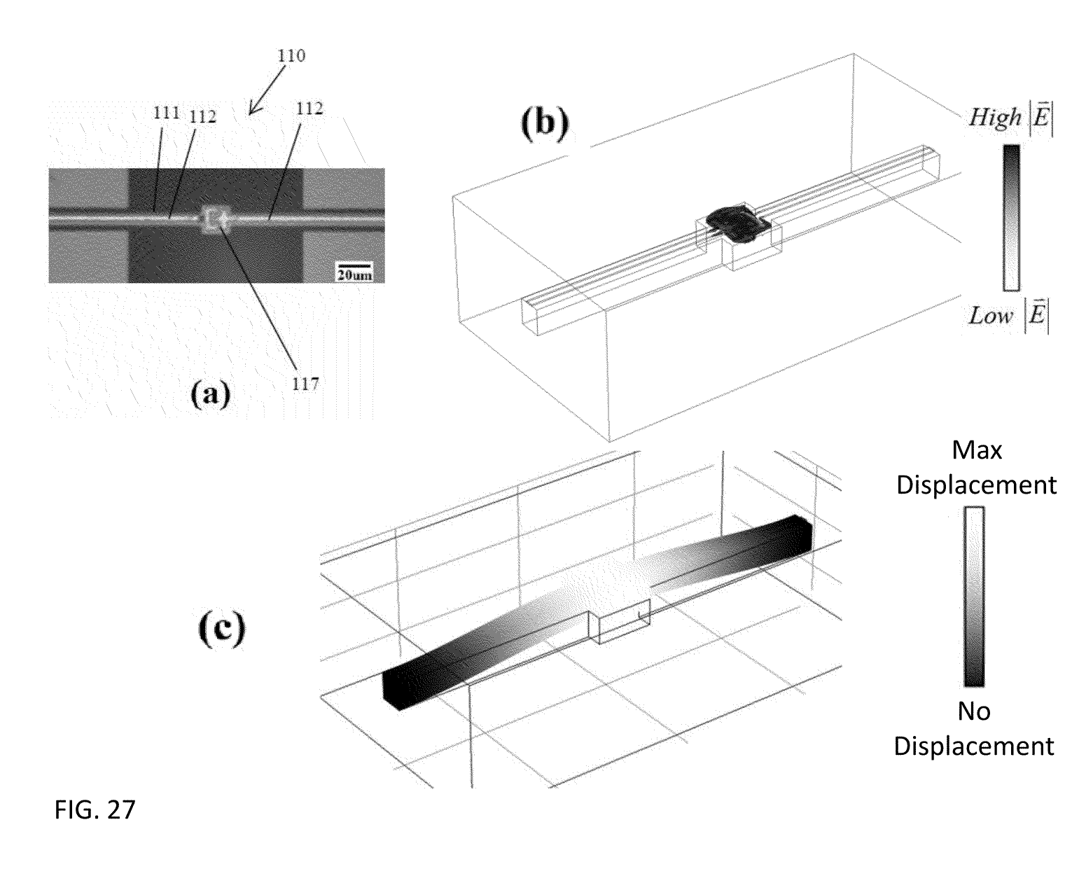

FIGS. 27a-c show another example design for the sensor 110. FIG. 27a shows an optical micrograph of the example sensor 110. In this example, the sensor 110 may include a microstructure 111 configured as a fixed-fixed beam with microelectrodes 112 having complementary (e.g., interleaved or interdigitated) configurations at a pad region 117 (which may be located at or near the middle of the microstructure 111) of the example sensor 110. Such a configuration for the microelectrodes 112 may result in an increased area for adsorption of material. FIG. 27b shows an example simulated iso-surface field strength in the example sensor 110. FIG. 27c shows an example simulation of mechanical displacement for the first out-of-plane mode of the example sensor 110.

### Example Sensor Design 12

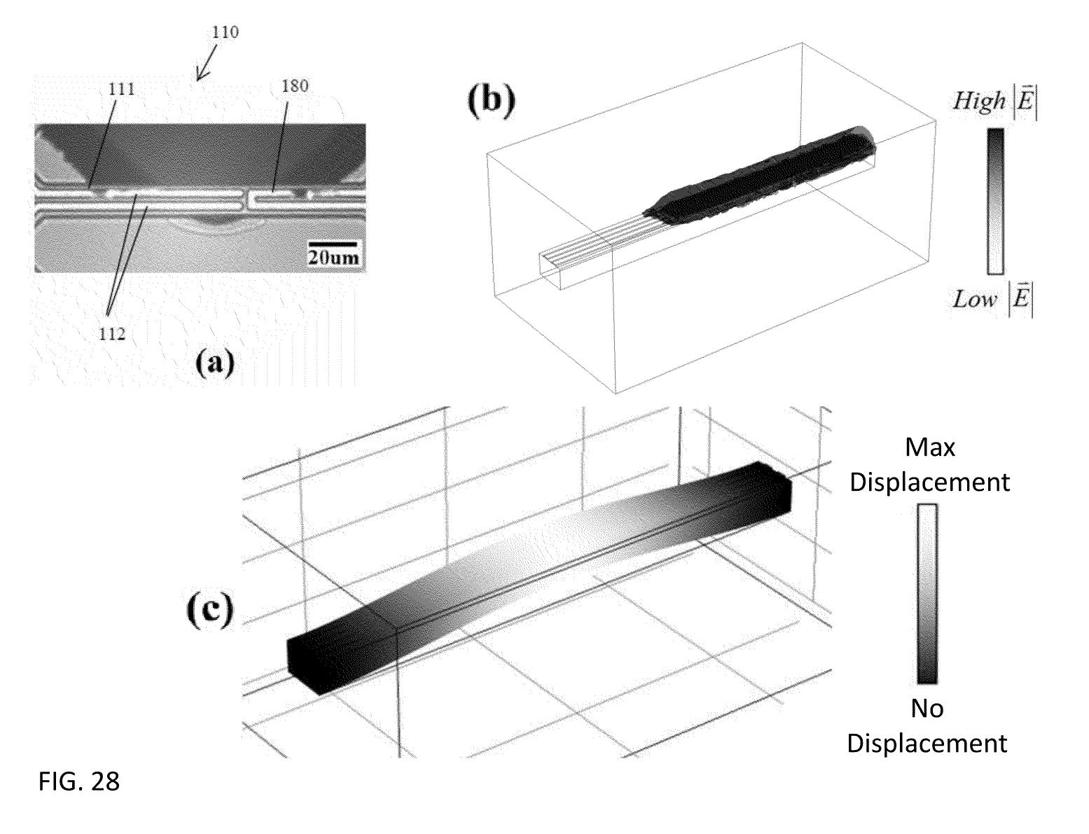

FIGS. 28a-c show another example design for the sensor 110. FIG. 28a shows an optical micrograph of the example sensor 110. In this example, the sensor 110 may include a microstructure 111 configured as a fixed-fixed beam with three microelectrodes 112. Two of the three electrodes 112 (shown on the left side in FIG. 28a) may enable particle collection using electrokinetics based on a capacitive-based method of generating electric field. The other electrode 112 (shown on the right side in FIG. 28a) may serve as the excitation electrode 180 and may enable mechanical excitation of the microstructure 111 using the magnetic Lorentz force (e.g., when current is passed through the excitation electrode 180 while the excitation electrode 180 is submersed in a magnetic field). The excitation electrode 180 may be positioned along the microstructure 111 in a position designed to excite higher amplitude response of the higher-order modes (which may also be more mass responsive). FIG. 28b shows an example simulated iso-surface field strength in the example sensor 110. FIG. 28c shows an example simulation of mechanical displacement for the first out-of-plane mode of the example sensor 110.

### Example Sensor Design 13

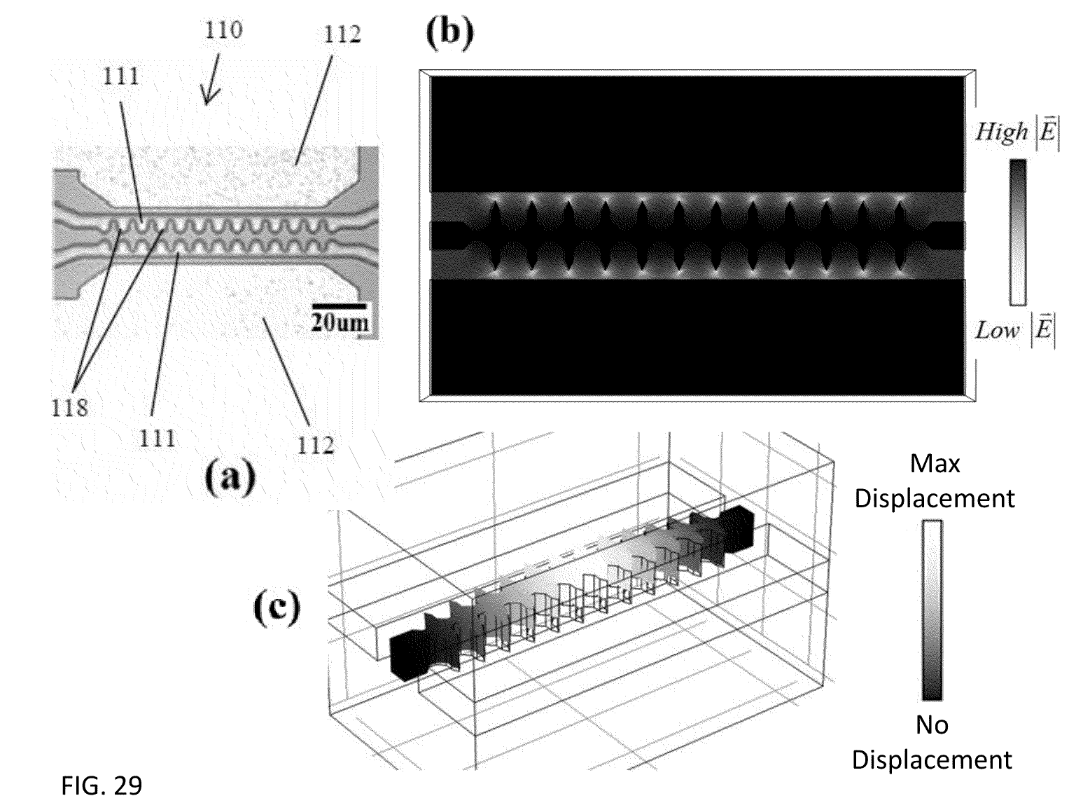

FIGS. 29a-c show another example design for the sensor 110. FIG. 29a shows an optical micrograph of the example sensor 110. In this example, the sensor 110 may include a microstructure 111 configured as a fixed-fixed beam with lateral protrusions 118 intermittently or periodically along the length of the microstructure 111. Near or adjacent to the microstructure 111 are fixed planar microelectrodes 112 on either lateral side. In this example, when the microstructure 111 and the planar microelectrodes 112 are energized, a relatively high |Eᵣₘₛ| may be generated at or near the tip regions of the lateral protrusions 118 of the microstructure 111, which may enhance material collection at the tips of the protrusions 118. FIG. 29b shows an example simulated iso-surface field strength in the example sensor 110. FIG. 29c shows an example simulation of mechanical displacement for the first out-of-plane mode of the example sensor 110.

### Example Sensor Design 14

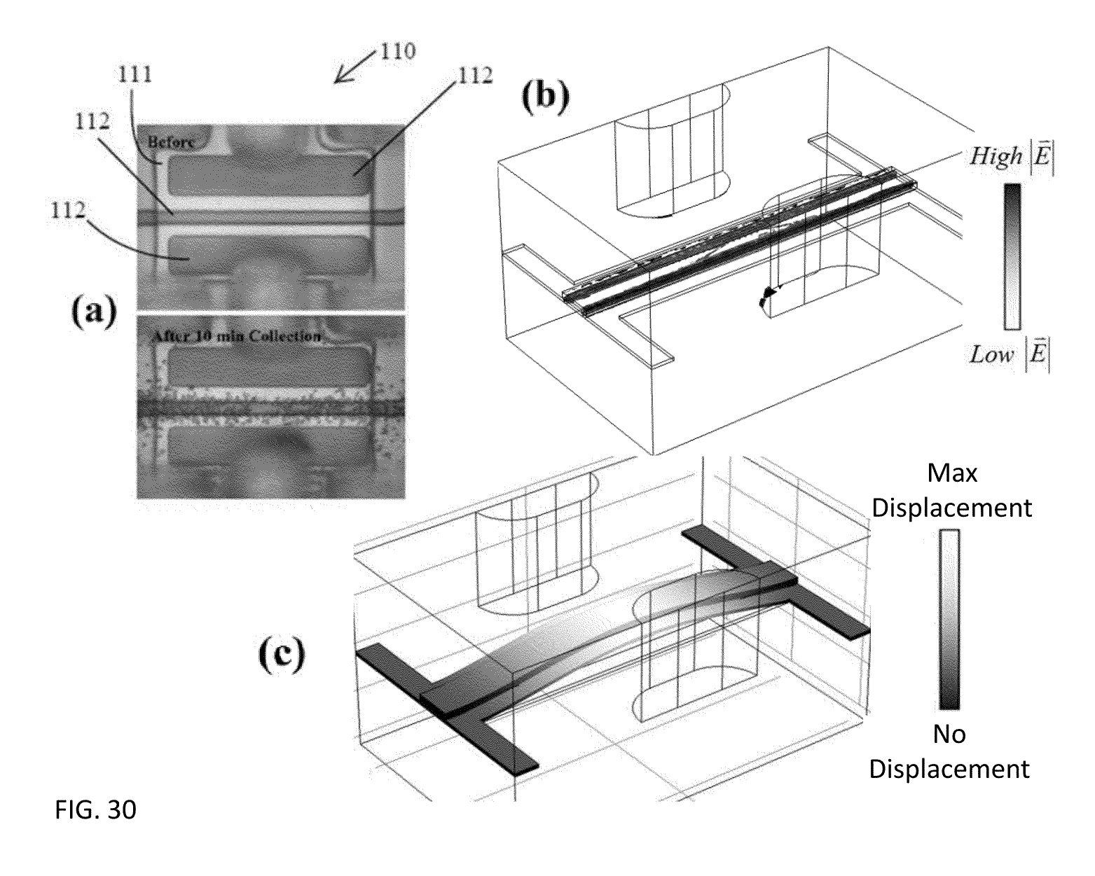

FIGS. 30a-c show another example design for the sensor 110. FIG. 30a shows an optical micrograph of the example sensor 110. In this example, the sensor 110 may include a microstructure 111 configured as a fixed-fixed beam with electrically conducting microelectrodes 112 (which may be made of polysilicon) mostly or completely encapsulated by an insulator (which may be made of silicon nitride) on the beam 111 having no or low electrical conductivity. Near or adjacent to the sensor may be two static microelectrodes 112 (see at top and bottom of image), which may be made of nickel. FIG. 30b shows an example simulated iso-surface field strength in the example sensor 110. FIG. 30c shows an example simulation of mechanical displacement for the first out-of-plane mode of the example sensor 110. This example design, having electrically insulated microelectrodes 112, may allow higher voltages to be applied to the microelectrodes 112 while reducing or avoiding electrolytic effects.

Generally, electrolytic effects may be undesirable since such effects may generate gas bubbles that may disrupt collection and/or may prevent measurement (for example if measured using a laser). Electrolysis may also be detrimental to the microelectrode(s) 112. Electrolysis may also introduce ions to the sample fluid thereby unexpectedly changing fluid properties.

Mechanical Excitation Concurrent with Electrokinetic Effects

Eliciting both electrokinetic phenomena and mechanical excitation of the sensor 110 using the same signal may be useful for improving temporal resolution of detection and/or simplifying the sensor 110, device 100 and system 1000. This may also simplify integration with other systems, which may translate to higher system reliability, among other advantages. Single-frequency or multi-frequency signals may be used for such a purpose.

The signal for mechanically exciting the sensor 110 and the signal for eliciting electrokinetic effects may be independent and decoupled while occurring simultaneously. For example, piezoelectric actuators may be used for mechanical excitation of the sensor 110 using one signal, while electrokinetic effects may be elicited using another signal.

In some examples, the same electrical excitation signal may be used to perform both mechanical excitation and to elicit electrokinetic effects simultaneously. For example, a current may be passed through the sensor 110 in a magnetic field to enable the magnetic Lorentz force to excite the microstructure 111 while the same signal elicits electrokinetic effects.

For any given system setup, there may be certain frequencies for eliciting electrokinetic effects that may yield better performance for sensing. For example, if a sensor 110 is designed be to operated based on pDEP, certain frequency ranges may elicit stronger pDEP of material while other frequencies may elicit nDEP. The resonant frequencies of the microstructure 111 may also be generally non-fluctuating (prior to material-loading and neglecting transient fluctuations).

In some examples, the frequency for eliciting electrokinetics may be substantially equal to the resonant frequency of the microstructure 111. In this case, a single frequency or a narrow frequency bandwidth may be used for eliciting both resonance and electrokinetically enhanced collection. Material detection may be performed using amplitude modulation techniques if the excitation signal frequency is non-changing.

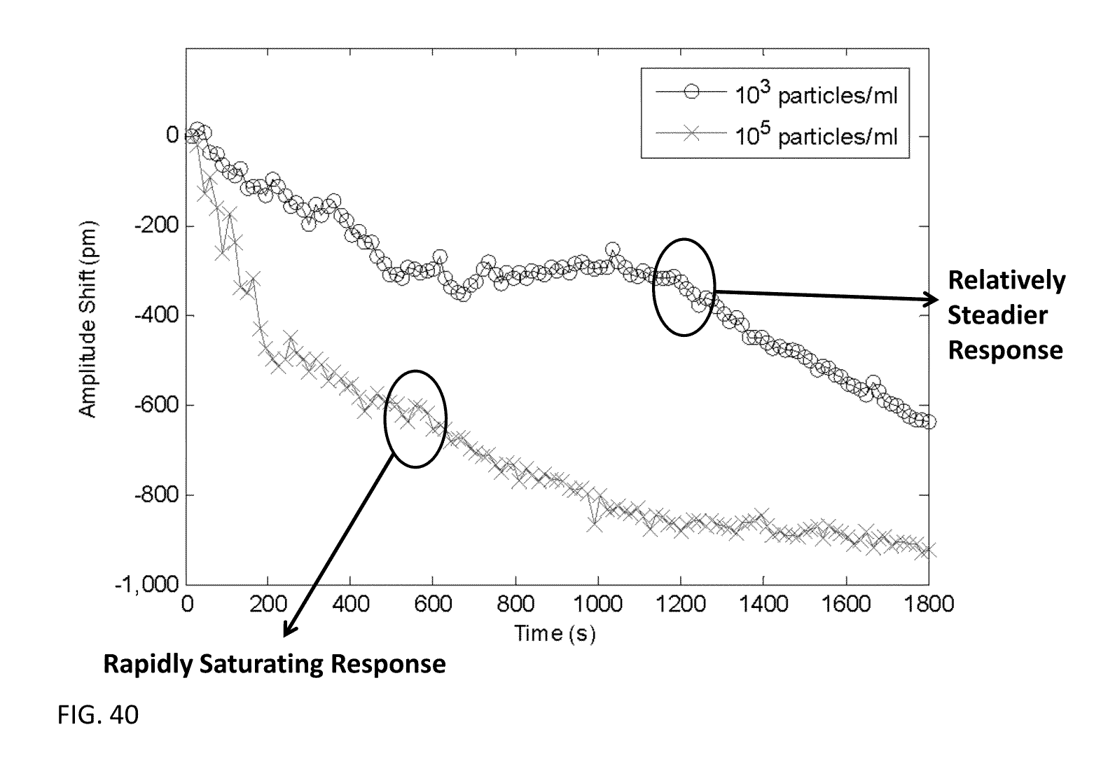

FIG. 40 illustrates the detection response of an example sensor 110 that was excited using a single frequency signal at about 1 MHz. In this example, the sensor 110 was used for detection of E. coli in deionized (DI) water. Particle suspensions of E. coli in DI water were passed through a microchannel 150 to the sensor 110 at a fixed flow rate of 1 mL/hr. The single frequency signal was found to induce both mechanical oscillation near the resonance of the microstructure 111 as well as pDEP of E. coli. The example results shown in FIG. 40 show an enhanced rate of detection for E. coli at the higher particle concentration of 10⁵ particles/mL (showing a more rapidly saturating response) compared with solutions at 10³ particles/mL (showing a relatively steadier frequency response).

Both mechanical resonance and DEP (as well as other electrokinetic effects) may have frequency dependencies that may be independent of one another. The use of a multi-frequency signal may facilitate in-situ, substantially real-time detection (e.g., in a liquid) with the assistance of electrokinetic effects, such that the microstructure 111 may be mechanically excited at its resonant frequency (which may enable amplitude modulation based detection) and such that suitably high electrokinetics-assisted collection responses may be achieved, by generating an AC electric field having different frequencies.

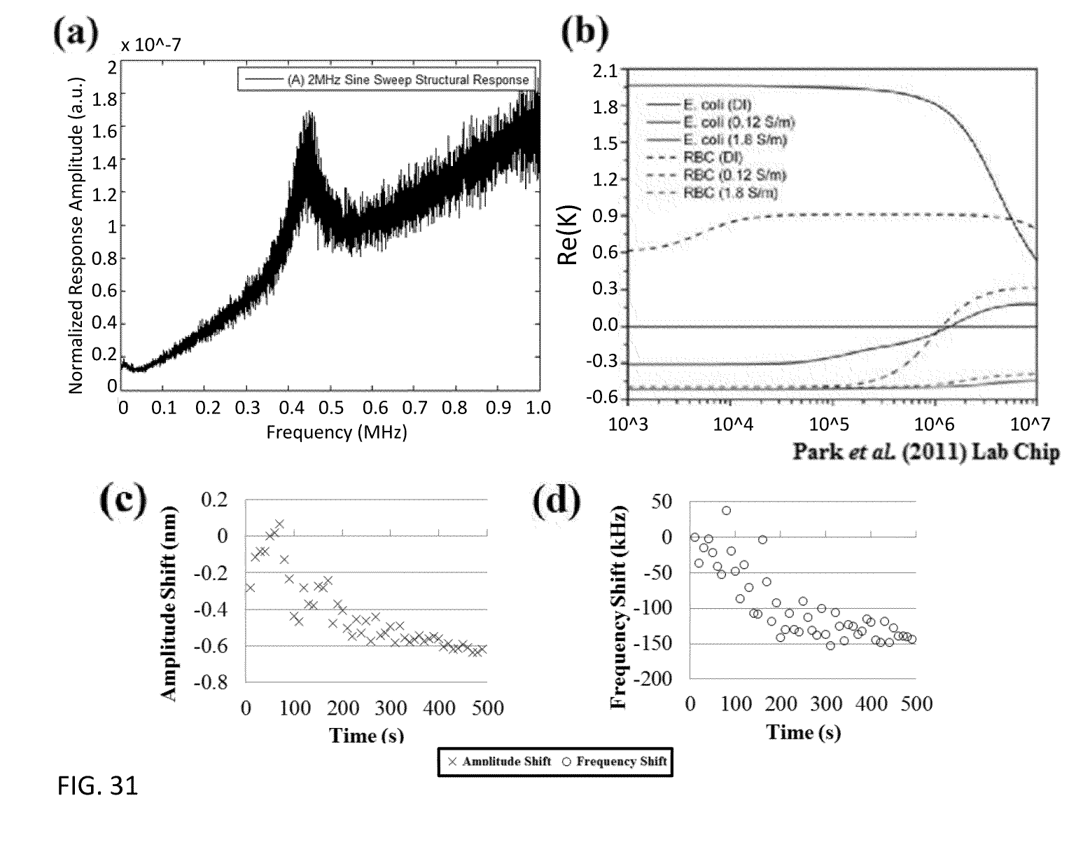

FIGS. 31a-d show example results of applying a multi-frequency signal to example sensor 14 described above. In this example, the sensor 110 was used for in-situ detection of E. coli in liquid media. FIG. 31a shows example frequency response of the sensor 110 in liquid prior to E. coli mass loading. Some relevant data showing expected Clausius-Mossotti factor of E. coli taken from [68] are shown in FIG. 31b.

FIG. 31b compares the Clausius-Mossoti (CM) factor of E. coli as a function of frequency. For example, consider E. coli in a moderate conductivity solution (e.g., about 0.12 S/m). FIG. 31b indicates that E. coli is expected to experience nDEP at frequencies below 1 MHz (because CM factor is negative), while above 1 MHz, E. coli experiences pDEP (because CM factor is positive). On the other hand, resonant frequencies of the microstructure 111 may vary depending on various design parameters and/or goals. Higher-order modes are typically at higher frequencies than the fundamental mode. In order to elicit both strong electrokinetic effects while eliciting strong mechanical resonant excitation, multi-frequency signals may be used. These separate frequency requirements may need to be considered in order to simultaneously eliciting electrokinetics with mechanical excitation.

Typically, when the microstructure 111 is excited in-situ in a liquid, the virtual mass effect due to the fluid may increase the effective mass of the microstructure 111 which may reduce its resonant frequency while immersed in a liquid. As shown in FIG. 31a, for the example sensor 110, the fundamental resonant frequency was found to be about 0.45 MHz in de-ionized water (and was found to be above about 1 MHz in air). The liquid may also dampen the oscillations, which may result in a lower Quality Factor response.

When relying on amplitude modulation to detect mass change, the sensor 110 may be excited at or near resonance and monitored for changes in the oscillation amplitude, as described above. In this example, the ideal excitation is near about 0.45 MHz. However, E. coli may experience nDEP when excited at 0.45 MHz, while the sensor 110 may be designed for utilizing pDEP to collect particles onto the microstructure 111. Depending on the media conductivity, pDEP of E. coli may occur at above around 1 MHz, for example.

In this example, by applying multi-frequency signals, both resonant oscillation of the sensor 110 (for amplitude modulation detection of mass) and pDEP collection may be possible. In this example, signals of about 0.45 MHz and about 1 MHz may be frequency mixed and used for excitation, which may result in both fundamental mode mechanical oscillation of the sensor 110 while eliciting pDEP-assisted collection to the microstructure 111 at or about the same time. In this example, the resonance and the oscillation amplitude of the microstructure 111 were monitored in real-time in a liquid for the collection of E. coli and is shown in FIG. 31c (showing the resonant amplitude shift) and in FIG. 31d (showing the resonant frequency shift).

In this example, a multi-frequency signal was used, comprising a summation of a small excitation amplitude frequency sweep signal over a wide bandwidth, a single-frequency signal at about 1 MHz (for eliciting pDEP), and another single-frequency signal at about 0.45 MHz. The small amplitude sweep signal was added for demonstration purposes to allow the resonant frequency to be measured due to the wide bandwidth covering the resonant frequency (for this example microstructure, resonant frequency was about 0.45 MHz). The sweeping signal may not be needed or used (e.g., if an amplitude modulation method of detection is used instead). The 1 MHz signal may elicit pDEP for collection of E. coli on the microstructure 111. The 0.45 MHz signal may cause mechanical excitation of the microstructure 111 at its first mode resonance when immersed in water, to facilitate the amplitude-modulation method of sensing.

The results shown in FIGS. 31c-d compare frequency shift and amplitude modulation methods of sensing. The results demonstrate agreement between the two, indicating that amplitude modulation is a suitable method of sensing (resonant frequency shift is typically the sensing method used). The results also show a saturating condition for the detection signal, discussed further below.

The scenario where the preferred frequency for eliciting electrokinetics is different from the resonant frequency(ies) of the microstructure 111 may be more common, in which case multi-frequency signals may be suitable. This may be because matching between the different frequencies cannot be guaranteed, either by design (e.g., a sensor 110 may have higher mass-responsivity at higher frequencies (on the order of MHz or above), but electrokinetic effects may occur at lower frequencies) or by practical realities. Other advantages related to using multi-frequency signals may include, for example, enhanced capabilities (such as simultaneous read out of multiple modes) and higher sensitivity detections (such as relying on higher-order modes).

Other electrokinetic phenomena may have |E|² dependency. Thus, electrokinetic structural excitation response may cause an expected frequency doubling response component.

For example, various electrokinetic phenomena exhibit a |E|² dependency in time-domain formulation that describes the forces. In the absence of a DC field or static charge, this may lead to frequency doubling due to the signal rectification nature of the squaring, where:

Given: E=E₀ sin(ωt)

Then: E²=X(1−cos(2ωt))

Where: X=(E₀²)/2

Thus, a frequency doubling may be expected in the mechanical excitation signal. This may be relevant where electrokinetic phenomena is relied upon for mechanical excitation (which may influence choice of excitation and design parameters again, when multi-frequency signals are to be used), since mechanical excitation frequency may be actually doubled. With a DC component in the electric field (e.g., from an applied potential and/or from static charges on the microstructure 111), the single frequency component may play a role along with the frequency doubled component. However, when using other methods of exciting the microstructure 111, such as relying on Lorentz force, the frequency response may be equal to the frequency of the excitation signal.

### Thermal Ablation

Surface-based sensors typically rely on surface area for retaining and/or detecting material. For typical surface-based sensors, there may be a saturation adsorption capacity (i.e., where the detection surface has been saturated with adsorbed material and is unable to adsorb additional material) which may limit their mass range for detection. Even if surface saturation is not reached, the accumulation of material on the sensor 110 may reduce the mass-responsivity of the sensor 110. Similar challenges may be faced where a material is internally sequestered in the sensor 110.

FIGS. 31c-d, also discussed above, show example results of saturation adsorption limited detection as free surface area for retaining material become occupied over the duration of an applied signal. As shown in FIGS. 31c-d, the amplitude and frequency shifts exhibited by the example sensor 110 levels out after a time of about 500 s, indicating that additional material may not be detected after that point.

Thermal ablation may be a suitable method to remove or eliminate adsorbed particles on the surface (or other sensing region) of the sensor 110, and return the sensor 110 fully or partially to its initial material-free state. Thermal ablation may also be suitable for removing or eliminating particles sequestered internally in the sensor 110. This may enable the sensor 110 to be used for longer duration detection applications and/or may enable the sensor 110 to be re-used for the same or different application.

In this example, when current is passed through the sensor 110, electrical energy is dissipated in the microstructure 111, which may lead to the generation of relatively high temperatures locally at the microstructure 111 by Joule heating. The high temperatures may be generated relatively quickly to thermally ablate adsorbed materials (in particular biological materials). For a sensor 110 with relatively small mass, relatively low heat capacity and relatively high thermal conductivity, the sensor 110 may be quickly cooled back to operating temperatures for a quick return to operation (e.g., within sub-milliseconds of cessation of applied electrical heating power after heating to temperatures on the order of hundreds of K).

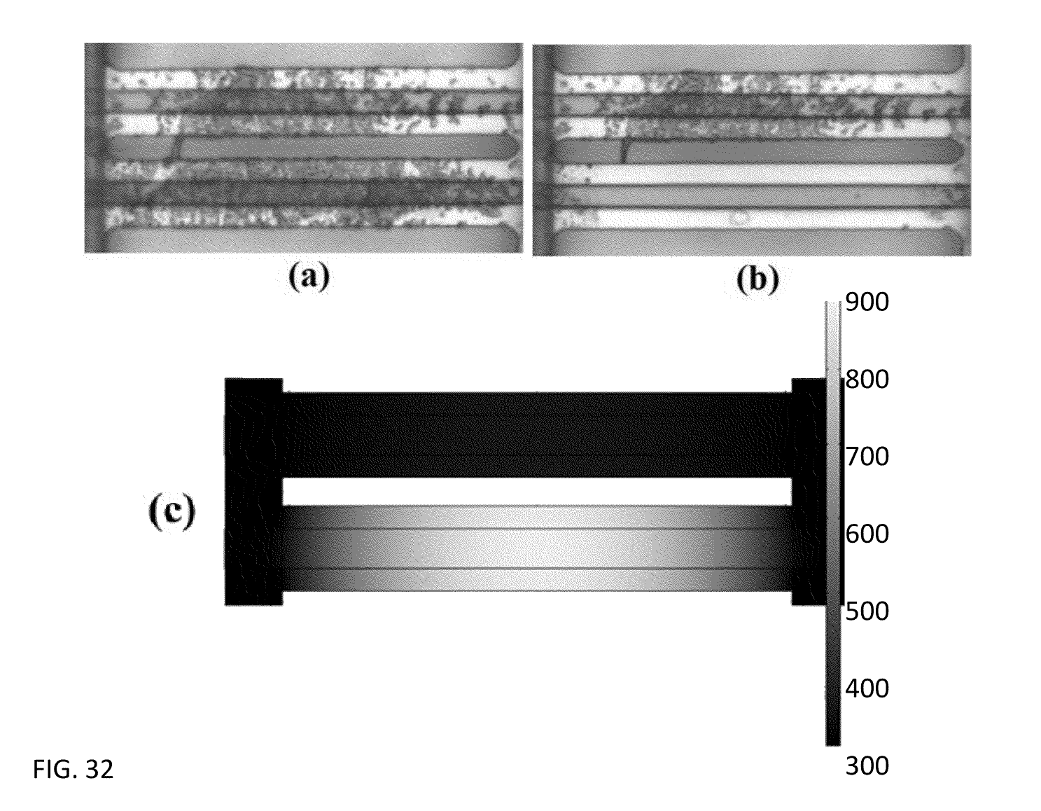

FIGS. 32a-d show some example results. In this example, the sensor 110 may include two mechanically independent microstructures 111 to which a signal may be applied to electrokinetically drive particles to the microstructures 111. FIG. 32a shows the example microstructures 111 with E. coli adsorbed onto the surface, with much of the collection surface area occupied by the E. coli. In FIG. 32b, one of the two microstructures 111 has been heated (e.g., electro-thermally heated) to a suitably high temperature (e.g., to about 900K or higher, as shown in FIG. 32c) in air for a time duration (e.g., about one second) sufficient to thermally ablate the adsorbed E. coli and eliminate some, most or all of the E. coli particles adsorbed on the surface of the microstructure 111. The thermal ablation may cause temperatures sufficient to eliminate the adsorbed particles with little or no damage to the sensor 110 itself. Heating temperatures higher than about 900K may be suitable, and may be adjusted in order to reduce or avoid damage or change in behavior of the sensor 110. Although only one microstructure 111 is shown to be thermally ablated, both microstructures 111 may be similarly thermally ablated.

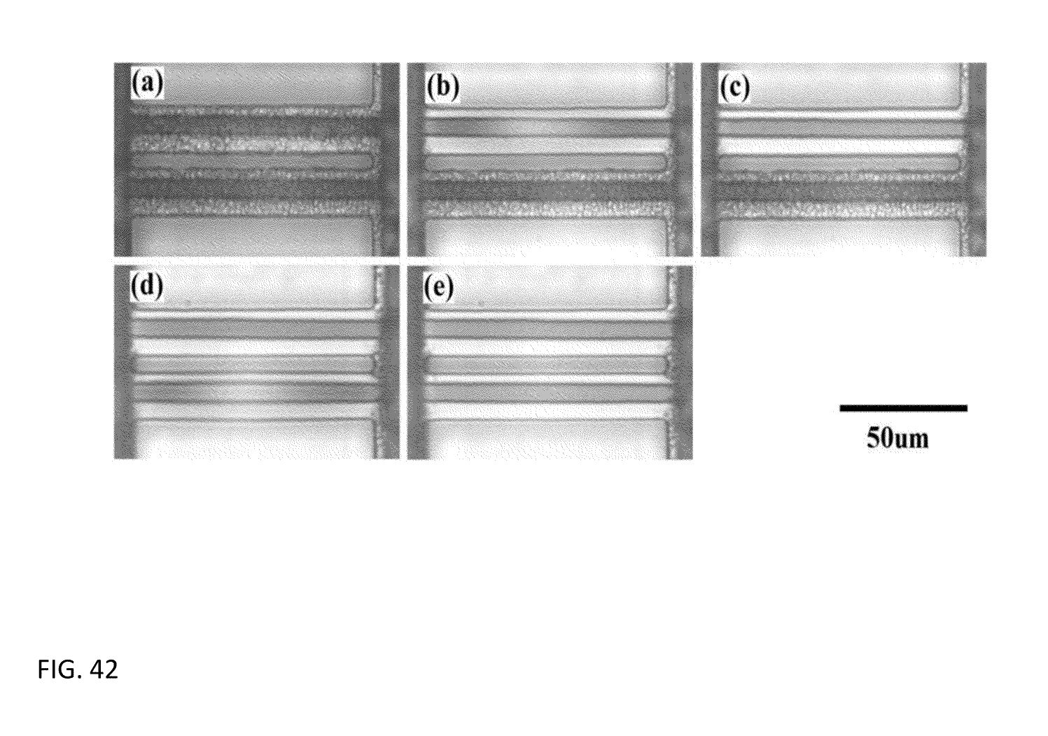

FIGS. 42a-42e are time-lapse images of thermal ablation of another example microstructure 111 similar to the microstructure 111 of FIGS. 32a and 32b. FIGS. 42a-42e illustrate the elimination of particles adsorbed on the surface of the microstructure 111 by thermal ablation.

In some examples, such thermal ablation may damage or eliminate some or all of the functionalized surface and the functionalized surface may be regenerated on the sensor 110 before reuse. In some examples, thermal ablation may serve to eliminate the functionalized surface and may thus allow the sensor 110 to be re-functionalized with a different functional coating, to sense different target materials.

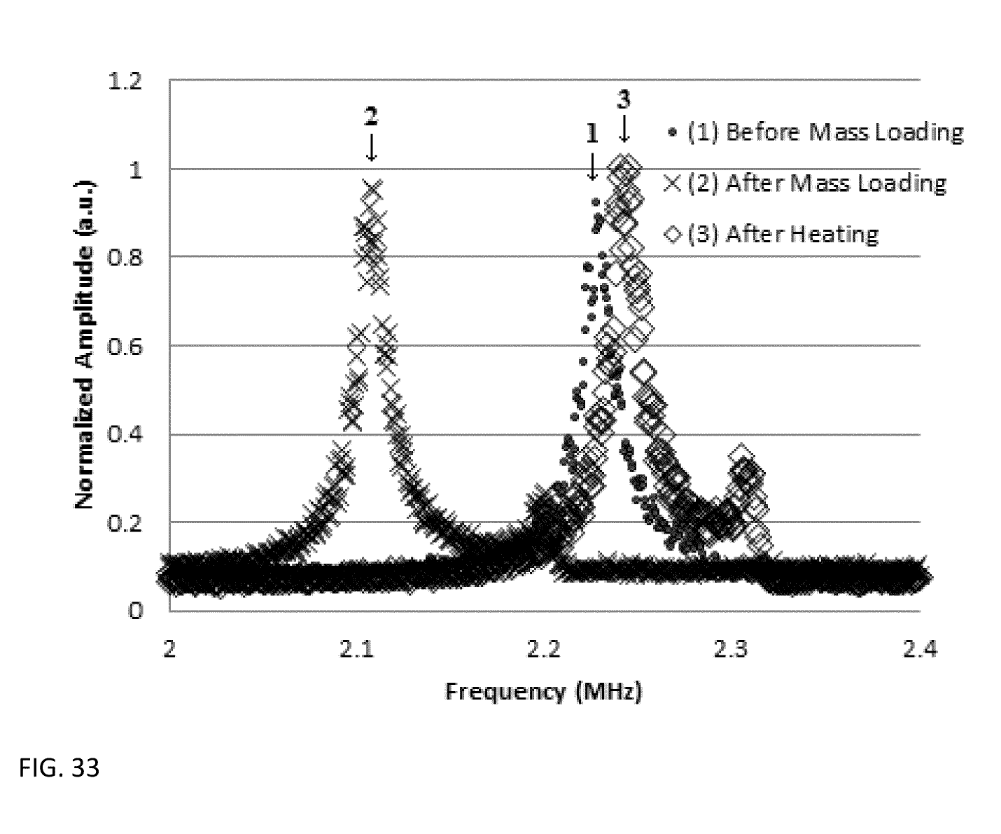

FIG. 33 shows an example of the frequency response of the thermally ablated sensor 110 before particle collection, after particle collection (that is, with material-loading on the sensor 110), and after thermal ablation. The results indicate that the resonant response after ablation has returned to near its original material-free frequency.

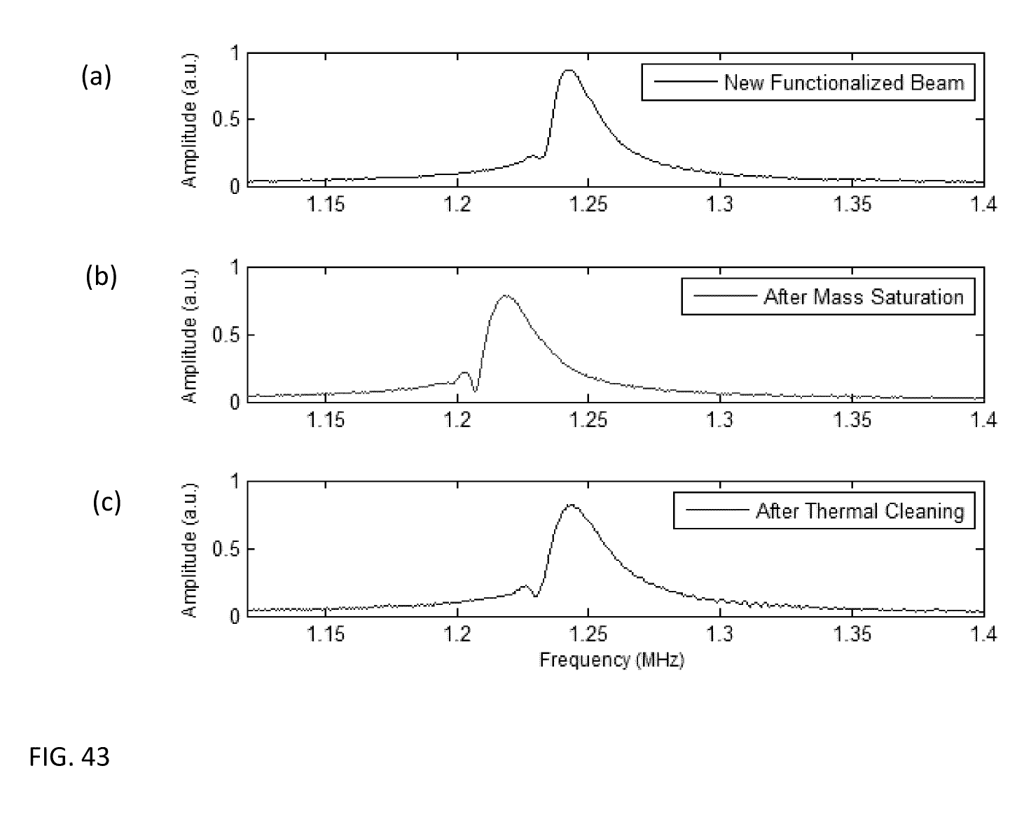

FIGS. 43a-43c show another series of graphs illustrating the frequency response of the sensor 110 before particle collection (FIG. 43a), when fully saturated by adsorbed particles (FIG. 43b), and after thermal ablation to eliminate the adsorbed particles (FIG. 43c). These results indicate that the resonant response of the sensor 110 is recovered after thermal ablation.

Other methods and techniques for removing or eliminating adsorbed materials from a surface may be suitable including, for example, washing the sensor 110 with suitable chemical compounds that break or weaken the bond between the adsorbed material and the functionalized surface. For example, in certain types of specific binding, washing by a solution having relatively high ionic strength (e.g., magnesium chloride at a concentration of about 0.5 M or less, hydrochloric acid at a concentration of about 1 M or less, or sodium chloride at a concentration of about 1 M less) may be suitable to dissociate the target material from the functionalized surface, such that the functionalized surface may be freed up to bind to materials again. Where the target material is coupled to the sensor 110 with non-specific binding, washing by other liquids may be sufficient to remove the target material from the functionalized surface.

### Introduction of Gas Bubble

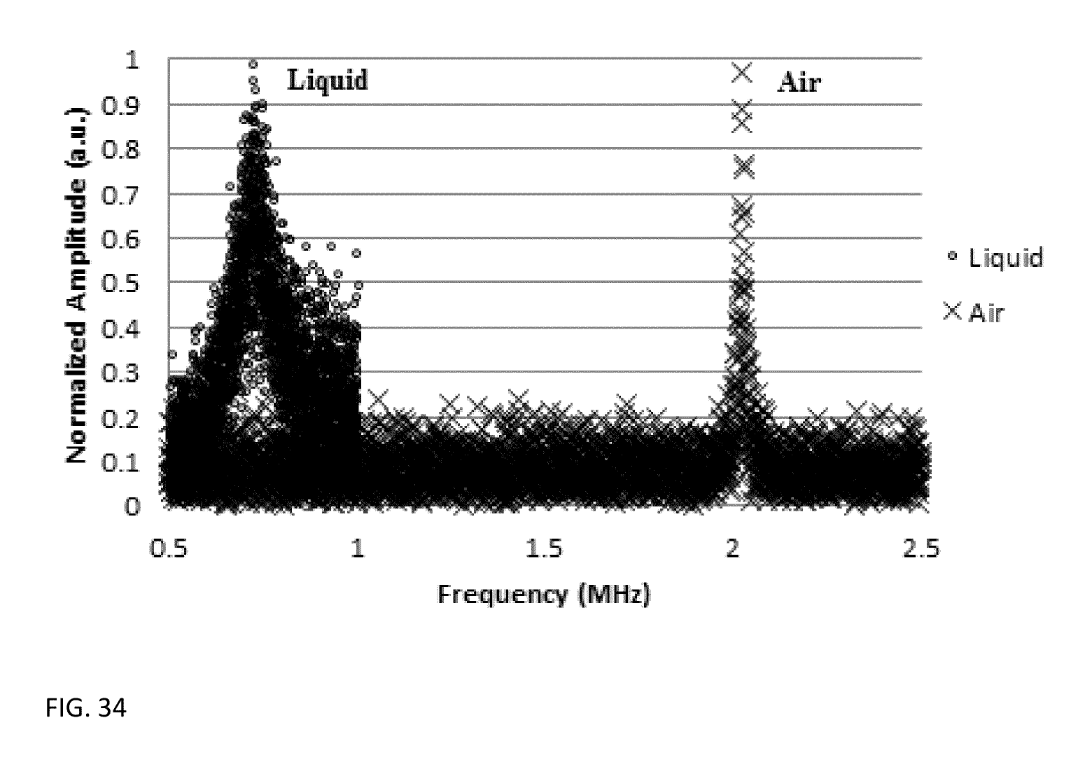

Microresonators, such as the disclosed sensor 110, excited in liquids may exhibit (i) lower mass responsivity which may be due to reduced resonant frequency owing to the added mass effect; and/or (ii) lower Q-factor which may lead to lower amplitude response. FIG. 34 shows an example comparison between the normalized frequency response of an example sensor 110 in liquid and in air. As shown in FIG. 34, in air the example sensor 110 exhibits a response with a higher Q-factor than in liquid (indicated by the peak broadening observed in the results in liquid). The resonant frequency is also observed to decrease in liquid, which may be due to the inertial mass effect. Such effects may reduce the performance of the sensor 110.

The introduction of a gas (e.g., air) bubble may address one or more of these performance challenges. A gas bubble may be introduced to quickly and temporarily engulf some or all of the sensor 110 to assist during the mechanical characterization step, for example, in order to allow a momentary higher responsivity environment for higher sensitivity detection. Suitable methods of introducing a gas bubble to the sensor 110 in a microchannel 150 may include direct injection and using a two-phase micromixer, for example, to generate plug flows upstream of the sensor 110. Other methods may be suitable. The sensor 110 may be washed (or mechanically shaken) prior to introduction of the gas bubble, in order to remove non-target material from the sensor 110, for example.

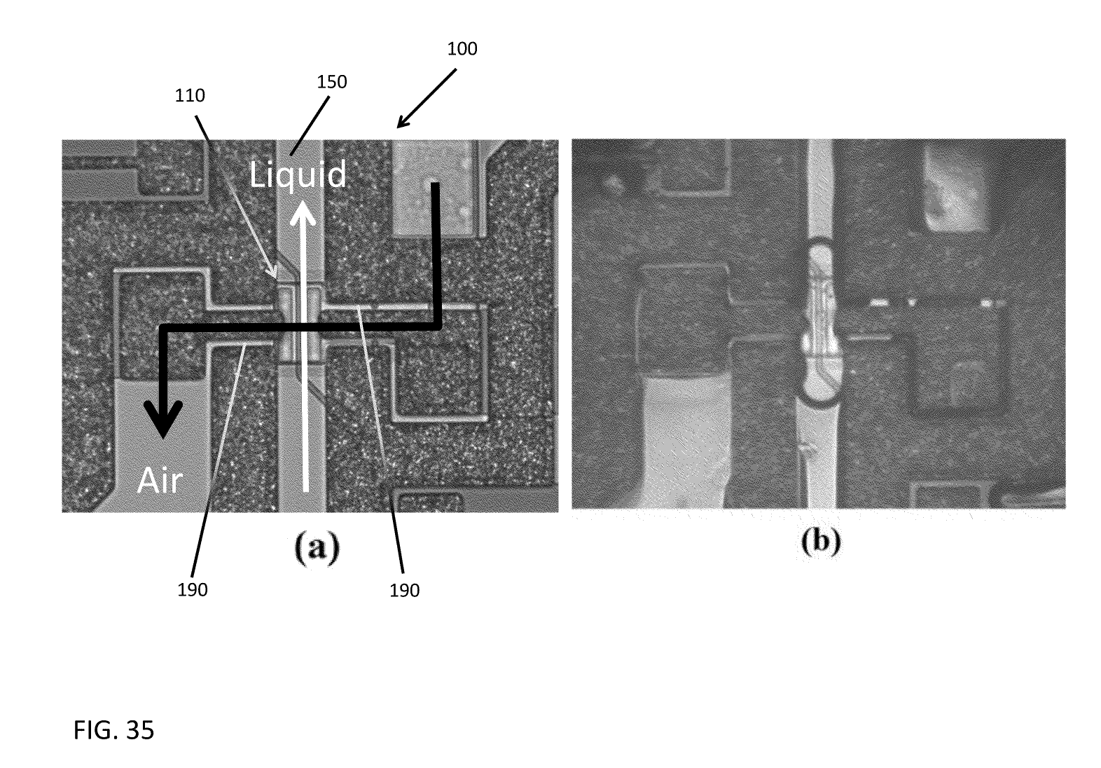

FIGS. 35a-b show an example of directly injecting a gas (in this example, air) bubble to surround the sensor 110. In this example, the device 100 may include a gas channel 190 designed to support the introduction of gas bubbles (e.g., via injection nozzles near the sensor 110). Such nozzles may be independent of the microchannel(s) 150. While the liquid flow is arrested, a gas bubble may be injected (e.g., intermittently, periodically and/or upon demand) locally into the fluid microchannel 150 to at least partially engulf the sensor 110. The gas bubble may engulf at least a portion of the sensor 110 (e.g., at least the portion where target material is expected to be present). This may enable mechanical characterization of the sensor 110 to be completed in a gaseous environment. The liquid flow can then be resumed upon collapsing of the gas bubble through air handling microchannels 190.

FIG. 35a illustrates the example device 100 including a liquid flow microchannel 150 and a gas flow channel 190 intersecting the liquid flow microchannel 150 in the vicinity of the sensor 110. FIG. 35b shows the example device 100 after a gas bubble has been directly injected to engulf the sensor 110.

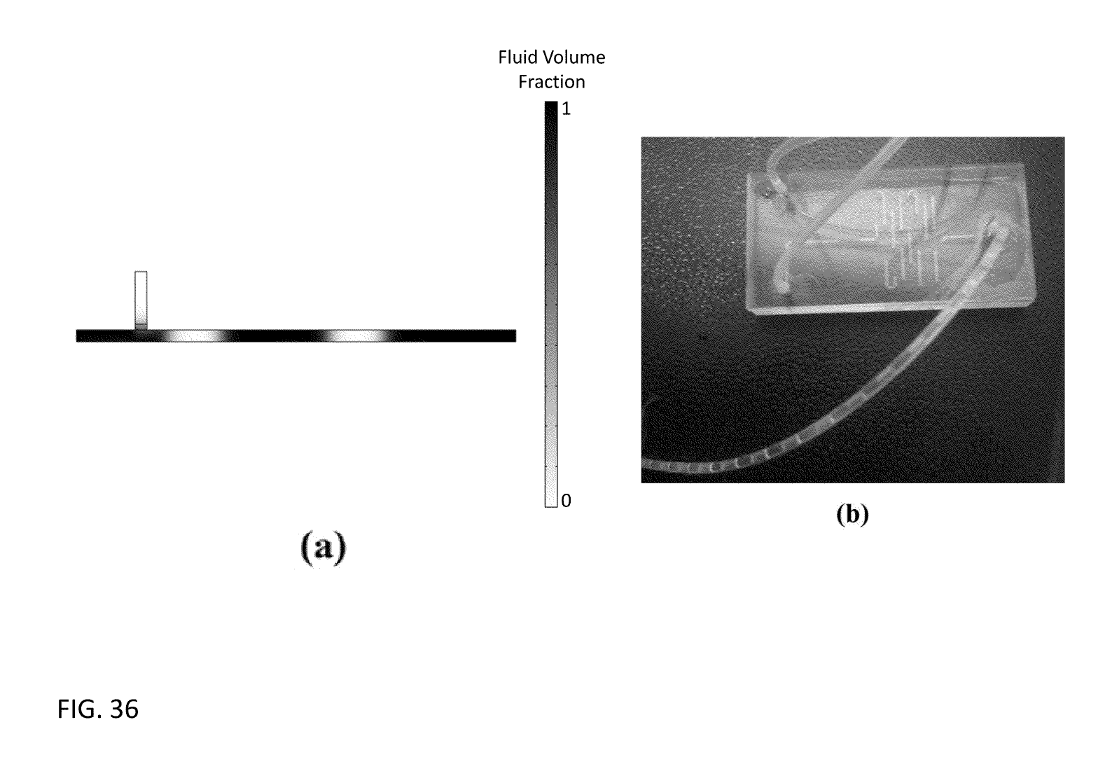

FIGS. 36a-b show an example of using a liquid/gas (e.g., air) micromixer to generate plug flows that may intermittently or periodically alternate between introduction of a gas bubble and liquid sample (with material to be analyzed). FIG. 36a shows an example simulation of the two-phase liquid/gas micromixing, in this example using a T-junction to generate plug flows for intermittently or periodically delivering gas bubbles to the device 100. FIG. 36b shows an image of an example liquid/gas mixer with the outlet port tubing (shown on the right and bottom of FIG. 36b) showing discrete segregated gas bubbles and liquid plugs that alternate between one another. It was found that the sensor 110 achieved a higher Q-factor and a higher resonant frequency inside the gas bubble than in-situ in liquid. For example, FIG. 34 shows a lowering of the frequency in the liquid as well as a Q-factor reduction in liquid, as evidenced by broadening of the peak.

The gas bubbles created upstream (in this example by a liquid-air micromixer) may be introduced into the microchannel(s) 150 of the device 100 without requiring air handling microchannels 190 for subsequent removal of the gas bubble. This may also be implemented in situations where only liquid microchannels 150 exist or where other design considerations limit incorporation of air channels 190.

Using a micromixer, the introduction of a gas bubble may be implemented in an automated manner, which may reduce impact on the temporal resolution of the device 100. For example, the detector 200 may be programmed to coordinate detection with periods where the sensor 110 is fully or partially engulfed in a gas bubble (in addition to or in place of detection when then sensor 110 is in a liquid environment).

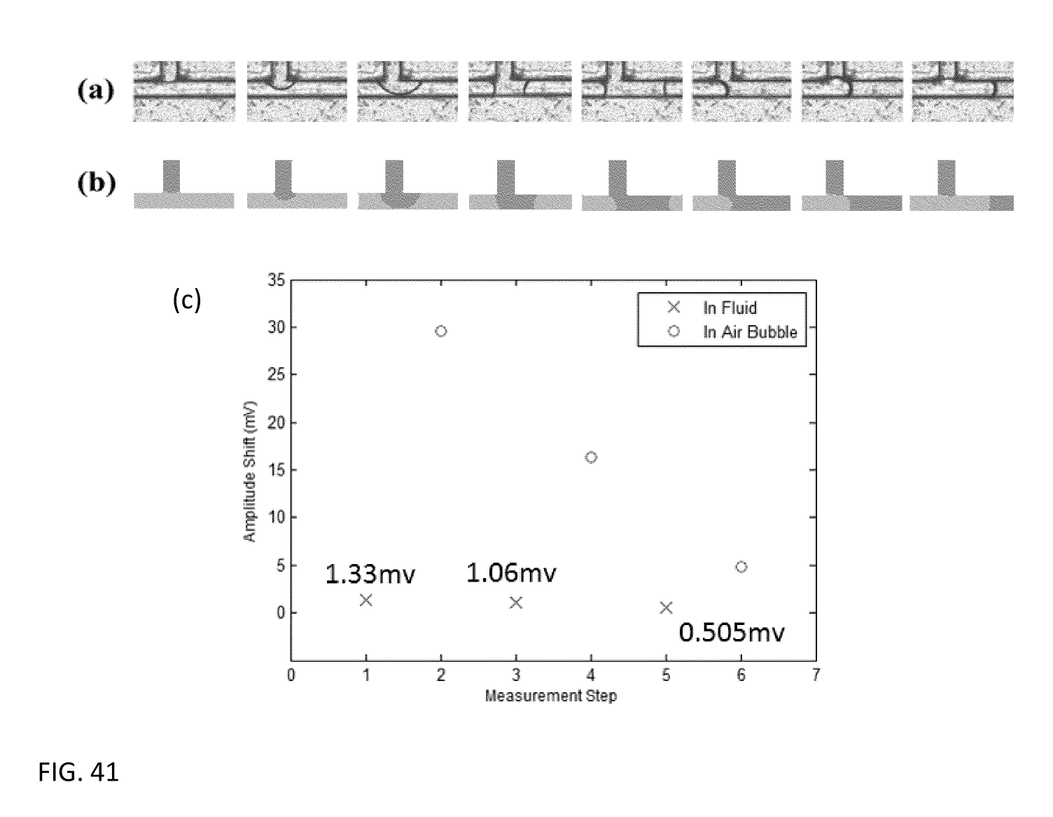

FIGS. 41a and 41b show images and schematic diagrams illustrating another example of a T-junction micro-mixer, illustrating plug flows of liquid and gas at the T-junction.

FIG. 41c shows example experimental data illustrating detection signals from the sensor 110 downstream of the T-junction micro-mixer. In this example, plug flows of E. coli solution at 10⁵ particles/mL and air were generated by an upstream T-junction micro-mixer (e.g., as shown in FIGS. 41a and 41b). The liquid and air plugs were passed to downstream sensor 110 along a microchannel 150 at 1 mL/hr. The sensor 110 was excited using a square wave signal at a fundamental frequency of about 0.52 MHz. This square wave signal was selected to enable the fundamental resonance response of the sensor 110 to be excited in both liquid and air using the first and third harmonic component of the fixed frequency square wave, respectively. Detection signals based on the amplitude modulation of the sensor 110 were recorded at each measurement step that alternated between liquid and air bubble states. The graph in FIG. 41c shows the first five measurement steps as the liquid plug first approached the sensor 110. These example results indicated increasing E. coli detection response in both air bubble and in liquid environments as more liquid plugs of E. coli solution were passed along the sensor. The air bubble measurement state was found to provide a more enhanced detection response than the liquid state.

### Confined Volumes and Microchannels

Electrokinetic effects and their influence on material mass transport may have a distance dependency. By confining the volume of the sample environment (e.g., by limiting the size of the chamber 120), it may be possible to ensure material within the control volume are more efficiently driven by the generated electrokinetic effects and collected at the sensor 110.

As well, by incorporating mass flow of fluid into and out of this control volume (e.g., through implementation of inlet 130, outlet 140 and microchannel(s) 150), the fluid flow rate may be controlled in order to enhance material collection efficiency while reducing measurement time. For example, bulk advection provided by an external micofluidic flow may help to deliver material to the sensor 110. This may provide performance enhancement even compared to an electrokinetics-assisted sensor 110 under a static closed system scenario.

### Other Variations

In some examples, the disclosed device 100 may be a standalone device 100 (e.g., in the form of a MEMS chip), which may offer the same or higher sensitivity than conventional particle detection devices, and which may be designed with target bacteria specificity.

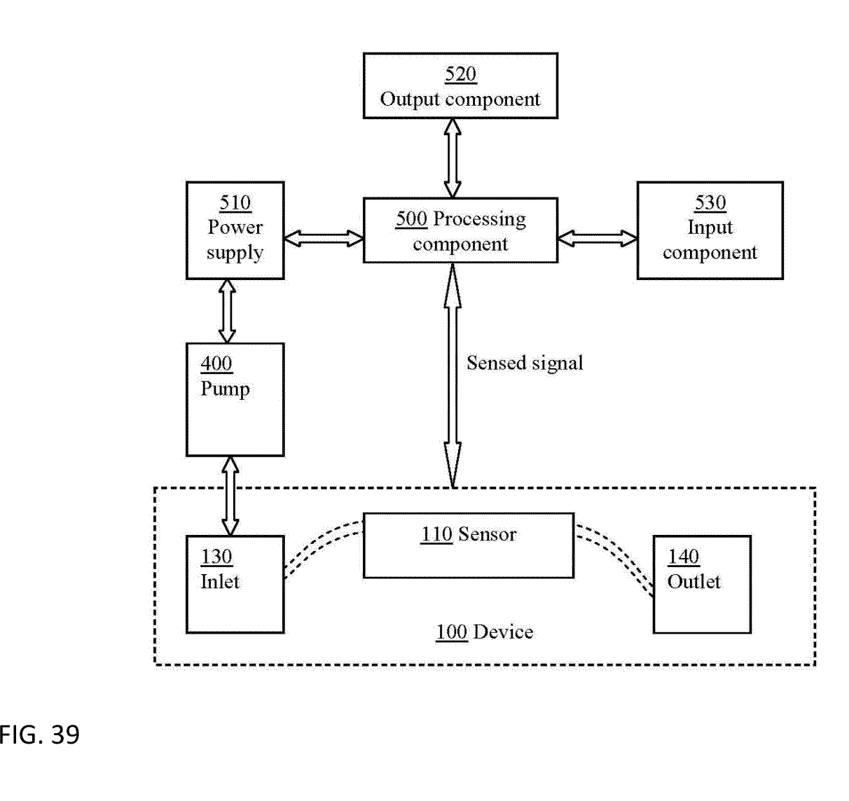

In some examples, as shown in FIG. 39, the disclosed device 100 may be integrated into a system 1000 (e.g., a miniature or portable package) with one or more signal processing components 500 (e.g., one or more processors, microprocessors or logic circuits). The processing component 500 may be coupled to: i) a power supply 510 (e.g., a battery or an external power supply), ii) one or more output components 520 (e.g., one or more screens or indicators) that output data (e.g., the detected signal) and/or iii) one or more user input components 530 (e.g., one or more keyboards, mouse or touch screens). Software applications executable by the processing component 500 may provide one or more user interfaces (e.g., one or more software graphical user interfaces (GUIs) implementable by a processor) that may be provided via the output component(s) 520 and that may be interacted with by the user via the input component(s) 530. In some examples, such a system 1000 may be provided as a commercial package for the general market. In some examples, the system 1000 may not include the output component(s) 520, the power supply 510 and/or the input component(s) 530, but may be adapted to couple to another system providing such functionality. In some examples, the software application providing the user interface(s) may be provided together with or separately from the system 1000.

In some examples, the disclosed device 100 may be integrated into conventional detection instruments (e.g., for detection of pathogens). For instance, coupling of an example of the disclosed device 100 with ENDETEC's TECTA™ system may provide a culture enrichment step for single-cell detection. Such an integrated system may be an additional or upgrade product for ENDETEC, for example where the disclosed device 100 may be used to detect bacteria growing in the culture faster than the conventional ENDETEC test (typically one cell in about 12-13 hr). Such a combination of technologies may also provide richer information than the individual test, for example where the disclosed device 100 includes an array of sensors 110 in the form of MEMS biosensors functionalized with various antibodies.

In some examples, the disclosed device 100 may be provided with one or more peripheral components including, for example: packaging slides, measurement laser and photodetector, and a suitable data acquisition system, among other possibilities.

In some examples, the functionalized surface may be removed from the sensor 110. For example, a suitable method for removal of a poly-L-lysine functionalized surface is now described. Microelectrodes 112 functionalized with poly-L-lysine (with or without adsorbed material) may be cleaned by submerging the microelectrodes 112 in a solution containing about 0.1 mM trypsin with about 0.6 mM ethylenediaminetetraacetic acid (EDTA) for a period of about 2 hours. Subsequent washing with PBS and filtered water may remove any remaining residue. The sensor 110 may then be functionalized with the same or different functional component, or left without a functionalized surface.

In some examples, after collection of material on the sensor 110, a complementary compound (e.g., a complementary antibody) may be coupled to the collected material, for labeling purposes or other purposes. In an example, after material has been collected on the surface of the microelectrodes 112, the microelectrodes 112 were washed with PBS for about 5 min and then placed in a sealed environment which had been saturated with water vapor. An about 50 μL droplet of an about 1 mg/mL biotin solution was placed on the microelectrode 112 and allowed to react for about 30 min followed by two more approximately 5 min washed in PBS. About 50 μL of a biotynylated antibody (approximately 200 μg/mL) complementary to the target material was allowed to react for about two hours. The free biotin on the antibody may be reacted with labels to provide further identification for the presence of the target material.

In some examples, in addition to or in place of sensing the presence of the target material(s), the sensor 110 may enable absolute or relative quantifying of the target material(s) in the sample. For example, the sensor 110 may be characterized and/or calibrated such that a measured response from the sensor 110 (e.g., a measured amount of quasi-static change, such as a measured amount of deflection, or dynamic change, such as a measured amount of frequency, phase and/or amplitude shift in resonance) may be correlated to a known amount (e.g., a known mass) of the target material(s), which may provide direct or indirect information about the amount of target material(s) within the sample.

In some examples, the sensor 110 may be designed to exhibit a detectable response (e.g., a detectable quasi-static or dynamic response) only after a threshold amount of target material(s) has been collected on and/or in the sensor 110. Thus, the sensor 110 may provide information that there is at least a certain amount of target material(s) within the sample.

### Applications

In various example aspects and embodiments, the present disclosure may be suitable for one or more of the following applications.

In some examples, the disclosed systems 1000, devices 100 and sensors 110 may be suitable for detection of biological material. For example, the disclosed sensor 110 may be functionalized with various antibodies and/or other bio-recognition coatings, for detection of different target biomaterials.

In some examples, the disclosed systems 1000, devices 100 and sensors 110 may provide relatively rapid and specific detection of contaminants, such as bacteria, and may be useful in the drinking or recreational water (e.g., for monitoring of lake water and/or well water for the presence of E. coli), food and beverage markets. The disclosed systems 1000, devices 100 and sensors 110 may also be useful in other environmental microbiological monitoring applications, such as in industrial systems. The disclosed systems 1000, devices 100 and sensors 110 may also be useful for diagnostic testing, and other biosensor applications, including pathogen detection in food and agriculture, healthcare and bio-defense, for example.

In some examples, the disclosed sensor 110 may be functionalized with selected antibody(ies) targeting certain target biomaterials (e.g., specific bacteria). Antibodies may be suitable for functionalizing the disclosed sensor 110 since antibodies may be relatively well-understood and studied for the detection and identification of biological species, and suitable antibodies may be commercially available.

In some examples, the disclosed systems 1000, devices 100 and sensors 110 may be implemented as a home-based detection device. Since the disclosed sensor 110 may be relatively quick and inexpensive to manufacture, compared to conventional biosensors, examples of the disclosed systems 1000, devices 100 and sensors 110 may enable home-based monitoring of pathogens, for example for monitoring of water quality, food safety (e.g., for deli meats) among other home-based monitoring possibilities. Use of the disclosed systems 1000, devices 100 and sensors 110 in the home, with relatively quick, specific and reliable results, may also lead to greater consumer confidence and may provide public, environmental monitoring technicians and healthcare professionals with a larger dataset directly from consumers.

In some examples, the disclosed devices 100 and sensors 110 may be relatively quick and cost-effective to mass manufacture, which may enable the device 100 and/or sensor 110 to be disposable. Disposability may enable greater ease of use (e.g., in a home environment) by untrained personnel, and may also avoid or reduce the possibility of contamination.

Although the present disclosure discusses examples where the sample fluid is a liquid, in some examples the disclosed systems 1000, devices 100 and sensors 110 may also be used for sensing of materials in a gaseous sample, such as for monitoring of airborne particles (e.g., for detection of pollution, airborne pathogens and/or chemicals). Such an application may be useful in critical environments, such as where air quality, or the presence of airborne pathogens or contaminants may be a concern (e.g., in hospitals, cleanrooms, airports, combat zone and industrial plants, among others). The ability to sense a target material in a gaseous sample (and possibly in addition to sensing in a liquid or vapor sample) may be useful for safety, security and/or national security applications, among others.

### Possible Advantages

In various example aspects and embodiments, the present disclosure may provide one or more advantages over conventional methods and systems.

In some examples, the disclosed sensors 110 may include a functionalized surface, which may be functionalized to retain the target material(s). For example, where the target material(s) is (are) a biological material, the functionalized surface may be functionalized with a commercially available antibody, which may provide selectivity and/or enhanced sensitivity [67]. Such a sensor 110 may serve as a label-free (that is, labeling of the target material(s) may not be necessary) biosensor.

In some examples, collection of material may be tuned (e.g., through control of the electrokinetic effects, as described above) to concentrate the target material(s) in the vicinity of the functionalized surface (e.g., an antibody-coated microelectrode 112). Such a sensor 110 may provide relatively low detection limits and/or relatively accelerated detection of the target material(s) (e.g., a target bacteria) without requiring labeling step. For example, the sensor 110 described in example study 1 above may have a detection limit of about 1000 cells/mL within about one hour, resulting from enhancements from increased mass sensitivity, improved electrokinetic-assisted collection, and/or antibody binding.

In some examples, operation of the disclosed systems 1000, devices 100 and sensors 110 may be combined with a culture amplification step to further improve selectivity and/or detection limits.

In some examples, the device 100 and/or sensor 110 may be fabricated with relatively low cost and/or may be suitable for mass production. For example, the disclosed device 100 may be fabricated using commercially available technologies, such as technologies provided by Micralyne and MEMSCAP, among others, for reasonably low cost.

In some examples, the sensor 110 may provide improved sensitivity, for example by reducing sensor size (which may increase intrinsic responsivity) and/or through use of strategic excitation for higher modes.

In some examples, the sensor 110 may enable enhancement of detection efficiency, for example by various configurations of the layout of the microelectrodes 112 or other electric field-generating feature (which may increase or maximize the amount of captured target material(s) per unit surface area of sensor 110).

In some examples, the sensor 110 may enable collection of material by causing both nDEP and pDEP conditions on the same sensor 110. For example, the sensor 110 may include two or more microelectrodes 112 on the same unitary microstructure 111 (e.g., on the same beam), which may be a more complex design and which may enable finer control over collection of material (e.g., control over the region(s) of the microstructure 111 where material is collected, better targeting of the target material(s), and/or ability to sort material based on the material's characteristics).

In some examples, the sensor 110 may be designed to exploit the nodes of its resonant response. In some situations, it may be useful to design the sensor 110 in order to intentionally collect material at or near resonant nodes of the microstructure 111. For example, the nodes may be used to help de-couple frequency shift response of different higher-order resonant modes, which may be used to differentiate different types of material collected on the same sensor 110. The nodes may be used to help gauge precision of the sensor 110 (e.g., using the null-sensitivity criterion). Consider the example of example sensor design 9 (FIGS. 25a-c), for example. As shown, material is collected primarily near the center of the microstructure 111. This region is at the antinode of the first resonant mode (as shown in FIG. 25c). For even-ordered higher-order resonant modes, this region coincides with a resonant node. By measuring for frequency shift of the even-ordered modes, it may be possible to determine how disperse the collected material are from the designed collection region (that is, at or near the center of the microstructure 111). Low dispersion would result in little or no resonant frequency shift for the even-ordered modes, while high dispersion would result in greater resonant frequency shift for the even-ordered modes.

In some examples, the selectivity of the sensor 110 may be further improved, for example by implementing a surface functionalization that may be tailored to the targeted material (e.g., a target pathogen).

In some examples, the sensor 110 and device 100 may serve as part of a relatively compact flow-through system 1000 that may enable automated testing. Such a system 1000 may be suitable for sale on a commercial market.

In some examples, the disclosed systems 1000, devices 100 and sensors 110 may provide reduced detection times compared to conventional systems, devices and sensors, including bacteria sensors. Conventional bacteria sensors typically rely on a passive transport of the bacteria to the detection surface, a process that may take hours or more. The disclosed systems 1000, devices 100 and sensors 110 may employ electrokinetic forces to drive the bacteria towards the sensor 110, which may accelerate their capture and/or detection.

In some examples, the disclosed systems 1000, devices 100 and sensors 110 may provide more selectivity for the target material(s) than conventional systems, devices and sensors, including bacteria sensors. In conventional bacteria sensors, bacteria identification usually requires a subsequent step (e.g., labeling) that is typically performed in a well-equipped laboratory. The disclosed systems 1000, devices 100 and sensors 110 may enable detection and identification of bacteria at or about the same time, for example through integrating standard antibodies onto the sensor 110.

In some examples, the disclosed systems 1000, devices 100 and sensors 110 may provide label-free detection of the target material(s). By using mass-based detection, post-processing (e.g., use of additional chemical reagents) may not be necessary for signal transduction. That is, compared to conventional immunoassays, the disclosed systems 1000, devices 100 and sensors 110, when used for bacteria detection, may not require a labeling step. This may provide a substantially real-time or near real-time (e.g., on the order of seconds to minutes) process and/or reduced operating costs.

In some examples, the disclosed systems 1000, devices 100 and sensors 110 may allow for relatively rapid and specific identification of pathogenic bacteria in an outbreak, which may save lives. For instance, a food-borne E. coli outbreak in Europe was found to have caused 18 deaths and infected thousands. Conventional tests to identify specific E. coli strains during outbreaks like this typically require culturing and characterizing the suspect bacteria in a laboratory, which may take several days. Conventional tests to characterize a completely new strain of bacteria may add another day or two, and those tests are typically done in specialized labs. The disclosed systems 1000, devices 100 and sensors 110 may instead provide a biosensor that may enable relatively rapid and specific detection and identification of pathogenic bacteria, which may be useful for protecting public health.

The embodiments of the present disclosure described above are intended to be examples only. Alterations, modifications and variations to the disclosure may be made without departing from the intended scope of the present disclosure. In particular, selected features from one or more of the above-described embodiments may be combined to create alternative embodiments not explicitly described. All values and sub-ranges within disclosed ranges are also disclosed. The subject matter described herein intends to cover and embrace all suitable changes in technology. All references mentioned are hereby incorporated by reference in their entirety.

### REFERENCES

[1] D. Bhatta, E. Stadden, E. Hashem, I. J. G. Sparrow, G. D. Emmerson, Multi-purpose optical biosensors for real-time detection of bacteria, viruses and toxins, Sens. Actuators B. 149 (2010) 233-238
[2] J. M. Brake, M. K. Daschner, Y-Y. Luk, N. L. Abbott, Biomolecular interactions at phospholipid-decorated surfaces of thermotropic liquid crystals, Science 302 (2003) 2094-2097
[3] O. Hayden, R. Bindeus, C. Haderspöck, K-J. Mann, B. Wirl, F. L. Dickert, Mass-sensitive detection of cells, viruses and enzymes with artificial receptors, Sens. Actuators, B 91 (2003) 316-319
[4] K. H. Bhatt, S. Grego, O. D. Velev, An AC electrokinetic technique for collection and concentration of particles and cells on patterned electrodes, Langmuir 21 (2005), 6603-6612
[5] Z. Gagnon, H-C. Chang, Aligning fast alternating current electroosmotic flow fields and characteristic frequencies with dielectrophoretic traps to achieve rapid bacteria detection, Electrophoresis 19 (2005) 3725-37
[6] M. P. Hughes, H. Morgan, F. J. Rixon, J. P. H. Burt, R. Pethig, Manipulation of herpes simplex virus type 1 by dielectrophoresis, Biochim. Biophys. Acta. 1425 (1998) 119-126
[7] P. K. Wong, C-Y. Chen, T-H. Wang, C-M. Ho, Electrokinetic bioprocessor for concentrating cells and molecules, Anal. Chem. 10 (2004) 574-579
[8] A. Docoslis, L. A. Tecero-Espinoza, B. Zhang, L-L. Cheng, B. A. Israel, P. Alexandridis, Using nonuniform electric fields to accelerate the transport of viruses to surfaces from media of physiological ionic strength, Langmuir 23 (2007) 3840-3848
[9] K. F. Hoettges, M. P. Hughes, A. Cotton, N. A. E. Hopkins, M. B. McDonnell, Optimizing particle collection for enhanced surface based biosensors, IEEE Eng. Med. Biol. Mag. 22 (2003) 68-74
[10] S. M. Radke, S. Member, E. C. Alocilja, A microfabricated biosensor for detecting foodborne bioterrorism agents, IEEE Sens. J. 5 (2005) 744-750
[11] J. Wu, Y. Ben, D. Battigelli, H-C. Chang, Long-range AC electroosmotic trapping and detection of bioparticles, Ind. Eng. Chem. Res. 44 (2005) 2815-2822
[12] Y. Huang, R. Pethig, Electrode design for negative dielectrophoresis, Meas. Sci. Technol. 2 (1991) 1142-1146
[13] M. P. Hughes, Nanoelectromechanics in Engineering and Biology, CRC Press (2003)
[14] A. Menachery, R. Pethig, Controlling cell destruction using dielectrophoretic forces, IEEE Proc. Nanobiotechnol. 152(2005) 145-149
[15] H. Morgan, N. G. Green, AC electrokinetics: colloids and nanoparticles, Research Studies Press Ltd (2003)
[16] M. Alvarez, L. M. Lechuga, Microcantilever-based platforms as biosensing tools, Analyst 135 (2010) 827-836
[17] B. Ilic, D. Czaplewski, H. G. Craighead, P. Neuzil, C. Campagnolo, C. Batt, Mechanical resonant immunospecific biological detector, Appl. Phys. Lett. 77 (2000) 450-452
[18] A. Gupta, D. Akin, R. Bashir, Single virus particle mass detection using microresonators with nanoscale thickness, Appl. Phys. Lett. 84 (2004) 1976
[19] K. Park, J. Jang, D. Irimia, J. Sturgis, J. Lee, J. P. Robinson, ‘Living cantilever arrays’ for characterization of mass of single live cells in fluids, Lab Chip 8 (2008) 1034-41
[20] H. S. Wasisto, S. Merzsch, A. Stranz, A. Waag, I. Kirsch E. Uhde T. Salthammer, E. Peiner, A Resonant Cantilever Sensor For Monitoring Airborne Nanoparticles, Solid-State Sensors, Actuators and Microsystems Conference (TRANSDUCERS), 16th International (2011) 1116-1119
[21] N. Islam, M. Lian, J. Wu, Enhancing microcantilever capability with integrated AC electroosmotic trapping, Microfluidics and Nanofluidics 3 (2007) 369-375
[22] S. Arefin, T. L. Porter, An Ac Electroosmosis Device For The Detection Of Bioparticles With Piezoresistive Microcantilever Sensors, J. Appl. Phys. 111 (2012) 054918-054926
[23] S. H. Tsang, D. Sameoto, M. Parameswaran, Out-of-plane electrothermal actuators in silicon-on-insulator technology, Canadian Journal of Electrical and Computer Engineering 31 (2006) 97-103
[24] T. P. Burg, M. Godin, S. M. Knudsen, W. Shen, G. Carlson, J. S. Foster, Weighing of biomolecules, single cells and single nanoparticles in fluid, Nature 446 (2007) 1066-1069
[25] M. M. C. Cheng, G. Cuda, Y. L. Bunimovich, M. Gaspari, J. R. Heath, H. D. Hill, C. A. Mirkin, A. J. Nijdam, R. Terracciano, T. Thundat, and M. Ferrari, Nanotechnologies for biomolecular detection and medical diagnostics, Current Opinion in Chemical Biology 2006, 10:11-19.
[26] H. Sone, Y. Fujinuma, T. Hiejda, T. Chiyoma, H. Okano, and S. Hosaka, Picogram mass sensor using microcantilever, SICE Annual Conference, Sapporo, Japan, August, 2004, 1508-1513.
[27] B. E. DeMartini, J. F. Rhoads, S. W. Shaw, and K. L. Tuner, A single input-single output sensor based on a coupled array of microresonantors, Sensors and Actuators A 2007, 137:147-156.
[28] J. Chow and Y. Lai, Mass Measurement with Micromechanical Single Harmonic Oscillators, IEEE 2^{nd} Microsystem and Nanoelectronics Research Conference, Ottawa, 2009.
[29] J. Verd, A. Uranga, G. Abada, J. Teva, F. Torres, F. Perez-Murano, J. Fraxedas, J. Esteve, and N. Barniol, Monolithic mass sensor fabricated using a convertional technology with attogram resolution in air conditions, Applied Physics Letters 2007, 91(013501).
[30] Y. T. Yang, C. Callegari, X. L. Feng, K. L. Ekinci, and M. L. Roukes, Zeptogram-scale Nanomechanical Mass Sensing, NANO letters 2006, 6(4).
[31] K. Miller, A. Cowen, G. Hames and B. Hardy, SOI MUMPs Design handbook 2004, MEMScAP.
[32] Y. Lai, Development of 3-DOF micromanipulator, 2004 PhD thesis, Dalhousie Univ., Halifax, NS.
[33] M. R. Tomkins, J. A. Wood, and A. Docoslis, Observation and analysis of electrokinetically driven particle trapping in planar microelectrode arrays, The Canadian Journal of Chemical Engineering 2008, 86, 609-621.
[34] J. A. Wood, B. Zhang, M. R. Tomkins, and A. Docoslis, Numerical investigation of AC electrokinetic virus trapping inside high ionic strength media, Microfluidics and Nanofluidics 2007, 3, 547-560.
[35] K. Xie, Y. Lai, X. Guo, and J. R. Campbell, A three-phased circular electrode array for electro-osmotic microfluidic pumping, Microsystem Technologies, 2011, 17(3), 367-372.
[36] X. Guo. K. Xie, J. R. Campbell and Y. Lai, Discrete 3D T-shaped Electrode Arrays for Moving Liquid by AC Electro-osmosis, MEMS/NEMS and microTAS, International Conference on Materials for Advanced Technologies, ICMAT2011, Singapore, Jun. 24, 2011.
[37] J. Chow and Y. Lai, Exciting higher-order flexural modes of free-standing microstructures with square wave driving signals, Review of Scientific Instruments 2010, 81(6).
[38] R. S. Brown and M. Hussain, The Walkerton tragedy—issues for water quality monitoring, Analyst, 2003, 128, 320-322.
[39] R. S. Brown, E. J.-P. Marcotte, C. E. Dunkinson, W. P. Aston, P. J. Gallant and D. Wilton, An Automated Detection Technology for Onsite E. coli and Coliform Bacteria Monitoring”, WEF Water Environment Laboratory Solutions, 2010, 17, 1-5.
[40] Frost and Sullivan, Biosensors and Medical Diagnostics, Global Industry Analysts, January 2011.
[41] M., Bligh, et al, Two-phase interdigitated microelectrode arrays for electrokinetic transport of microparticles J. Micromech. Microeng. 2008, 18 055007.
[42] M., Bligh. et al, Sorting microparticles into lateral streams using a two-phase rectangular electrokinetic array, J. Micromech. Microeng. 2008, 18 045002.
[43] A., Docoslis, et al, Using Nonuniform Electric Fields To Accelerate the Transport of Viruses to Surfaces from Media of Physiological Ionic Strength, Langmuir 2007, 23 (7):3840-3848.
[44] A, Ramos et al, Pumping of liquids with traveling-wave electroosmosis, J Appl Phys 2005, 97(8), 084906.
[45] S., Gangwal, et al, Induced-Charge Electrophoresis of Metallodielectric Particles, Phys. Rev. Lett. 2008, 100, 058302.
[46] X., Guo, et al, Discrete 3D T-shaped electrode arrays for Microfluidic pumping, 2011 Advanced Materials Research: MEMS/NEMS/microTAS, 254.
[47] X., Guo, et al, A study of ACED flows induced by 3D electrode arrays fabricated from PolyMUMPs” Microelectron Eng, 2011(accepted).
[48] F., Amhad, et al, Detection and occurrence of indicator organism and pathogens, Water Environ. Research, 81(10) 960-980, 2009.
[49] K. A., Gilbride, et al, Molecular techniques in wastewater: Understanding microbial communities, detecting pathogens, and real-time process control. J. Microbial. Methods 66 (2006) 1-20.
[50] T. M., Scott et al, Microbial source tracking: current methodology and future directions. Appl. Environ. Microbiol. 2002, 68(12), 5796-5803.
[51] S. Park et al, Enzyme-linked immuno-strip biosensor to detect Escheriochia coli O157:H7. Ultramicroscopy, 2008, 108(10), 1348-1351.
[52] M. Wagner, et al, Probing activated sludge with oligonucleotides specific for proteobactaeria: inadequacy of culture-dependent methods for describing microbial community structure. Appl. Environ. Microbiol. 1993, 59(5), 1520-1525.
[53] S. Sandhya et al, Molecular beacons: a real-time polymerase chain reaction assay for detecting Escherichia coli from fresh produce and water. Anal. Chim. Acta., 2008, 614(2), 208-212.
[54] E. Majid et al. Boron doped diamond biosensor for detection of Escherichia coli. J. Agric. Food Chem., 2008, 56(17), 7691-7695.
[55] O. Lackzka et al, Detection of Escherichia coli and Salmonella typhimurium using interdigitated microelectrode capactive immunosensors: the importance of transducer geometry. Anal. Chem., 2008, 80(19), 7239-7247.
[56] C. K., Park, et al, Enzyme-linked immuno-strip biosensor to detect Escherichia coli 0157:H7. Ultramicroscopy, 2008, 108(10), 1348-1351.
[57] A., Wolter, et al, Detection of Escherichia coli and Salmonella typhimurium, and Legionella pneumophila in water using a flow-through chemiluminescence microarray readout system. Anal. Chem., 2008, 80(15), 5854-5863.
[58] S., Ram, et al, Rapid culture-independent quantitative detection of enterotoxigenic Escherichia coli in surface waters by real-time PCR with molecular beacon. Environ. Sc. Technol., 2008, 42(12), 4577-4582.
[59] S. M., Miller, et al, In situ synthesized virulence and marker gene biochip for detection of bacterial pathogens in water. Appl. Environ. Microbiol., 2008, 74(7), 2200-2209.
[60] Y., You. et al, A novel DNA microarray for rapid diagnosis of entropathogenic bacterial in stool specimens of patients with diarrhea. J. Microbiol. Methods, 2008 75(3), 566-571.
[61] E., Yacoub-George, et al, Automated 10-channel capillary chip Immunodetector for Biological Agents Detection, Biosens. Bioelectron. 2007, 22, 1368-1375.
[62] M., Zourob, et al, Bacteria Detection Using Disposable Optical Leaky Waveguide Sensor. Biosens. Bioelectron. 2005, 21, 293-302.
[63] D. A., Boehm, et al, On-chip microfluidic biosensor for bacterial detection and identification. Sensors and Actuators B: Chemical 126(2007) 508-514.
[64] B., Byrne, et al, Anti-body Based Sensors: Principles, Problems and potential for Detection of Pathogens and associated Tocins, Sensors, 2009, (9), p. 4407-4445.
[65] J. Chow and Y. Lai, Towards sensitivity enhancement of resonant MEMS mass detectors by high-order mode-selection with mode-optimized mass-loading, Sensors & Actuators: A. Physical. 2011. SNA-D-11-00501 (under review).
[66] M. Tomkins, et al, A coupled cantilever-microelectrode biosensor for enhanced pathogen detection, Sensors & Actuators: B. Chemical. 176:248-252 (publication expected 2013).
[67] de la Rica R et al. Single-cell pathogen detection with a reverse-phase immunoassay on impedimetric transducers. Anal Chem 81:7732-6 (2009).
[68] Park, S., Zhang, Y., Wang, T. and Yang, S. (2011) Continuous dielectrophoretic bacterial separation and concentration from physiological media of high conductivity. Lab on a Chip 11, 2893-3900.
[69] Pohl, H. A., Dielectrophoresis: the behavior of neutral matter in nonuniform electric fields (1978), Cambridge University Press. Cambridge.
[70] Guo, X., Xie, K., Campbell, R. J., and Lai, Y. (2011). A study on three-dimensional electrode arrays fabricated by PolyMUMPs® for AC electro-osmotic pumping Microelectronic Engineering, Vol. 88(10) 2011, pp (3113-3118).
[71] Xie, K., Lai, Y., Guo, X., and Campbell, J R (2010). A Three-Phase Serpentine Micro Electrode Array for AC Electroosmotic Flow Pumping. Microsystem Technologies, Vol. 16(10), pp. (1825-1830).
[72] Li, D. (2004). Electrokinetics in microfluidics, Elsevier.
[73] Green, N. G., and Morgan, H. (1998). Separation of submicrometre particles using a combination of dielectrophoretic and electrohydrodynamic forces. J. Phys. D: Appl. Phys., Vol. 31, pp. (L25-L30).
[74] Pohl, H. A. (1951). The motion and precipitation of suspensoids in divergent electric fields. Journal of Applied Physics, Vol. 22, pp. (869-871).
[75] Humberto, F., Morales, F., Duarte, J. E., and Marti, J. S. (2008). Non-uniform electric field-induced yeast cell electrokinetic behavior. Revista Ingenieria E Investigacion, Vol. 28, pp. (116-121).
[76] Sigurdson, M., Wang, D., and Meinhart, C. D. (2005). Electrothermal stirring for heterogeneous immunoassays. Lab Chip, Vol. 5, pp. (1366-1373).
[77] Castellanos, A., Ramos, A., Gonzalez, A., Green, N. G., and Morgan, H. (2003). Electrohydrodynamics and dielectrophoresis in Microsystems: scaling laws. J. Phys. D: Appl. Phys., Vol. 36, pp. (2584-2597).
[78] Feng, J. J., Krishnamoorthy, S., and Sundaram, S. (2007). Numerical analysis of mixing by electrothermal induced flow in microfluidic systems. Biomicrofluidics, Vol. 1, pp. (024102:1-8).
[79] Ramos, A., Morgan, H., Green, N. G., and Castellanos, A. (1998). AC electrokinetics: a review of forces in microelectrode structures. J. Phys. D: Appl. Phys., Vol. 31, pp. (2338-2353).
[80] Bhatia, S. K., Shriver-Lake, L. C., Prior, K. J., Georger, J. H., Calvert, J. M., Bredehorst, R., and Ligler, F. S. (1989) Use of Thiol-terminated silanes and heterobifunctional crosslinkers for immobilization of antibodies on silica surfaces. Anal. Biochem., Vol. 178, pp. (408-413).
[81] Holzel, et al. (2005) Trapping Single Molecules by Dielectrophoresis. Physical Review Letters 95(128102).

1-8. (canceled)

9. An electrokinetics-assisted sensor for sensing a target material, the sensor comprising:
a microstructure deflectable in response to added mass on a body of the microstructure;
at least one feature on or near the microstructure designed to generate an electric field giving rise to one or more electrokinetic effects to drive material towards the body of the microstructure, when an electrical signal is applied to the at least one feature; and
a functionalized surface on the body of the microstructure comprising at least one macromolecule specific for the target material, that captures the target material on the body;
wherein presence of at least the target material on the body of the microstructure causes a response in the microstructure, the response including a detectable change in deflection of the microstructure.

10. The sensor of claim 9 wherein the functionalized surface comprises at least one macromolecule specific for a biological target material.

11. (canceled)

12. The sensor of claim 9 wherein the at least one feature comprises at least one of: a resistive feature, a capacitive feature, and a microelectrode.

13. The sensor of claim 12 wherein the resistive feature comprises at least one of: a change in conductivity of the microstructure, a change in cross-sectional area of the microstructure, and a resistive electrical component.

14. (canceled)

15. The sensor of claim 9 wherein the detectable change in deflection of the microstructure comprises a change in a resonant mode of the microstructure.

16. The sensor of claim 15 wherein the at least one feature gives rise to one or more electrokinetic effects to drive material towards at least one of:
an antinode of the resonant mode, wherein presence of material at the antinode results in greater detectable change than presence of material elsewhere on the microstructure; and
a node of the resonant mode, wherein presence of material at the node results in little or no detectable change.

17. (canceled)

18. The sensor of claim 15 wherein the detectable change comprises a change in at least one of: resonant frequency, resonant amplitude, and resonant phase.

19. The sensor of claim 9 wherein the one or more electrokinetic effects comprises at least one of: dielectrophoresis (DEP), electroosmosis (EO), and electrothermal flow.

20. The sensor of claim 9 wherein the microstructure comprises at least one of: a cantilever beam having one free end and one fixed end, and a fixed-fixed beam having two fixed ends.

21. The sensor of claim 9 wherein at least one feature gives rise to one or more electrokinetic effects to drive material with at least one of: different mass, different charge and different polarization, to different areas on or near the microstructure.

22. The sensor of claim 9 wherein the generated electric field has locally enhanced or diminished field strength at a selected area to collect the target material.

23. (canceled)

24. A device for electrokinetics-assisted sensing of a target material, the device comprising:
a chamber defined in a substrate, the chamber housing:
i) an electrokinetics-assisted sensor comprising:
a microstructure deflectable in response to added mass on a body of the microstructure;
at least one feature on or near the microstructure designed to generate an electric field giving rise to one or more electrokinetic effects to drive material towards the body of the microstructure, when an electrical signal is applied to the at least one feature; and
a functionalized surface on the body of the microstructure comprising at least one macromolecule specific for the target material, that captures the target material on the body;
wherein presence of at least the target material on the body of the microstructure causes a response in the microstructure, the response including a detectable change in deflection of the microstructure; and
ii) a fluid sample; and at least one bonding pad in electrical communication with the at least one feature of the sensor, that delivers an electrical signal to the sensor to cause generation of the electric field.

25. The device of claim 24 further comprising an excitation electrode at or near the sensor, that mechanically excites the sensor into a resonant mode.

26. The device of claim 24 wherein the chamber is in fluid communication with an inlet enabling inflow of the fluid sample and an outlet enabling outflow of the fluid sample.

27. The device of claim 24 wherein the chamber is in fluid communication with a gas microchannel that enables introduction of a gas bubble into the chamber.

28-36. (canceled)

37. A method for electrokinetics-assisted sensing of a target material, the method comprising:
providing a fluid sample to an electrokinetics-assisted sensor, the sensor comprising:
a microstructure deflectable in response to added mass on a body of the microstructure;
at least one feature on or near the microstructure designed to generate an electric field giving rise to one or more electrokinetic effects to drive material towards the body of the microstructure, when an electrical signal is applied to the at least one feature; and
a functionalized surface on the body of the microstructure comprising at least one macromolecule specific for the target material, that captures the target material on the body;
wherein presence of at least the target material on the body of the microstructure causes a response in the microstructure, the response including a detectable change in deflection of the microstructure;
applying at least one electrical signal to the at least one feature of the sensor to give rise to one or more electrokinetic effects to drive material in the fluid sample toward the microstructure of the sensor;
applying i) a same or different electrical signal or ii) a magnetic field to the sensor or to an actuator at or near the sensor to mechanically excite the sensor into a resonant mode;
detecting a resonant response of the sensor; and
determining, based on at least one of the frequency, phase and amplitude of the resonant response, whether the target material is present in the fluid sample and/or an amount of target material present in the fluid sample.

38. The method of claim 37 wherein the electrical signal to give rise to one or more electrokinetic effects and the electrical signal to mechanically excite the sensor are comprised in a same single frequency or multi-frequency electrical signal.

39. The method of claim 37 further comprising, prior to detecting the resonant response, removing non-target material from the sensor.

40-43. (canceled)

44. The method of claim 37 wherein the fluid sample comprises a liquid, the method further comprising, prior to applying the electrical signal to mechanically excite the sensor, introducing a gas bubble to fully or partially engulf the sensor.

45. The method of claim 37 wherein the fluid sample comprises a gas.
